(19) United States
(12) Patent Application Publication
(10) Pub. No.: US 2024/0268096 A1
(43) Pub. Date: Aug. 8, 2024

(54) MEMORY DEVICE AND ELECTRONIC DEVICE

(71) Applicant: Semiconductor Energy Laboratory Co., Ltd., Atsugi-shi (JP)

(72) Inventors: Yuki OKAMOTO, Ebina (JP); Takanori MATSUZAKI, Atsugi (JP); Hiroki INOUE, Atsugi (JP)

(21) Appl. No.: 18/423,850

(22) Filed: Jan. 26, 2024

(30) Foreign Application Priority Data
Feb. 3, 2023 (JP) 2023-015427

(51) Int. Cl. H10B 12/00

(52) U.S. Cl. CPC H10B 12/30; H10B 12/50

(57) ABSTRACT

A memory device capable of reading multi-bit data at a time is provided. The memory device includes a first layer and a second layer positioned above or below the first layer. The first layer includes a first transistor and a first capacitor, and the second layer includes a second transistor and a second capacitor. Each of the first and second capacitors is a trench capacitor, and the trench length of the second capacitor is larger than the trench length of the first capacitor. A voltage retained in the first capacitor corresponds to a lower bit signal of data, and a voltage retained in the second capacitor corresponds to a higher bit signal of the data.

### BACKGROUND OF THE INVENTION

### 1. Field of the Invention

One embodiment of the present invention relates to a memory device and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Specific examples of the technical field of one embodiment of the present invention disclosed in this specification include a semiconductor device, a display apparatus, a liquid crystal display apparatus, a light-emitting apparatus, a power storage device, an imaging device, a memory device, a signal processing device, a sensor, a processor, an electronic device, a system, a method for driving any of them, a method for manufacturing any of them, and a method for inspecting any of them.

### 2. Description of the Related Art

In recent years, with the increase in the amount of data manipulated, a memory device having a larger memory capacity has been required. To increase memory capacity per unit area, stacking memory cells as in a 3D NAND memory device is effective (see Patent Documents 1 to 3). Stacking memory cells can increase memory capacity per unit area in accordance with the number of stacked memory cells.

### REFERENCES

### Patent Documents

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

With the increase in the amount of data manipulated, the amount of data written to a memory device and the amount of data read from the memory device tend to increase. In particular, in the case where multi-bit data is read from a memory device that includes a plurality of memory cells each retaining 1-bit data, 1-bit data reading needs to be performed on the plurality of memory cells one by one; thus, the larger the amount of data to be read is, the longer the time required for reading operation is. Therefore, in recent years, multi-bit data reading operation is desired to be performed in a shorter time in the memory device.

An object of one embodiment of the present invention is to provide a memory device capable of writing and reading multi-bit data. Another object of one embodiment of the present invention is to provide a memory device with high reading speed. Another object of one embodiment of the present invention is to provide a memory device with low power consumption. Another object of one embodiment of the present invention is to provide a memory device to be manufactured at low cost. Another object of one embodiment of the present invention is to provide a memory device with a small circuit area. Another object of one embodiment of the present invention is to provide an electronic device including the above memory device. Another object of one embodiment of the present invention is to provide a novel memory device or a novel electronic device.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all the objects listed above and the other objects.

One embodiment of the present invention is a memory device with a structure in which, in order to reduce the time required for reading operation, selection signals for reading are concurrently transmitted to a plurality of memory cells and multi-bit data is read from the plurality of memory cells. Specifically, the memory device includes at least the same number of memory cells as the number of bits of retained data, and each of the memory cells includes a capacitor. Here, a memory device that retains 4-bit data is described as an example.

Capacitance values of the capacitors included in the memory cells are preferably different from each other. For example, in the case of a memory device that retains 4-bit data, the memory device preferably includes four memory cells. The ratio of capacitance values of the capacitors included in the four memory cells is 1:2:4:8. For example, when the lowest capacitance value in the four capacitors is Cᵤₜ, the capacitance values of the other three capacitors are 2 Cᵤₜ, 4 Cᵤₜ, and 8 Cᵤₜ.

In this case, the voltage written to the capacitor with the capacitance value of Cᵤₜ corresponds to a signal of the lower zeroth bit (of the upper third bit, the first digit from the right in the four digits) of the 4-bit data. The voltage written to the capacitor with the capacitance value of 2 Cᵤₜ corresponds to a signal of the lower first bit (of the upper second bit, the second digit from the right in the four digits) of the 4-bit data. The voltage written to the capacitor with the capacitance value of 4 Cᵤₜ corresponds to a signal of the lower second bit (of the upper first bit, the third digit from the right in the four digits) of the 4-bit data. The voltage written to the capacitor with the capacitance value of 8 Cᵤₜ corresponds to a signal of the lower third bit (of the upper zeroth bit, the fourth digit from the right in the four digits) of the 4-bit data.

Each of the memory cells can be a DRAM (Dynamic Random Access Memory), for example. In this case, each of the memory cells includes a transistor in addition to the capacitor. In each of the memory cells, one of a source and a drain of the transistor is electrically connected to one of a pair of electrodes of the capacitor, and the other of the source and the drain of the transistor is electrically connected to a first wiring (e.g., a bit line). A gate of the transistor is electrically connected to a second wiring (e.g., a word line).

Here, the case where the first wiring is precharged with a ground potential or the like, and then selection signals for reading are concurrently transmitted to the four memory cells through the second wiring is considered. At this time, the transistor of each of the four memory cells is turned on, and charges are redistributed between the one of the pair of electrodes of the capacitor in each of the four memory cells and the first wiring. Since the capacitance values of the capacitors of the four memory cells are different from each other, the total amount of charge retained in the capacitors of the four memory cells is uniquely determined in accordance with the 4-bit data. Thus, a potential of the first wiring that is changed by the charge redistribution is also uniquely determined in accordance with the 4-bit data. After that, by reading the potential of the first wiring with the use of a reading circuit, the 4-bit data retained in the four memory cells can be read.

The four memory cells preferably overlap with each other. In particular, the four memory cells may be formed using, for example, the same layout pattern (such a pattern is sometimes referred to as a circuit pattern; in particular, in the case where patterning is performed using a light-blocking mask or the like, the pattern is sometimes referred to as a mask pattern). At this time, the four memory cells may be trench capacitors (sometimes referred to as cylinder capacitors). Since capacitance values of the trench capacitors are determined in accordance with the trench depths (the thicknesses of insulating films in which openings are formed as the trenches), capacitors with different depths are formed in the four memory cells. Note that in this case, the trench depths differ among the capacitors (the thicknesses of the insulating films in which the openings are formed as the trenches differ among the capacitors); thus, there is no need to change a layout pattern for each memory cell. That is, a stacked-layer structure of memory cells having the same layout pattern and including capacitors with different capacitance values can be manufactured.

A structure of a memory device or an electronic device of one embodiment of the present invention is described below.

(1) One embodiment of the present invention is a memory device including a first layer and a second layer. The second layer is positioned above or below the first layer. The first layer includes a first transistor, a first capacitor, and a first insulator; and the second layer includes a second transistor, a second capacitor, and a second insulator. The first transistor includes a first oxide semiconductor, and the second transistor includes a second oxide semiconductor. The first insulator includes a first opening, and the second insulator includes a second opening. The first capacitor is a trench capacitor at least part of which is included inside the first opening, and the second capacitor is a trench capacitor at least part of which is included inside the second opening. The length of the second opening is larger than the length of the first opening. One of a source and a drain of the first transistor is electrically connected to the first capacitor, and one of a source and a drain of the second transistor is electrically connected to the second capacitor. The other of the source and the drain of the first transistor is electrically connected to a wiring, and the other of the source and the drain of the second transistor is electrically connected to the wiring. The second oxide semiconductor includes a region overlapping with at least part of the first oxide semiconductor. The second opening includes a region overlapping with at least part of the first opening. A voltage retained in the first capacitor corresponds to a lower bit signal of digital data to be written, and a voltage retained in the second capacitor corresponds to a higher bit signal of the digital data to be written.

(2) Another embodiment of the present invention may be the structure in (1) in which the first layer includes a third conductor and the second layer includes a fourth conductor. The first transistor may include a first conductor functioning as the other of the source and the drain, and the second transistor may include a second conductor functioning as the other of the source and the drain. The third conductor and the fourth conductor may each be included in the wiring.

It is particularly preferable that the third conductor include a region in contact with the first conductor and the fourth conductor include a region in contact with the second conductor. It is preferable that the second conductor include a region overlapping with at least part of the first conductor and the fourth conductor include a region overlapping with at least part of the third conductor.

(3) Another embodiment of the present invention may be the structure in (2) in which the first oxide semiconductor and the second oxide semiconductor each contain one or more selected from indium, zinc, and an element M.

The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

(4) Another embodiment of the present invention may be the structure in (3) in which a capacitance value of the second capacitor is greater than or equal to 1.8 times and less than or equal to 2.2 times a capacitance value of the first capacitor.

(5) Another embodiment of the present invention may be the structure in (1) in which the first layer includes a third insulator and a third conductor, and the second layer includes a fourth insulator and a fourth conductor. The first transistor may include a fifth conductor functioning as the one of the source and the drain and a first conductor functioning as the other of the source and the drain; and the second transistor may include a sixth conductor functioning as the one of the source and the drain and a second conductor functioning as the other of the source and the drain. The third conductor and the fourth conductor may each be included in the wiring.

It is particularly preferable that the third insulator be positioned above the first insulator, the fifth conductor be positioned above the first insulator and below the third insulator, and the first conductor be positioned above the third insulator. The third insulator includes a third opening. The first oxide semiconductor preferably includes a region in contact with a side surface of the third opening, the fifth conductor, and the first conductor. It is preferable that the fourth insulator be positioned above the second insulator, the sixth conductor be positioned above the second insulator and below the fourth insulator, and the second conductor be positioned above the fourth insulator. The fourth insulator includes a fourth opening. The second oxide semiconductor preferably includes a region in contact with a side surface of the fourth opening, the sixth conductor, and the second conductor. The third opening preferably includes a region overlapping with at least part of the first opening, and the fourth opening preferably includes a region overlapping with at least part of the second opening. The third conductor preferably includes a region in contact with the first conductor, and the fourth conductor preferably includes a region in contact with the second conductor. It is preferable that the second conductor include a region overlapping with at least part of the first conductor, the fourth conductor include a region overlapping with at least part of the third conductor, and the sixth conductor include a region overlapping with at least part of the fifth conductor.

(6) Another embodiment of the present invention may be the structure in (5) in which the first oxide semiconductor and the second oxide semiconductor each contain one or more selected from indium, zinc, and an element M.

The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

(7) Another embodiment of the present invention may be the structure in (6) in which a capacitance value of the second capacitor is greater than or equal to 1.8 times and less than or equal to 2.2 times a capacitance value of the first capacitor.

(8) Another embodiment of the present invention may be the structure in any one of (1) to (7) in which a driver circuit layer is included. In particular, the driver circuit layer is preferably positioned below the first transistor, the second transistor, the first capacitor, and the second capacitor.

(9) Another embodiment of the present invention is an electronic device including the memory device in (8) and a housing.

In the above-described structure, selection signals for reading are concurrently transmitted to a plurality of memory cells to read data, whereby the time required for the reading operation can be shortened as compared with the case where selection signals for reading are sequentially transmitted to the plurality of memory cells to read data. That is, when selection signals for reading are concurrently transmitted to the plurality of memory cells, the reading speed of the memory device can be increased.

Since the time required for the reading operation of the memory device is shortened, the total operation time of the memory device is shortened. Thus, the power consumption of the memory device can also be reduced.

It is preferable that the plurality of memory cells overlap with each other. Thus, the circuit area of the memory device can be reduced. Furthermore, the plurality of memory cells can be formed using the same layout pattern. When capacitors of the plurality of memory cells are trench capacitors and the trench depths (the thicknesses of insulating films in which openings are formed as the trenches) differ among the capacitors, a plurality of memory cells including capacitors with different capacitance values can be manufactured even with the same layout pattern. Therefore, the above plurality of memory cells can be manufactured with the same layout pattern; thus, the manufacturing cost of the memory device can be reduced.

According to one embodiment of the present invention, a memory device capable of writing and reading multi-bit data can be provided. According to another embodiment of the present invention, a memory device with high reading speed can be provided. According to another embodiment of the present invention, a memory device with low power consumption can be provided. According to one embodiment of the present invention, a memory device to be manufactured at low cost can be provided. According to one embodiment of the present invention, a memory device with a small circuit area can be provided. According to one embodiment of the present invention, an electronic device including the above memory device can be provided. According to another embodiment of the present invention, a novel memory device or a novel electronic device can be provided.

Note that the effects of one embodiment of the present invention are not limited to the effects listed above. The effects listed above do not preclude the existence of other effects. The other effects are effects that are not described in this section and are described below. Effects that are not described in this section are derived from the description of the specification, the drawings, and the like and can be extracted as appropriate from the description by those skilled in the art. One embodiment of the present invention has at least one of the effects listed above and the other effects. Accordingly, one embodiment of the present invention does not have the effects listed above in some cases.

### BRIEF DESCRIPTION OF THE DRAWINGS

FIG. 1 is a block diagram illustrating a structure example of a memory device.

FIG. 2 is a circuit diagram illustrating a structure example of a memory device.

FIG. 3 is a timing chart showing an operation example of a memory device.

FIG. 4 is a timing chart showing an operation example of a memory device.

FIG. 5 is a circuit diagram illustrating a structure example of a memory device.

FIG. 6 is a schematic cross-sectional view illustrating a structure example of a memory device.

FIG. 7 is a schematic cross-sectional view illustrating a structure example of a memory device.

FIG. 8 is a block diagram illustrating a structure example of a reading circuit of a memory device.

FIG. 9 is a block diagram illustrating a structure example of a circuit included in a reading circuit.

FIGS. 10A and 10B are circuit diagrams each illustrating an example of part of a structure of a memory device.

FIGS. 11A to 11C are circuit diagrams each illustrating a structure example of a circuit included in a reading circuit.

FIG. 12 is a block diagram illustrating a structure example of a circuit included in a reading circuit.

FIGS. 13A and 13B are circuit diagrams each illustrating a structure example of a circuit included in a reading circuit.

FIG. 14 is a circuit diagram illustrating a structure example of a circuit included in a reading circuit.

FIG. 15 is a block diagram illustrating a structure example of a memory device.

FIG. 16 is a timing chart showing an operation example of a memory device.

FIGS. 17A to 17C are circuit diagrams each illustrating a structure example of a circuit included in a reading circuit.

FIG. 18 is a block diagram illustrating a structure example of a memory device.

FIG. 19A is a perspective view illustrating a structure example of a memory device, and

FIG. 19B is a block diagram illustrating a structure example of a semiconductor device.

FIG. 20 is a schematic cross-sectional view of a structure example of a memory device.

FIG. 21A is a schematic plan view illustrating a structure example of a memory layer, and FIGS. 21B to 21D are schematic cross-sectional views each illustrating the structure example of the memory layer.

FIGS. 22A to 22C are schematic cross-sectional views each illustrating a structure example of a transistor included in a memory layer.

FIG. 23 is a schematic cross-sectional view illustrating a structure example of a memory device.

FIG. 24A is a schematic plan view illustrating a structure example of a memory layer, and FIGS. 24B and 24C are schematic cross-sectional views each illustrating the structure example of the memory layer.

FIGS. 25A and 25B are schematic cross-sectional views each illustrating a structure example of a memory layer.

FIGS. 26A and 26B illustrate examples of electronic components.

FIGS. 27A and 27B illustrate examples of electronic devices, and FIGS. 27C to 27E illustrate an example of a large computer.

FIG. 28 illustrates an example of a device for space.

FIG. 29 illustrates an example of a storage system that can be used for a data center.

### DETAILED DESCRIPTION OF THE INVENTION

In this specification and the like, a semiconductor device means a device that utilizes semiconductor characteristics, and refers to a circuit including a semiconductor element (e.g., a transistor, a diode, or a photodiode), and a device including the circuit. The semiconductor device also means devices that can function by utilizing semiconductor characteristics. As an example of a semiconductor device, an integrated circuit can be given. As another example of a semiconductor device, a chip including an integrated circuit can be given. As another example of a semiconductor device, an electronic component in which a chip is stored in a package can be given. Furthermore, a memory device, a display apparatus, a light-emitting apparatus, a lighting device, and an electronic device themselves are semiconductor devices in some cases and include a semiconductor device in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow(s) electrical connection between X and Y (e.g., a switch, a transistor, an inductor, a resistor element, a diode, a display device, a light-emitting device, or a load) can be connected between X and Y. Note that a switch has a function of being controlled to be turned on or off. That is, the switch has a function of being in a conduction state (on state) or a non-conduction state (off state) to control whether a current flows or not.

For example, in the case where X and Y are functionally connected, one or more circuits that allow(s) functional connection between X and Y (e.g., a logic circuit (an inverter, a NAND circuit, a NOR circuit, or the like); a signal converter circuit (a digital-to-analog converter circuit, an analog-to-digital converter circuit, a gamma correction circuit, or the like); a potential level converter circuit (a power supply circuit such as a step-up circuit or a step-down circuit, a level shifter circuit for changing the potential level of a signal, or the like); a voltage source; a current source; a switching circuit; an amplifier circuit (a circuit that can increase signal amplitude, current amount, or the like, an operational amplifier, a differential amplifier circuit, a source follower circuit, a buffer circuit, or the like); a signal generation circuit; a memory circuit; or a control circuit) can be connected between X and Y. For example, even when another circuit is interposed between X and Y, X and Y are functionally connected when a signal output from X is transmitted to Y.

Note that an explicit description, X and Y are electrically connected, includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

The expression “X, Y, a source (for example, sometimes called one of a first terminal and a second terminal) of a transistor, and a drain (for example, sometimes called the other of the first terminal and the second terminal) of the transistor are electrically connected to each other, and X, the source of the transistor, the drain of the transistor, and Y are electrically connected to each other in this order” can be used, for example. Alternatively, the expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression similar to the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “resistor element” can be, for example, a circuit element or a wiring having a resistance higher than 0Ω. Therefore, in this specification and the like, a “resistor element” includes a wiring having a resistance, a transistor in which a current flows between its source and drain, a diode, and a coil. Thus, the term “resistor element” can be sometimes replaced with the terms “resistor”, “load”, or “region having a resistance”; conversely, the terms “resistor”, “load”, or “region having a resistance” can be sometimes replaced with the term “resistor element”. The resistance can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance may be greater than or equal to 1Ω and less than or equal to 1×10⁹Ω.

In this specification and the like, a “capacitor” can be, for example, a circuit element having a capacitance value higher than 0° F., a region of a wiring having a capacitance value higher than 0° F., or gate capacitance of a transistor. Terms such as “capacitor” and “gate capacitance” can be replaced with the term “capacitance” in some cases. Conversely, the term “capacitance” can be replaced with a term such as “capacitor” or “gate capacitance” in some cases. In addition, the “capacitor” (including a capacitor with three or more terminals) includes an insulator and a pair of conductors between which the insulator is interposed. The term “a pair of conductors” of a capacitor can be replaced with the term “a pair of electrodes”, “a pair of conductive regions”, “a pair of regions”, or “a pair of terminals”. In addition, the terms “one of a pair of terminals” and “the other of the pair of terminals” are referred to as a first terminal and a second terminal, respectively, in some cases. Note that the capacitance value can be higher than or equal to 0.05 fF and lower than or equal to 10 pF, for example. For example, the capacitance value may be higher than or equal to 1 pF and lower than or equal to 10 μF.

In this specification and the like, a transistor includes three terminals called a gate, a source, and a drain. The gate is a control terminal for controlling the on/off state of the transistor. The two terminals functioning as the source and the drain are input/output terminals of the transistor. Functions of the two input/output terminals of the transistor depend on the conductivity type (n-channel type or p-channel type) of the transistor and the levels of potentials applied to the three terminals of the transistor, and one of the two terminals serves as a source and the other serves as a drain. Therefore, the terms “source” and “drain” can be sometimes used interchangeably in this specification and the like. In this specification and the like, the terms “one of a source and a drain” (or a first electrode or a first terminal) and “the other of the source and the drain” (or a second electrode or a second terminal) are used to describe the connection relation of a transistor. Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, a drain-source current does not change very much even if a drain-source voltage changes when the transistor operates in a saturation region, so that a flat slope of voltage-current characteristics can be obtained. By utilizing the flat slope of the voltage-current characteristics, an ideal current source circuit or an active load having an extremely high resistance can be obtained. Accordingly, a differential circuit, a current mirror circuit, or the like having excellent properties can be obtained.

A single circuit element shown in a circuit diagram may include a plurality of circuit elements. For example, a single resistor element shown in a circuit diagram may be two or more resistor elements electrically connected to each other in series. For another example, a single capacitor shown in a circuit diagram may be two or more capacitors electrically connected to each other in parallel. For another example, a single transistor shown in a circuit diagram may be two or more transistors which are electrically connected to each other in series and whose gates are electrically connected to each other. For another example, a single switch shown in a circuit diagram may be a switch including two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, and the like can be referred to as a node.

In this specification and the like, a selector sometimes refers to, for example, a circuit in which a plurality of input terminals and one output terminal are included, one of the plurality of input terminals is selected, and electrical continuity is established between the selected input terminal and the one output terminal. In other words, the selector is sometimes a circuit in which one of input signals input to the plurality of input terminals is selected and the selected input signal is output to the output terminal. Alternatively, for example, a selector sometimes refers to a circuit in which a plurality of output terminals and one input terminal are included, one of the plurality of output terminals is selected, and electrical continuity is established between the selected output terminal and the one input terminal. In other words, the selector is sometimes a circuit in which one of the plurality of output terminals is selected and an input signal input to the input terminal is output to the selected output terminal. That is, the selector sometimes refers to a multiplexer or a demultiplexer.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values, and a potential supplied to a wiring, a potential applied to a circuit and the like, and a potential output from a circuit and the like, for example, are changed with a change of the reference potential.

In this specification and the like, the term “high-level potential” or “low-level potential” does not mean a particular potential. For example, in the case where two wirings are both described as “functioning as a wiring for supplying a high-level potential,” the levels of the high-level potentials that these wirings supply are not necessarily equal to each other. Similarly, in the case where two wirings are both described as “functioning as a wiring for supplying a low-level potential,” the levels of the low-level potentials that these wirings supply are not necessarily equal to each other.

A current means an electric charge transfer (electrical conduction); for example, the expression “electrical conduction of positively charged particles is caused” can be replaced with “electrical conduction of negatively charged particles is caused in the opposite direction”. Therefore, unless otherwise specified, a current in this specification and the like refers to an electric charge transfer (electrical conduction) caused by carrier movement. Examples of a carrier here include an electron, a hole, an anion, a cation, and a complex ion, and the type of carrier differs between current flow systems (e.g., a semiconductor, a metal, an electrolyte solution, and a vacuum). The direction of a current in a wiring or the like refers to the direction in which a carrier with a positive electric charge moves, and the current amount is expressed as a positive value. In other words, the direction in which a carrier with a negative electric charge moves is opposite to the direction of a current, and the current amount is expressed as a negative value. Thus, in the case where the polarity of a current (or the direction of a current) is not specified in this specification and the like, the expression “a current flows from an element A to an element B” can be replaced with “a current flows from an element B to an element A”. The expression “a current is input to an element A” can be replaced with “a current is output from an element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or claims. For another example, a “first” component in one embodiment in this specification and the like can be omitted in other embodiments or claims.

In this specification and the like, terms for describing arrangement, such as “over”, “above”, “under”, and “below”, are sometimes used for convenience to describe the positional relation between components with reference to drawings. The positional relation between components is changed as appropriate in accordance with the direction from which each component is described. Thus, the positional relation is not limited to that described with a term used in this specification and the like and can be explained with another term as appropriate depending on the situation. For example, the expression “an insulator over (on) a top surface of a conductor” can be replaced with the expression “an insulator on a bottom surface of a conductor” when the direction of a diagram showing these components is rotated by 180º.

Terms such as “over”, “above”, “under”, and “below” do not necessarily mean that a component is placed directly on or under and directly in contact with another component. For example, the expression “an electrode B over an insulating layer A” does not necessarily mean that the electrode B is on and in direct contact with the insulating layer A, and can mean the case where another component is provided between the insulating layer A and the electrode B. In a similar manner, for example, the expression “an electrode B above an insulating layer A” does not necessarily mean that the electrode B is over and in direct contact with the insulating layer A, and can mean the case where another component is provided between the insulating layer A and the electrode B. In a similar manner, for example, the expression “an electrode B below an insulating layer A” does not necessarily mean that the electrode B is under and in direct contact with the insulating layer A, and can mean the case where another component is provided between the insulating layer A and the electrode B.

In this specification and the like, components arranged in a matrix and their positional relation are sometimes described using terms such as “row” and “column”. The positional relation between components is changed as appropriate in accordance with the direction from which each component is described. Thus, the positional relation is not limited to that described with a term used in this specification and the like and can be explained with another term as appropriate depending on the situation. For example, the term “row direction” can be replaced with the term “column direction” when the direction of the diagram is rotated by 90°.

In this specification and the like, terms such as “film” and “layer” can be interchanged with each other depending on circumstances. For example, the term “conductive layer” can be changed to the term “conductive film” in some cases. Moreover, the term “insulating film” can be changed into the term “insulating layer” in some cases. Moreover, such terms can be replaced with a word not including a term such as “film” or “layer” depending on the case or circumstances. For example, the term “conductive layer” or “conductive film” can be changed into the term “conductor” in some cases. For example, in some cases, the term “insulating layer” or “insulating film” can be changed into the term “insulator” in some cases.

In this specification and the like, the terms “electrode”, “wiring”, and “terminal” do not have functional limitations. For example, an “electrode” is used as part of a wiring in some cases, and vice versa. Furthermore, a term such as “electrode” or “wiring” can also mean a combination of a plurality of electrodes or wirings provided in an integrated manner, for example. For another example, a “terminal” can be used as part of a wiring or an electrode, and a “wiring” and an “electrode” can be used as part of a terminal. Furthermore, the term “terminal” includes the case where at least two of electrodes, wirings, terminals, and the like are formed in an integrated manner. Therefore, for example, an “electrode” can be part of a wiring or a terminal, and a “terminal” can be part of a wiring or an electrode. Moreover, the terms “electrode”, “wiring”, and “terminal” are sometimes replaced with the term “region”, for example.

In this specification and the like, terms such as “wiring”, “signal line”, and “power supply line” can be interchanged with each other depending on the case or in accordance with circumstances. For example, the term “wiring” can be changed into the term “signal line” in some cases. For another example, the term “wiring” can be changed into a term such as “power supply line” in some cases. Inversely, a term such as “signal line” or “power supply line” can be changed into the term “wiring” in some cases. A term such as “power supply line” can be changed into the term “signal line” in some cases. Inversely, a term such as “signal line” can be changed into the term “power source line” in some cases. The term “potential” that is applied to a wiring can be changed into the term “signal” depending on the case or in accordance with circumstances. Inversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed as appropriate depending on the circumstances. For example, even when two periods are shown to have an equal length, the two periods have different lengths in some cases. Furthermore, for example, even when one of two periods is shown longer than the other, the two periods can have the equal length in some cases, or the one of the two periods has a shorter length than the other in other cases.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide contained in a channel formation region of a transistor is called an oxide semiconductor in some cases. That is, a metal oxide included in a channel formation region of a transistor that has at least one of an amplifying function, a rectifying function, and a switching function can be referred to as a metal oxide semiconductor. In addition, an OS transistor is a transistor including a metal oxide or an oxide semiconductor.

In this specification and the like, a metal oxide containing nitrogen is also referred to as a metal oxide in some cases. In addition, a metal oxide containing nitrogen may be referred to as a metal oxynitride.

In this specification and the like, an impurity in a semiconductor refers to, for example, elements other than the main components of a semiconductor layer. For instance, an element with a concentration lower than 0.1 atomic % is an impurity. When an impurity is contained, one or more selected from the increase in the density of defect states in the semiconductor, the decrease in the carrier mobility, and the decrease in the crystallinity sometimes occur. When the semiconductor is an oxide semiconductor, examples of impurities that change the characteristics of the semiconductor include Group 1 elements, Group 2 elements, Group 13 elements, Group 14 elements, Group 15 elements, and transition metals other than the main components of the oxide semiconductor. Specific examples are hydrogen (included also in water), lithium, sodium, silicon, boron, phosphorus, carbon, and nitrogen.

In this specification and the like, a switch is in a conduction state (on state) or in a non-conduction state (off state) to control whether a current flows therethrough or not. Alternatively, a switch has a function of selecting and changing a current path. Thus, a switch may have two or more terminals through which a current flows, in addition to a control terminal. For example, an electrical switch or a mechanical switch can be used. That is, a switch is not limited to a certain element and can be any element capable of controlling a current.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. In the case of using a transistor as a switch, the conduction state of the transistor refers to a state in which a source electrode and a drain electrode of the transistor are regarded as being electrically short-circuited or a state in which a current can flow between the source electrode and the drain electrode, for example. The non-conduction state of the transistor refers to a state in which the source electrode and the drain electrode of the transistor are regarded as being electrically disconnected. In the case where a transistor operates just as a switch, there is no particular limitation on the polarity (conductivity type) of the transistor.

An example of a mechanical switch is a switch using a microelectromechanical systems (MEMS) technology. Such a switch includes an electrode that can be moved mechanically, and its conduction and non-conduction are controlled with movement of the electrode.

In this specification, “parallel” indicates a state where the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The terms “approximately perpendicular” and “substantially perpendicular” indicate that the angle formed between two straight lines is greater than or equal to 60° and less than or equal to 120°.

In this specification and the like, the structure described in each embodiment can be combined with the structures described in the other embodiments as appropriate to constitute one embodiment of the present invention. In the case where a plurality of structure examples are described in one embodiment, some of the structure examples can be combined as appropriate.

Note that a content (or part thereof) described in one embodiment can be applied to, combined with, or replaced with another content (or part thereof) described in the same embodiment and/or a content (or part thereof) described in another embodiment or other embodiments.

Note that in each embodiment, a content described in the embodiment is a content described with reference to a variety of diagrams or a content described with text in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

The embodiments in this specification are described with reference to drawings. Note that the embodiments can be implemented in many different modes, and it will be readily appreciated by those skilled in the art that modes and details can be changed in various ways without departing from the spirit and scope of the present invention. Therefore, the present invention should not be construed as being limited to the description of the embodiments. Note that in the structures of the invention described in the embodiments, the same portions or portions having similar functions are denoted by the same reference numerals in different drawings and the description of such portions is not repeated in some cases. In perspective views and the like, illustration of some components might be omitted for clarity of the drawings.

In this specification and the like, when a plurality of components denoted by the same reference numerals need to be distinguished from each other, identification signs such as “_1”, “[n]”, and “[m,n]” are sometimes added to the reference numerals. Components denoted with identification signs such as “_1”, “[n]”, and “[m,n]” in drawings and the like are sometimes denoted without such identification signs in this specification and the like when the components do not need to be distinguished from each other.

In the drawings of this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, the following can be included: a variation in a signal, a voltage, or a current due to noise or difference in timing.

### Embodiment 1

In this embodiment, a memory device of one embodiment of the present invention is described.

### <Structure Example 1 of Memory Device>

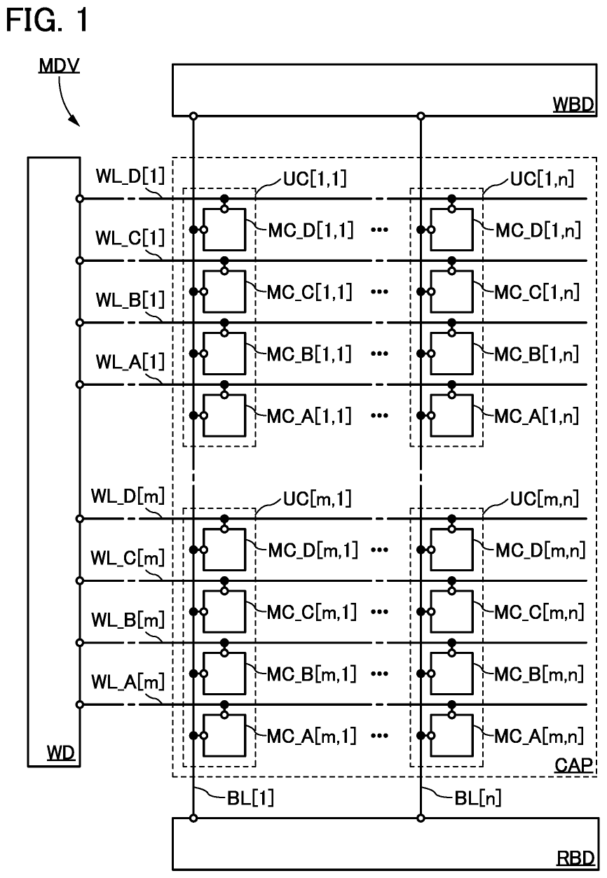

FIG. 1 is a block diagram illustrating a structure example of a memory device of one embodiment of the present invention. A memory device MDV illustrated in FIG. 1 includes a cell array portion CAP, a driver circuit WBD, a driver circuit RBD, and a driver circuit WD, for example.

The cell array portion CAP includes a plurality of circuits UC. In the cell array portion CAP, the plurality of circuits UC are arranged in a matrix of m rows and n columns (m and n are each an integer greater than or equal to 1).

For example, a circuit UC[1,1] is placed in the first row and the first column of the cell array portion CAP. A circuit UC[m,1] is placed in the m-th row and the first column of the cell array portion CAP. A circuit UC[1,n] is placed in the first row and the n-th column of the cell array portion CAP. A circuit UC[m,n] is placed in the m-th row and the n-th column of the cell array portion CAP.

In the cell array portion CAP in FIG. 1, for example, wirings BL[1] to BL[n] extend in the column direction. In the cell array portion CAP in FIG. 1, for example, a wiring WL_A[1] to a wiring WL_A[m], a wiring WL_B[1] to a wiring WL_B[m], a wiring WL_C[1] to a wiring WL_C[m], and a wiring WL_D[1] to a wiring WL_D[m] extend in the row direction.

The plurality of circuits UC arranged in the cell array portion CAP each include a memory cell MC_A, a memory cell MC_B, a memory cell MC_C, and a memory cell MC_D, for example. Note that in this specification and the like, in the case where the memory cell MC_A, the memory cell MC_B, the memory cell MC_C, and the memory cell MC_D do not need to be distinguished from each other, they are referred to as a memory cell MC in some cases.

Specifically, the circuit UC[1,1] includes, for example, a memory cell MC_A[1,1], a memory cell MC_B[1,1], a memory cell MC_C[1,1], and a memory cell MC_D[1,1]. The circuit UC[m, 1] includes, for example, a memory cell MC_A[m,1], a memory cell MC_B[m, 1], a memory cell MC_C[m, 1], and a memory cell MC_D[m,1]. The circuit UC[1,n] includes, for example, a memory cell MC_A[1,n], a memory cell MC_B[1,n], a memory cell MC_C[1,n], and a memory cell MC_D[1,n]. The circuit UC[m,n] includes, for example, a memory cell MC_A[m,n], a memory cell MC_B[m,n], a memory cell MC_C[m,n], and a memory cell MC_D[m,n].

Note that in this specification and the like, when an address in the matrix of the cell array portion CAP is expressed, variables (e.g., alphabets) are sometimes used like the i-th row and the j-th column. For example, in the case where the circuit UC positioned in the i-th row and the j-th column (i is an integer greater than or equal to 1 and less than or equal to m and j is an integer greater than or equal to 1 and less than or equal to n) is described, the circuit UC is denoted as a circuit UC[i,j] using i and j.

In the circuit UC[i,j], a memory cell MC_A[i,j], a memory cell MC_B[i,j], a memory cell MC_C[i,j], and a memory cell MC_D[i,j] are electrically connected to a wiring BL[j]. The memory cell MC_A[i,j] is electrically connected to a wiring WL_A[i], the memory cell MC_B[i,j] is electrically connected to the wiring WL_B[i], the memory cell MC_C[i,j] is electrically connected to the wiring WL_C[i], and the memory cell MC_D[i,j] is electrically connected to the wiring WL_D[i].

The wiring BL has a function of a write bit line and a read bit line for the circuit UC, for example. Specifically, the wiring BL has a function of a write bit line and a read bit line for each of the memory cell MC_A, the memory cell MC_B, the memory cell MC_C, and the memory cell MC_D that are included in the circuit UC.

The wiring WL_A, the wiring WL_B, the wiring WL_C, and the wiring WL_D each have a function of a word line for the circuit UC, for example. Specifically, the wiring WL_A has a function of a word line for the memory cell MC_A included in the circuit UC. Similarly, the wiring WL_B has a function of a word line for the memory cell MC_B included in the circuit UC. Similarly, the wiring WL_C has a function of a word line for the memory cell MC_C included in the circuit UC. Similarly, the wiring WL_D has a function of a word line for the memory cell MC_D included in the circuit UC.

Each of the memory cells MC_A to MC_D is a memory cell capable of retaining 1-bit digital data, for example. That is, the circuit UC includes four memory cells of the memory cell MC_A to the memory cell MC_D, and thus functions as a memory circuit capable of retaining 4-bit (2⁴-level=16-level) digital data. Specifically, for example, in the case where 4-bit data is written to the circuit UC, the memory cell MC_A retains data of the lower zeroth bit (of the upper third bit, the first digit from the right in the four digits), the memory cell MC_B retains data of the lower first bit (of the upper second bit, the second digit from the right in the four digits), the memory cell MC_C retains data of the lower second bit (of the upper first bit, the third digit from the right in the four digits), and the memory cell MC_D retains data of the lower third bit (of the upper zeroth bit, the fourth digit from the right in the four digits). In other words, it can be said that lower bit data is retained in a memory cell including a capacitor with a small capacitance value, and higher bit data is retained in a memory cell including a capacitor with a large capacitance value.

Note that the structure of the circuit UC of the memory device of one embodiment of the present invention is not limited thereto. For example, data that can be retained in the circuit UC may have 1 bit (2-level), 2 bits (22-level=4-level), or 3 bits (23-level=8-level). That is, the number of memory cells included in the circuit UC may be one, two, or three. Alternatively, data that can be retained in the memory cell included in the circuit UC may have 5 bit (25-level=32-level) or more. That is, the number of memory cells included in the circuit UC may be five or more.

As described above, the number of bits of data that can be retained in the circuit UC of the memory device of one embodiment of the present invention can be determined depending on the number of memory cells included in the circuit UC. Note that in this embodiment, the circuit UC including four memory cells as in the memory device MDV illustrated in FIG. 1 is described.

The driver circuit WBD has a function of a write bit line driver circuit for transmitting writing data signals to the plurality of circuits UC included in the cell array portion CAP, for example.

In particular, the driver circuit WBD transmits 1-bit data signals one by one to the wiring BL when 4-bit data is written to the circuit UC, for example. Note that specific operation of writing data to the circuit UC is described later.

The driver circuit RBD has a function of a read bit line driver circuit for reading data signals read from the plurality of circuits UC included in the cell array portion CAP, for example.

In particular, the driver circuit RBD reads an analog potential of the wiring BL in accordance with data read from all the memory cells of the circuit UC, for example. Note that specific operation of reading data from the circuit UC is described later.

The driver circuit WD functions as a write word line driver circuit for selecting the circuit UC, to which data is written, from the plurality of circuits UC included in the cell array portion CAP at the time of data writing, for example. The driver circuit WD also functions as a read word line driver circuit for selecting the circuit UC, from which data is read, from the plurality of circuits UC included in the cell array portion CAP at the time of data reading, for example.

Specifically, in writing, the driver circuit WD transmits selection signals sequentially to the memory cell MC_A to the memory cell MC_D included in the circuit UC in order to write data to each of them, for example. In reading, the driver circuit WD concurrently transmits selection signals to the memory cell MC_A to the memory cell MC_D included in the circuit UC in order to read data from each of them. In other words, the driver circuit WD has a function of transmitting the selection signal to one of the plurality of wirings WL (the wiring WL_A[1] to the wiring WL_A[m], the wiring WL_B[1] to the wiring WL_B[m], the wiring WL_C[1] to the wiring WL_C[m], and the wiring WL_D[1] to the wiring WL_D[m]) and a function of concurrently transmitting the selection signals to a group of a wiring WL_A[k] to a wiring WL_D[k] (k is an integer greater than or equal to 1 and less than or equal to m). Note that it is also possible that in reading, the driver circuit WD does not transmit selection signals concurrently but transmits a selection signal to one of the plurality of wirings WL (the wiring WL_A[1] to the wiring WL_A[m], the wiring WL_B[1] to the wiring WL_B[m], the wiring WL_C[1] to the wiring WL_C[m], and the wiring WL_D[1] to the wiring WL_D[m]).

Next, circuit structure examples of the memory cell MC_A to the memory cell MC_D included in the circuit UC are described.

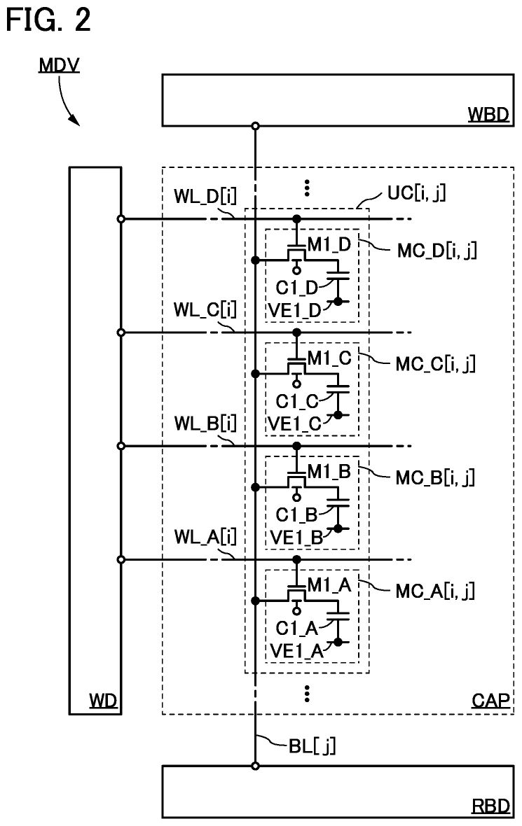

FIG. 2 is a circuit diagram illustrating structure examples of the memory cell MC_A to the memory cell MC_D included in the circuit UC in the memory device MDV illustrated in FIG. 1. In particular, the circuit UC[i,j] included in the cell array portion CAP is selectively illustrated in FIG. 2. FIG. 2 illustrates the memory cell MC_A[i,j], the memory cell MC_B[i,j], the memory cell MC_C[i,j], and the memory cell MC_D[i,j] as the memory cells included in the circuit UC[i,j].

The memory cell MC_A[i,j] includes a transistor M1_A and a capacitor C1_A. The memory cell MC_B[i,j] includes a transistor M1_B and a capacitor C1_B. The memory cells MC_C[i,j] include a transistor M1_C and a capacitor C1_C. The memory cell MC_D[i,j] includes a transistor M1_D and a capacitor C1_D.

For example, an OS transistor is preferably used as each of the transistor M1_A to the transistor M1_D. Specifically, examples of a metal oxide included in a channel formation region of the OS transistor include indium oxide, gallium oxide, and zinc oxide. The metal oxide preferably includes one or more kinds selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO). Note that the OS transistor will be described in detail in Embodiment 3.

A transistor other than the OS transistor may be used as each of the transistor M1_A to the transistor M1_D. For example, a transistor including silicon in a channel formation region (hereinafter referred to as a Si transistor) can be used as each of the transistor M1_A to the transistor M1_D. As the silicon, single crystal silicon, amorphous silicon (sometimes referred to as hydrogenated amorphous silicon), microcrystalline silicon, or polycrystalline silicon (including low-temperature poly silicon (LTPS)) can be used, for example.

Examples of a transistor that can be used as each of the transistor M1_A to the transistor M1_D other than the OS transistor and the Si transistor include a transistor including germanium in a channel formation region, a transistor including a compound semiconductor, such as zinc selenide, cadmium sulfide, gallium arsenide, indium phosphide, gallium nitride, or silicon germanium, in a channel formation region, a transistor including a carbon nanotube in a channel formation region, and a transistor including an organic semiconductor in a channel formation region.

Although each of the transistor M1_A to the transistor M1_D illustrated in FIG. 2 is an n-channel transistor, each of the transistor M1_A to the transistor M1_D may be a p-channel transistor depending on conditions or circumstances. In the case where the n-channel transistor is replaced with a p-channel transistor, a potential input to the circuit UC needs to be changed as appropriate so that the circuit UC operates normally. Note that the same applies to transistors described in other parts of the specification and transistors illustrated in the drawings other than FIG. 2. In this embodiment, the structure and operation of the circuit UC are described on the assumption that each of the transistor M1_A to the transistor M1_D is an n-channel transistor.

In FIG. 2, each of the transistor M1_A to the transistor M1_D includes a back gate.

Specifically, each of the transistor M1_A to the transistor M1_D illustrated in FIG. 2 is a transistor including gates above and below a channel, for example. Thus, the transistor M1_A to the transistor M1_D each include a first gate and a second gate. For convenience, the first gate is referred to as a gate (sometimes referred to as a front gate) and the second gate is referred to as a back gate, but the first gate and the second gate can be interchanged. Therefore, in this specification and the like, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to a first wiring and a gate is electrically connected to a second wiring”.

Each of the memory cell MC_A to the memory cell MC_D in the memory device of one embodiment of the present invention do not depend on the connection structure of a back gate of a transistor. In FIG. 2, the back gates of the transistor M1_A the transistor to M1_D are illustrated. The connection structures of the back gates are not illustrated, and the destinations to which the back gates are electrically connected can be determined at the design stage. For example, in a transistor including a back gate, a gate and the back gate may be electrically connected to each other to increase the on-state current of the transistor. In other words, for example, the gate and back gate of the transistor M1_A may be electrically connected. Alternatively, for example, in a transistor including a back gate, a wiring electrically connected to an external circuit may be provided and a fixed potential or a variable potential may be supplied to the back gate of the transistor with the external circuit to change the threshold voltage of the transistor or to reduce the off-state current of the transistor. Note that the same applies to a transistor described in other parts of the specification and a transistor illustrated in other drawings than FIG. 2.

In the memory cell MC_A[i,j], a first terminal of the transistor M1_A is electrically connected to the wiring BL[j], a second terminal of the transistor M1_A is electrically connected to a first terminal of the capacitor C1_A, and the gate of the transistor M1_A is electrically connected to the wiring WL_A[i]. A second terminal of the capacitor C1_A is electrically connected to a wiring VE1_A.

In the memory cell MC_B[i,j], a first terminal of the transistor M1_B is electrically connected to the wiring BL[j], a second terminal of the transistor M1_B is electrically connected to a first terminal of the capacitor C1_B, and the gate of the transistor M1_B is electrically connected to the wiring WL_B[i]. A second terminal of the capacitor C1_B is electrically connected to a wiring VE1_B.

In the memory cell MC_C[i,j], a first terminal of the transistor M1_C is electrically connected to the wiring BL[j], a second terminal of the transistor M1_C is electrically connected to a first terminal of the capacitor C1_C, and the gate of the transistor M1_C is electrically connected to the wiring WL_C[i]. A second terminal of the capacitor C1_C is electrically connected to a wiring VE1_C.

In the memory cell MC_D[i,j], a first terminal of the transistor M1_D is electrically connected to the wiring BL[j], a second terminal of the transistor M1_D is electrically connected to a first terminal of the capacitor C1_D, and the gate of the transistor M1_D is electrically connected to the wiring WL_D[i]. A second terminal of the capacitor C1_D is electrically connected to a wiring VE1_D.

The wiring VE1_A, the wiring VE1_B, the wiring VE1_C, and the wiring VE1_D each have a function of a wiring supplying a fixed potential, for example. The fixed potential can be, for example, a high-level potential, a low-level potential, the ground potential, or a negative potential. The fixed potentials supplied from the wiring VE1_A to the wiring VE1_D may be equal to or different from one another. Alternatively, some of the potentials supplied from the wiring VE1_A to the wiring VE1_D may be equal and the other of the potentials may be different. In addition, one or more selected from the wiring VE1_A to the wiring VE1_D may have a function of a wiring supplying not a fixed potential but a variable potential (e.g., a pulse potential).

The capacitor C1_A has a function of retaining a voltage corresponding to a data signal of the lower zeroth bit (of the upper third bit, the first digit from the right in the four digits) of 4-bit digital data, for example. The capacitor C1_B has a function of retaining a voltage corresponding to a data signal of the lower first bit (of the upper second bit, the second digit from the right in the four digits) of the 4-bit digital data, for example. The capacitor C1_C has a function of retaining a voltage corresponding to a data signal of the lower second bit (of the upper first bit, the third digit from the right in the four digits) of the 4-bit digital data, for example. The capacitor C1_D has a function of retaining a voltage corresponding to a data signal of the lower third bit (of the upper zeroth bit, the fourth digit from the right in the four digits) of the 4-bit digital data, for example.

The capacitance value of the capacitor C1_B is preferably approximately twice as large as the capacitance value of the capacitor C1_A. The capacitance value of the capacitor C1_C is preferably approximately four times as large as the capacitance value of the capacitor C1_A. The capacitance value of the capacitor C1_D is preferably approximately eight times as large as the capacitance value of the capacitor C1_A. In other words, the ratio of the capacitance values of the capacitor C1_A, the capacitor C1_B, the capacitor C1_C, and the capacitor C1_D is preferably approximately C1_A:C1_B:C1_C:C1_D=1:2:4:8.

That is, when the capacitance value of the capacitor C1_A is Cᵤₜ, the capacitance values of the capacitor C1_B, the capacitor C1_C, and the capacitor C1_D are preferably 2 Cᵤₜ, 4 Cᵤₜ, and 8 Cᵤₜ, respectively.

Note that the capacitance value of each of the capacitor C1_A to the capacitor C1_D included in the circuit UC might have an error because of a variation in the process or the like in the manufacturing stage of the circuit UC. Therefore, the capacitance value Cᵤₜ of the capacitor C1_A, the capacitance value 2 Cᵤₜ of the capacitor C1_B, the capacitance value 4 Cᵤₜ of the capacitor C1_C, and the capacitance value 8 Cᵤₜ of the capacitor C1_D are preferably greater than or equal to 0.9 times and less than or equal to 1.1 times, further preferably greater than or equal to 0.95 times and less than or equal to 1.05 times, still further preferably greater than or equal to 0.99 times and less than or equal to 1.01 times respective desired values.

For example, when the capacitance value of the capacitor C1_A is Cᵤₜ, the capacitance value of the capacitor C1_B is preferably greater than or equal to 1.8 times and less than or equal to 2.2 times Cᵤₜ, further preferably greater than or equal to 1.9 times and less than or equal to 2.1 times Cᵤₜ, still further preferably greater than or equal to 1.98 times and less than or equal to 2.02 times Cᵤₜ. For example, the capacitance value of the capacitor C1_C is preferably greater than or equal to 3.6 times and less than or equal to 4.4 times Cᵤₜ, further preferably greater than or equal to 3.8 times and less than or equal to 4.2 times Cᵤₜ, still further preferably greater than or equal to 3.96 times and less than or equal to 4.04 times Cᵤₜ. For example, the capacitance value of the capacitor C1_D is preferably greater than or equal to 7.2 times and less than or equal to 8.8 times Cᵤₜ, further preferably greater than or equal to 7.6 times and less than or equal to 8.4 times Cᵤₜ, still further preferably greater than or equal to 7.92 times and less than or equal to 8.08 times Cᵤₜ.

Note that description in this embodiment is made on the assumption that there is no error in the capacitance value of each of the capacitor C1_A to the capacitor C1_D.

The memory cell MC_A including the capacitor C1_A whose capacitance value is Cᵤₜ retains a value of the zeroth bit (the first digit from the right in four digits) of the 4-bit digital data written to the circuit UC. The memory cell MC_B including the capacitor C1_B whose capacitance value is 2 Cᵤₜ retains a value of the first bit (the second digit from the right in the four digits) of the 4-bit digital data written to the circuit UC. The memory cell MC_C including the capacitor C1_C whose capacitance value is 4 Cᵤₜ retains a value of the second bit (the third digit from the right in the four digits) of the 4-bit digital data written to the circuit UC. The memory cell MC_D including the capacitor C1_D whose capacitance value is 8 Cᵤₜ retains a value of the third bit (the fourth digit from the right in the four digits) of the 4-bit digital data written to the circuit UC.

### <Operation Example 1 of Memory Device>

Next, an example of a writing operation method of the memory device MDV illustrated in FIG. 2 is described.

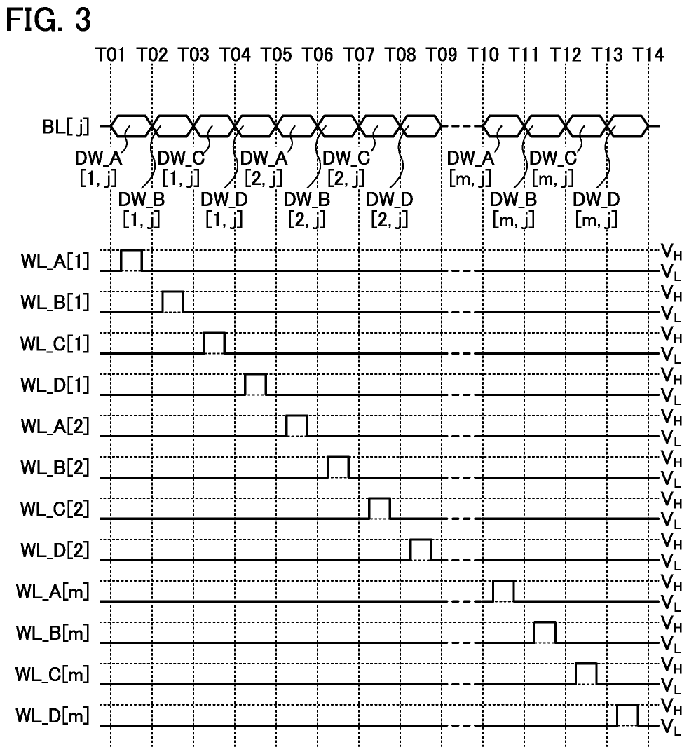

FIG. 3 is a timing chart showing an example of the writing operation of the memory device MDV. The timing chart in FIG. 3 shows changes in potentials of the wiring BL[j], the wiring WL_A[1], the wiring WL_B[1], the wiring WL_C[1], the wiring WL_D[1], the wiring WL_A[2], the wiring WL_B[2], the wiring WL_C[2], the wiring WL_D[2], the wiring WL_A[m], the wiring WL_B[m], the wiring WL_C[m], and the wiring WL_D[m] from Time T01 to Time T14 and around the period.

Note that in the timing chart in FIG. 3, a high-level potential is denoted by V_{H} and a low-level potential is denoted by V_{L}.

In the timing chart in FIG. 3, 4-bit digital data is written to a circuit UC[1,j] from Time T01 to Time T05. Specifically, as the 4-bit digital data, data DW_A[1,j], data DW_B[1,j], data DW_C[1,j], and data DW_D[1, j] are written to a memory cell MC_A[1,j], a memory cell MC_B[1,j], a memory cell MC_C[1,j], and a memory cell MC_D[1,j], respectively. Similarly, as the 4-bit digital data, data DW_A[2,j], data DW_B[2,j], data DW_C[2,j], and data DW_D[2,j] are written to a memory cell MC_A[2,j], a memory cell MC_B[2,j], a memory cell MC_C[2,j], and a memory cell MC_D[2,j] that are included in a circuit UC[2,j], respectively, from Time 05 to Time 09. Similarly, as the 4-bit digital data, data DW_A[m,j], data DW_B[m,j], data DW_C[m,j], and data DW_D[m,j] are written to a memory cell MC_A[m,j], a memory cell MC_B[m,j], a memory cell MC_C[m,j], and a memory cell MC_D[m,j] that are included in a circuit UC[m,j], respectively, from Time 10 to Time 14.

### [From Time T01 to Time T02]

From Time T01 to Time T02, the driver circuit WBD outputs the data DW_A[1,j] to the wiring BL[j]. The data DW_A[1,j] can be 1-bit data, e.g., a high-level potential or a low-level potential.

The driver circuit WD outputs a high-level potential to the wiring WL_A[1]. The driver circuit WD outputs a low-level potential to each of the wiring WL_A[2] to the wiring WL_A[m], the wiring WL_B[1] to the wiring WL_B[m], the wiring WL_C[1] to the wiring WL_C[m], and the wiring WL_D[1] to the wiring WL_D[m].

Since the potential of the wiring WL_A[1] is a high-level potential, the high-level potential is input to the gate of the transistor M1_A in the memory cell MC_A[1,j] included in the circuit UC[1,j]. Accordingly, the transistor M1_A in the memory cell MC_A[1,j] is turned on. When the transistor M1_A in the memory cell MC_A[1,j] is turned on, the data DW_A[1,j] supplied to the wiring BL[j] is written to the first terminal of the capacitor C1_A in the memory cell MC_A[1,j].

Meanwhile, since the potential of each of the wiring WL_A[2] to the wiring WL_A[m] is a low-level potential, the low-level potential is supplied to the gate of the transistor M1_A included in each of the memory cell MC_A[2,j] to the memory cell MC_A[m,j]. Thus, the transistor M1_A included in each of the memory cell MC_A[2,j] to the memory cell MC_A[m,j] is turned off. Accordingly, the data DW_A[1,j] supplied to the wiring BL[j] is not written to the first terminal of the capacitor C1_A in each of the memory cell MC_A[2,j] to the memory cell MC_A[m,j]. Similarly, since the potential of each of the wiring WL_B[1] to the wiring WL_B[m], the wiring WL_C[1] to the wiring WL_C[m], and the wiring WL_D[1] to the wiring WL_D[m] is a low-level potential, the data DW_A[1,j] supplied to the wiring BL[j] is not written to each of the memory cell MC_B[1, j] to the memory cell MC_B[m,j], the memory cell MC_C[1,j] to the memory cell MC_C[m,j], and the memory cell MC_D[1,j] to the memory cell MC_D[m,j].

After the data DW_A[1,j] is written to the memory cell MC_A[1,j] of the circuit UC[1,j], the potential of the wiring WL_A[1] is changed to a low-level potential. Accordingly, a low-level potential is input to the gate of the transistor M1_A of the memory cell MC_A[1,j] in the circuit UC[1,j], and the transistor M1_A of the memory cell MC_A[1,j] is turned off. Thus, the data DW_A[1,j] is retained in the memory cell MC_A[1,j] of the circuit UC[1,j].

### [From Time T02 to Time T03]

From Time T02 to Time T03, the driver circuit WBD outputs the data DW_B[1,j] to the wiring BL[j]. The data DW_B[1,j] can be 1-bit data like the data DW_A[1,j], e.g., a high-level potential or a low-level potential.

The driver circuit WD outputs a high-level potential to the wiring WL_B[1]. The driver circuit WD outputs a low-level potential to each of the wiring WL_A[1] to the wiring WL_A[m], the wiring WL_B[2] to the wiring WL_B[m], the wiring WL_C[1] to the wiring WL_C[m], and the wiring WL_D[1] to the wiring WL_D[m].

Since the potential of the wiring WL_B[1] is a high-level potential, the high-level potential is input to the gate of the transistor M1_B in the memory cell MC_B[1,j] included in the circuit UC[1,j]. Accordingly, the transistor M1_B in the memory cell MC_B[1,j] is turned on. When the transistor M1_B in the memory cell MC_B[1,j] is turned on, the data DW_B[1,j] supplied to the wiring BL[j] is written to the first terminal of the capacitor C1_B in the memory cell MC_B[1,j].

Meanwhile, since the potential of each of the wiring WL_B[2] to the wiring WL_B[m] is a low-level potential, the low-level potential is supplied to the gate of the transistor M1_B included in each of the memory cell MC_B[2,j] to the memory cell MC_B[m,j]. Thus, the transistor M1_B included in each of the memory cell MC_B[2,j] to the memory cell MC_B[m,j] is turned off. Accordingly, the data DW_B[1,j] supplied to the wiring BL[j] is not written to the first terminal of the capacitor C1_B in each of the memory cell MC_B[2,j] to the memory cell MC_B[m,j]. Similarly, since the potential of each of the wiring WL_A[1] to the wiring WL_A[m], the wiring WL_C[1] to the wiring WL_C[m], and the wiring WL_D[1] to the wiring WL_D[m] is a low-level potential, the data DW_B[1, j] supplied to the wiring BL[j] is not written to each of the memory cell MC_A[1,j] to the memory cell MC_A[m,j], the memory cell MC_C[1,j] to the memory cell MC_C[m,j], and the memory cell MC_D[1,j] to the memory cell MC_D[m,j].

After the data DW_B[1,j] is written to the memory cell MC_B[1,j] of the circuit UC[1,j], the potential of the wiring WL_B[1] is changed to a low-level potential. Accordingly, a low-level potential is input to the gate of the transistor M1_B of the memory cell MC_B[1,j] in the circuit UC[1,j], and the transistor M1_B of the memory cell MC_B[1,j] is turned off. Thus, the data DW_B[1,j] is retained in the memory cell MC_B[1,j] of the circuit UC[1,j].

### [From Time T03 to Time T04]

From Time T03 to Time T04, the driver circuit WBD outputs the data DW_C[1,j] to the wiring BL[j]. The data DW_C[1,j] can be 1-bit data like the data DW_A[1,j] and the data DW_B[1, j], e.g., a high-level potential or a low-level potential.

The driver circuit WD outputs a high-level potential to the wiring WL_C[1]. The driver circuit WD outputs a low-level potential to each of the wiring WL_A[1] to the wiring WL_A[m], the wiring WL_B[1] to the wiring WL_B[m], the wiring WL_C[2] to the wiring WL_C[m], and the wiring WL_D[1] to the wiring WL_D[m].

Since the potential of the wiring WL_C[1] is a high-level potential, the high-level potential is input to the gate of the transistor M1_C in the memory cell MC_C[1,j] included in the circuit UC[1,j]. Accordingly, the transistor M1_C in the memory cell MC_C[1,j] is turned on. When the transistor M1_C in the memory cell MC_C[1,j] is turned on, the data DW_C[1,j] supplied to the wiring BL[j] is written to the first terminal of the capacitor C1_C in the memory cell MC_C[1,j].

Meanwhile, since the potential of each of the wiring WL_C[2] to the wiring WL_C[m] is a low-level potential, the low-level potential is supplied to the gate of the transistor M1_C included in each of the memory cell MC_C[2,j] to the memory cell MC_C[m,j]. Thus, the transistor M1_C included in each of the memory cell MC_C[2,j] to the memory cell MC_C[m,j] is turned off. Accordingly, the data DW_C[1,j] supplied to the wiring BL[j] is not written to the first terminal of the capacitor C1_C in each of the memory cell MC_C[2,j] to the memory cell MC_C[m,j]. Similarly, since the potential of each of the wiring WL_A[1] to the wiring WL_A[m], the wiring WL_B[1] to the wiring WL_B[m], and the wiring WL_D[1] to the wiring WL_D[m] is a low-level potential, the data DW_C[1, j] supplied to the wiring BL[j] is not written to each of the memory cell MC_A[1,j] to the memory cell MC_A[m,j], the memory cell MC_B[1,j] to the memory cell MC_B[m,j], and the memory cell MC_D[1,j] to the memory cell MC_D[m,j].

After the data DW_C[1,j] is written to the memory cell MC_C[1,j] of the circuit UC[1,j], the potential of the wiring WL_C[1] is changed to a low-level potential. Accordingly, a low-level potential is input to the gate of the transistor M1_C of the memory cell MC_C[1,j] in the circuit UC[1,j], and the transistor M1_C of the memory cell MC_C[1,j] is turned off. Thus, the data DW_C[1,j] is retained in the memory cell MC_C[1,j] of the circuit UC[1,j].

### [From Time T04 to Time T05]

From Time T04 to Time T05, the driver circuit WBD outputs the data DW_D[1,j] to the wiring BL[j]. The data DW_D[1,j] can be 1-bit data like the data DW_A[1,j], the data DW_B[1,j], and the data DW_C[1,j], e.g., a high-level potential or a low-level potential.

The driver circuit WD outputs a high-level potential to the wiring WL_D[1]. The driver circuit WD outputs a low-level potential to each of the wiring WL_A[1] to the wiring WL_A[m], the wiring WL_B[1] to the wiring WL_B[m], the wiring WL_C[1] to the wiring WL_C[m], and the wiring WL_D[2] to the wiring WL_D[m].

Since the potential of the wiring WL_D[1] is a high-level potential, the high-level potential is input to the gate of the transistor M1_D in the memory cell MC_D[1,j] included in the circuit UC[1,j]. Accordingly, the transistor M1_D in the memory cell MC_D[1,j] is turned on. When the transistor M1_D in the memory cell MC_D[1,j] is turned on, the data DW_D[1,j] supplied to the wiring BL[j] is written to the first terminal of the capacitor C1_D in the memory cell MC_D[1,j].

Meanwhile, since the potential of each of the wiring WL_D[2] to the wiring WL_D[m] is a low-level potential, the low-level potential is supplied to the gate of the transistor M1_D included in each of the memory cell MC_D[2,j] to the memory cell MC_D[m,j]. Thus, the transistor M1_D included in each of the memory cell MC_D[2,j] to the memory cell MC_D[m,j] is turned off. Accordingly, the data DW_D[1,j] supplied to the wiring BL[j] is not written to the first terminal of the capacitor C1_D in each of the memory cell MC_D[2,j] to the memory cell MC_D[m,j]. Similarly, since the potential of each of the wiring WL_A[1] to the wiring WL_A[m], the wiring WL_B[1] to the wiring WL_B[m], and the wiring WL_C[1] to the wiring WL_C[m] is a low-level potential, the data DW_D[1,j] supplied to the wiring BL[j] is not written to each of the memory cell MC_A[1,j] to the memory cell MC_A[m,j], the memory cell MC_B[1,j] to the memory cell MC_B[m,j], and the memory cell MC_C[1,j] to the memory cell MC_C[m,j].

After the data DW_D[1,j] is written to the memory cell MC_D[1,j] of the circuit UC[1,j], the potential of the wiring WL_D[1] is changed to a low-level potential. Accordingly, a low-level potential is input to the gate of the transistor M1_D of the memory cell MC_D[1,j] in the circuit UC[1,j], and the transistor M1_D of the memory cell MC_D[1,j] is turned off. Thus, the data DW_D[1, j] is retained in the memory cell MC_D[1,j] of the circuit UC[1,j].

The above-described operation from Time T01 to Time T05 is performed, whereby the data DW_A[1,j], the data DW_B[1,j], the data DW_C[1,j], and the data DW_D[1,j] are written as the 4-bit digital data to the circuit UC[1,j] of the memory device MDV.

### [From Time T05 to Time T09]

From Time T05 to Time T09, 4-bit digital data is written to the circuit UC[2,j].

Specifically, as the 4-bit digital data, the data DW_A[2,j], the data DW_B[2,j], the data DW_C[2,j], and the data DW_D[2,j] are written to the memory cell MC_A[2,j], the memory cell MC_B[2,j], the memory cell MC_C[2,j], and the memory cell MC_D[2,j], respectively. Note that the data DW_A[2,j], the data DW_B[2,j], the data DW_C[2,j], and the data DW_D[2,j] can each be 1-bit data, e.g., a high-level potential or a low-level potential.

From Time T05 to Time T06, the driver circuit WBD outputs the data DW_A[2,j] to the wiring BL[j]. The driver circuit WD outputs a high-level potential to the wiring WL_A[2]. The driver circuit WD outputs a low-level potential to each of the wiring WL_A[1] to the wiring WL_A[m] excluding the wiring WL_A[2], the wiring WL_B[1] to the wiring WL_B[m], the wiring WL_C[1] to the wiring WL_C[m], and the wiring WL_D[1] to the wiring WL_D[m]. By such operation, the data DW_A[2,j] can be written to the memory cell MC_A[2,j] of the circuit UC[2,j]. For the specific operation of writing the data DW_A[2,j] to the memory cell MC_A[2,j], the above operation example from Time T01 to Time T02 can be referred to, for example.

From Time T06 to Time T07, the driver circuit WBD outputs the data DW_B[2,j] to the wiring BL[j]. The driver circuit WD outputs a high-level potential to the wiring WL_B[2]. The driver circuit WD outputs a low-level potential to each of the wiring WL_A[1] to the wiring WL_A[m], the wiring WL_B[1] to the wiring WL_B[m] excluding the wiring WL_B[2], the wiring WL_C[1] to the wiring WL_C[m], and the wiring WL_D[1] to the wiring WL_D[m]. By such operation, the data DW_B[2,j] can be written to the memory cell MC_B[2,j] in the circuit UC[2,j]. For the specific operation of writing the data DW_B[2,j] to the memory cell MC_B[2,j], the above operation example from Time T02 to Time T03 can be referred to, for example.

From Time T07 to Time T08, the driver circuit WBD outputs the data DW_C[2,j] to the wiring BL[j]. The driver circuit WD outputs a high-level potential to the wiring WL_C[2]. The driver circuit WD outputs a low-level potential to each of the wiring WL_A[1] to the wiring WL_A[m], the wiring WL_B[1] to the wiring WL_B[m], the wiring WL_C[1] to the wiring WL_C[m] excluding the wiring WL_C[2], and the wiring WL_D[1] to the wiring WL_D[m]. By such operation, the data DW_C[2,j] can be written to the memory cell MC_C[2,j] in the circuit UC[2,j]. For the specific operation of writing the data DW_C[2,j] to the memory cell MC_C[2,j], the above operation example from Time T03 to Time T04 can be referred to, for example.

From Time T08 to Time T09, the driver circuit WBD outputs the data DW_D[2,j] to the wiring BL[j]. The driver circuit WD outputs a high-level potential to the wiring WL_D[2]. The driver circuit WD outputs a low-level potential to each of the wiring WL_A[1] to the wiring WL_A[m], the wiring WL_B[1] to the wiring WL_B[m], the wiring WL_C[1] to the wiring WL_C[m], and the wiring WL_D[1] to the wiring WL_D[m] excluding the wiring WL_D[2]. By such operation, the data DW_D[2,j] can be written to the memory cell MC_D[2,j] in the circuit UC[2,j]. For the specific operation of writing the data DW_D[2,j] to the memory cell MC_D[2,j], the above operation example from Time T04 to Time T05 can be referred to, for example.

The above-described operation from Time T05 to Time T09 is performed, whereby the data DW_A[2,j], the data DW_B[2,j], the data DW_C[2,j], and the data DW_D[2,j] are written as the 4-bit digital data to the circuit UC[2,j] of the memory device MDV.

### [From Time T09 to Time T10]

From Time T09 to Time T10, 4-bit digital data is sequentially written to a circuit UC[3,j] to a circuit UC[m−1,j]. Note that for the writing of the digital data to the circuits UC, the above description of the operation of writing the digital data to the circuit UC[1,j] (the operation from Time T01 to Time T05) or the above description of the operation of writing the digital data to the circuit UC[2,j] (the operation from Time T05 to Time T09) can be referred to.

### [From Time T10 to Time T14]

From Time T10 to Time T14, 4-bit digital data is written to the circuit UC[m,j]. Specifically, as the 4-bit digital data, the data DW_A[m,j], the data DW_B[m,j], the data DW_C[m,j], and the data DW_D[m,j] are written to the memory cell MC_A[m,j], the memory cell MC_B[m,j], the memory cell MC_C[m,j], and the memory cell MC_D[m,j], respectively. Note that the data DW_A[m,j], the data DW_B[m,j], the data DW_C[m,j], and the data DW_D[m,j] can each be 1-bit data, e.g., a high-level potential or a low-level potential.

For the writing of the digital data to the circuit UC[m,j], the above description of the operation of writing the digital data to the circuit UC[1,j] (the operation from Time T01 to Time T05) or the above description of the operation of writing the digital data to the circuit UC[2,j] (the operation from Time T06 to Time T09) can be referred to.

### <Operation Example 2 of Memory Device>

Next, an example of a reading operation method of the memory device MDV illustrated in FIG. 2 is described.

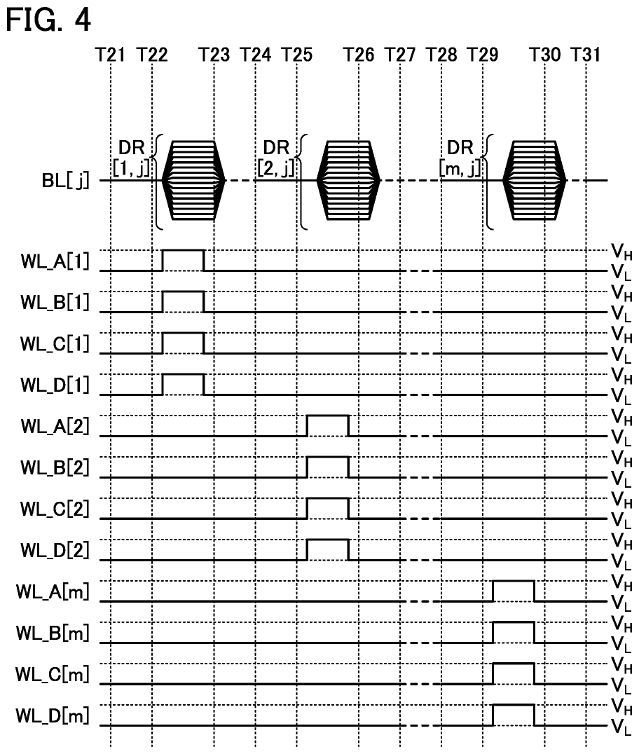

FIG. 4 is a timing chart showing an example of the reading operation of the memory device MDV. The timing chart in FIG. 4 shows changes in potentials of the wiring BL[j], the wiring WL_A[1], the wiring WL_B[1], the wiring WL_C[1], the wiring WL_D[1], the wiring WL_A[2], the wiring WL_B[2], the wiring WL_C[2], the wiring WL_D[2], the wiring WL_A[m], the wiring WL_B[m], the wiring WL_C[m], and the wiring WL_D[m] from Time T21 to Time T31 and around the period.

Note that in the timing chart in FIG. 4, a high-level potential is denoted by V_{H} and a low-level potential is denoted by V_{L} as in the timing chart in FIG. 3.

In the timing chart in FIG. 4, 4-bit (16-level) data DR[1,j] is read from the circuit UC[1,j] from Time T21 to Time T24. Note that the data DR[1,j] corresponds to the data DW_A[1,j] to the data DW_D[1,j] respectively written to the memory cell MC_A[1,j] to the memory cell MC_D[1,j] from Time T01 to Time T05 in the timing chart in FIG. 3. Similarly, 4-bit (16-level) data DR[2,j] is read from the circuit UC[2,j] from Time T24 to Time T27. Note that the data DR[2,j] corresponds to the data DW_A[2,j] to the data DW_D[2,j] respectively written to the memory cell MC_A[2,j] to the memory cell MC_D[2,j] from Time T05 to Time T09 in the timing chart in FIG. 3. Similarly, 4-bit (16-level) data DR[m,j] is read from the circuit UC[m,j] from Time T28 to Time T31. Note that the data DR[m,j] corresponds to the data DW_A[m,j] to the data DW_D[m,j] respectively written to the memory cell MC_A[m,j] to the memory cell MC_D[m,j] from Time T10 to Time T14 in the timing chart in FIG. 3.

### [From Time T21 to Time T22]

From Time T21 to Time T22, the driver circuit RBD supplies V_{P} as a potential to the wiring BL[j] as prior operation for reading data from the circuit UC[1,j]. Note that V_{P} can be, for example, a potential half of the sum of the high-level potential and the low-level potential in the wiring BL[j]. After V_{P} is supplied to the wiring BL[j], the driver circuit RBD and the driver circuit WBD bring the wiring BL[j] into a floating state. That is, from Time T21 to Time T22, the wiring BL[j] is precharged with V_{P}.

### [From Time T22 to Time T23]

From Time T22 to Time T23, the driver circuit WD outputs a high-level potential to each of the wiring WL_A[1], the wiring WL_B[1], the wiring WL_C[1], and the wiring WL_D[1]. The driver circuit WD outputs a low-level potential to each of the wiring WL_A[2] to the wiring WL_A[m], the wiring WL_B[2] to the wiring WL_B[m], the wiring WL_C[2] to the wiring WL_C[m], and the wiring WL_D[2] to the wiring WL_D[m].

Since the potential of the wiring WL_A[1] is a high-level potential, the high-level potential is input to the gate of the transistor M1_A in the memory cell MC_A[1,j] included in the circuit UC[1,j]. Accordingly, the transistor M1_A in the memory cell MC_A[1,j] is turned on. Similarly, since the potential of the wiring WL_B[1] is a high-level potential, the high-level potential is input to the gate of the transistor M1_B in the memory cell MC_B[1,j] included in the circuit UC[1,j]. Accordingly, the transistor M1_B in the memory cell MC_B[1,j] is turned on. Similarly, since the potential of the wiring WL_C[1] is a high-level potential, the high-level potential is input to the gate of the transistor M1_C in the memory cell MC_C[1,j] included in the circuit UC[1,j]. Accordingly, the transistor M1_C in the memory cell MC_C[1,j] is turned on. Similarly, since the potential of the wiring WL_D[1] is a high-level potential, the high-level potential is input to the gate of the transistor M1_D in the memory cell MC_D[1,j] included in the circuit UC[1,j]. Accordingly, the transistor M1_D in the memory cell MC_D[1,j] is turned on.

Meanwhile, since the potential of each of the wiring WL_A[2] to the wiring WL_A[m] is a low-level potential, the low-level potential is supplied to the gate of the transistor M1_A included in each of the memory cell MC_A[2,j] to the memory cell MC_A[m,j]. Thus, the transistor M1_A included in each of the memory cell MC_A[2,j] to the memory cell MC_A[m,j] is turned off. Similarly, since the potential of each of the wiring WL_B[2] to the wiring WL_B[m] is a low-level potential, the low-level potential is supplied to the gate of the transistor M1_B included in each of the memory cell MC_B[2,j] to the memory cell MC_B[m,j]. Thus, the transistor M1_B included in each of the memory cell MC_B[2,j] to the memory cell MC_B[m,j] is turned off. Similarly, since the potential of each of the wiring WL_C[2] to the wiring WL_C[m] is a low-level potential, the low-level potential is supplied to the gate of the transistor M1_C included in each of the memory cell MC_C[2,j] to the memory cell MC_C[m,j]. Thus, the transistor M1_C included in each of the memory cell MC_C[2,j] to the memory cell MC_C[m,j] is turned off. Similarly, since the potential of each of the wiring WL_D[2] to the wiring WL_D[m] is a low-level potential, the low-level potential is supplied to the gate of the transistor M1_D included in each of the memory cell MC_D[2,j] to the memory cell MC_D[m,j]. Thus, the transistor M1_D included in each of the memory cell MC_D[2,j] to the memory cell MC_D[m,j] is turned off.

Accordingly, electrical continuity is not established between the wiring BL[j] and the first terminal of the capacitor C1_A in each of the memory cell MC_A[2,j] to the memory cell MC_A[m,j]. Electrical continuity is not established between the wiring BL[j] and the first terminal of the capacitor C1_B in each of the memory cell MC_B[2,j] to the memory cell MC_B[m,j]. Electrical continuity is not established between the wiring BL[j] and the first terminal of the capacitor C1_C in each of the memory cell MC_C[2,j] to the memory cell MC_C[m,j]. Electrical continuity is not established between the wiring BL[j] and the first terminal of the capacitor C1_D in each of the memory cell MC_D[2,j] to the memory cell MC_D[m,j].

As described above, the transistors M1_A to M1_D of the respective memory cells MC_A[1,j] to MC_D[1, j] included in the circuit UC[1,j] are turned on, whereby charges are redistributed between the wiring BL[j] and the first terminal of the capacitor C1_A in the memory cell MC_A[1, j], the first terminal of the capacitor C1_B in the memory cell MC_B[1,j], the first terminal of the capacitor C1_C in the memory cell MC_C[1,j], and the first terminal of the capacitor C1_D in the memory cell MC_D[1,j]. Specifically, the first terminals of the capacitor C1_A to the capacitor C1_D and the wiring BL[j] ideally have equivalent potentials. The potential level is determined depending on the amount of charge retained in the first terminals of the capacitor C1_A to the capacitor C1_D and the wiring BL[j]. Note that in the case where a low-level potential is a reference potential, the potential level is determined depending on the amount of charge retained in the first terminals of the capacitor C1_A to the capacitor C1_D.

The capacitance values of the capacitor C1_A to the capacitor C1_D are Cᵤₜ, 2 Cᵤₜ, 4 Cᵤₜ, and 8 Cᵤₜ, respectively. When a constant potential supplied from each of the wiring VE1_A to the wiring VE1_D is a low-level potential and a high-level potential (V_{H}) is written to each of the memory cell MC_A[1,j] to the memory cell MC_D[1,j], the amounts of charge retained in the capacitor C1_A to the capacitor C1_D are Cᵤₜ V_{H}, 2 Cᵤₜ V_{H}, 4 Cᵤₜ V_{H}, and 8 Cᵤₜ V_{H}, respectively. When a low-level potential is written to each of the memory cell MC_A[1,j] to the memory cell MC_D[1,j], the amount of charge retained in each of the capacitor C1_A to the capacitor C1_D is 0. When one of the high-level potential and the low-level potential is written to each of the memory cell MC_A[1,j] to the memory cell MC_D[1,j], the amounts of charge retained in the whole circuit UC[1,j] are the following 16 types: 0, Cᵤₜ V_{H}, 2 Cᵤₜ V_{H}, 3 Cᵤₜ V_{H}, 4 Cᵤₜ V_{H}, 5 Cᵤₜ V_{H}, 6 Cᵤₜ V_{H}, 7 Cᵤₜ V_{H}, 8 Cᵤₜ V_{H}, 9 Cᵤₜ V_{H}, 10 Cᵤₜ V_{H}, 11 Cᵤₜ V_{H}, 12 Cᵤₜ V_{H}, 13 Cᵤₜ V_{H}, 14 Cᵤₜ V_{H}, and 15 Cᵤₜ V_{H}.

Therefore, in the above operation from Time T22 to Time T23, by the charge redistribution between the wiring BL[j] and the first terminal of the capacitor C1_A in the memory cell MC_A[1,j], the first terminal of the capacitor C1_B in the memory cell MC_B[1,j], the first terminal of the capacitor C1_C in the memory cell MC_C[1,j], and the first terminal of the capacitor C1_D in the memory cell MC_D[1,j], the potential of the wiring BL[j] is one of the 16 types as shown in the timing chart in FIG. 4. In this operation example, data corresponding to the potential is data DR[1,j] read from the circuit UC[1,j].

From Time T22 to Time T23, after the charge redistribution between the wiring BL[j] and the first terminal of the capacitor C1_A in the memory cell MC_A[1,j], the first terminal of the capacitor C1_B in the memory cell MC_B[1,j], the first terminal of the capacitor C1_C in the memory cell MC_C[1,j], and the first terminal of the capacitor C1_D in the memory cell MC_D[1, j], the driver circuit WD outputs a low-level potential to each of the wiring WL_A[1], the wiring WL_B[1], the wiring WL_C[1], and the wiring WL_D[1]. Accordingly, the transistor M1_A of the memory cell MC_A[1,j], the transistor M1_B of the memory cell MC_B[1,j], the transistor M1_C of the memory cell MC_C[1,j], and the transistor M1_D of the memory cell MC_D[1, j] are turned off.

When the potential of the wiring BL[j] is a potential corresponding to the data DR[1,j], the driver circuit RBD reads the value of the data DR[1,j] with reference to the potential. As described above, by the operation from Time T21 to Time T23, the data DR[1,j] can be read from the circuit UC[1,j].

### [From Time T23 to Time T24]

The memory cell MC_A[1,j] to the memory cell MC_D[1,j] in the circuit UC[1,j] each have a DRAM structure; thus, when data is read once, data retained in the capacitor C1_A to the capacitor C1_D is lost (destructive reading).

Thus, from Time T23 to Time T24, data is rewritten to each of the memory cell MC_A[1,j] to the memory cell MC_D[1,j] in the circuit UC[1,j] in order to recover the lost data. Note that the operation from Time T01 to Time T05 in the timing chart in FIG. 3 can be referred to for the method for writing data to each of the memory cell MC_A[1,j] to the memory cell MC_D[1, j] in the circuit UC[1,j].

### [From Time T24 to Time T27]

From Time T24 to Time T27, the data DR[2,j] is read from the circuit UC[2,j].

From Time T24 to Time T25, the driver circuit RBD supplies a low-level potential to the wiring BL[j] as prior operation for reading data from the circuit UC[2,j]. After the low-level potential is supplied to the wiring BL[j], the driver circuit RBD and the driver circuit WBD bring the wiring BL[j] into a floating state. That is, from Time T24 to Time T25, the wiring BL[j] is precharged with the low-level potential.

From Time T25 to Time T26, the driver circuit WD outputs a high-level potential to each of the wiring WL_A[2], the wiring WL_B[2], the wiring WL_C[2], and the wiring WL_D[2]. The driver circuit WD outputs a low-level potential to each of the wiring WL_A[1] to the wiring WL_A[m] excluding the wiring WL_A[2], the wiring WL_B[1] to the wiring WL_B[m] excluding the wiring WL_B[2], the wiring WL_C[1] to the wiring WL_C[m] excluding the wiring WL_C[2], and the wiring WL_D[1] to the wiring WL_D[m] excluding the wiring WL_D[2]. By such operation, the data DR[2,j] can be read from each of the memory cell MC_A[1,j] to the memory cell MC_D[1,j] in the circuit UC[2,j]. Note that for the specific operation of reading the data DR[2,j] from each of the memory cell MC_A[1,j] to the memory cell MC_D[1,j], the above operation example from Time T22 to Time T23 can be referred to.

From Time T26 to Time T27, the data lost by the destructive reading from Time T25 to Time T26 is rewritten to each of the memory cell MC_A[2,j] to the memory cell MC_D[2,j] in the circuit UC[2,j]. Note that the operation from Time T05 to Time T09 in the timing chart in FIG. 3 can be referred to for the method for writing data to each of the memory cell MC_A[2,j] to the memory cell MC_D[2,j] in the circuit UC[2,j].

### [From Time T27 to Time T28]

From Time T27 to Time T28, data is read from the circuit UC[3,j] to the circuit UC[m−1,j] sequentially. Note that for the reading of data from the circuits UC, the above description of the operation of reading data from the circuit UC[1,j] (the operation from Time T21 to Time T24) or the above description of the operation of reading data from the circuit UC[2,j] (the operation from Time T24 to Time T27) can be referred to.

### [From Time T28 to Time T31]

From Time T28 to Time T31, the data DR[m,j] is read from the circuit UC[m,j].

Note that for the reading of the data from the circuit UC[m,j] from Time T29 to Time T30, the above description of the operation of reading the data from the circuit UC[1,j] (the operation from Time T21 to Time T24) or the above description of the operation of reading the data from the circuit UC[2,j] (the operation from Time T24 to Time T27) can be referred to.

From Time T30 to Time T31, the data lost by the destructive reading from Time T29 to Time T30 is rewritten to each of the memory cell MC_A[m,j] to the memory cell MC_D[m,j] in the circuit UC[m,j]. Note that the operation from Time T10 to Time T14 in the timing chart in FIG. 3 can be referred to for the method for writing data to each of the memory cell MC_A[m,j] to the memory cell MC_D[m,j] in the circuit UC[m,j].

As described above, in the operation of reading data from the circuit UC included in the memory device MDV is performed by selecting the memory cell MC_A to the memory cell MC_D included in the circuit UC not one by one but concurrently. Thus, the time required for reading data from the circuit UC in the memory device MDV shown in the timing chart in FIG. 4 can be shorter than the time required for reading data from the memory cell MC_A to the memory cell MC_D individually. Thus, by performing the reading operation shown in the timing chart in FIG. 4, the reading speed in the memory device MDV can be higher than that in a conventional manner.

Note that in the timing chart in FIG. 4, the 4-bit data retained in the circuit UC is read by concurrently selecting all the memory cell MC_A to the memory cell MC_D included in the circuit UC; however, the reading operation may be performed by selecting one of the memory cell MC_A to the memory cell MC_D. For example, one of the memory cell MC_A to the memory cell MC_D may be selected and may perform 1-bit data writing and reading on the separately selected memory cell.

In particular, the capacitance values of the capacitors C1 in the memory cell MC_A to the memory cell MC_D are different from each other; thus, in accordance with the access frequency of retained 1-bit data, which one of the memory cell MC_A to the memory cell MC_D retains the data may be determined. For example, in the case where data writing speed is desired to be increased, a memory cell with a small capacitance value (e.g., the memory cell MC_A or the memory cell MC_B) is used. For example, in the case where data reading speed is desired to be increased, a memory cell with a large capacitance value (e.g., the memory cell MC_C or the memory cell MC_D) is used. For example, in the case where data is desired to be retained for a long time, a memory cell with a large capacitance value (e.g., the memory cell MC_C or the memory cell MC_D) is used.

In particular, in the memory device of one embodiment of the present invention, in the case where 1-bit data, not multi-bit data, is written and read, the ratio of the capacitance values of the capacitors in the memory cell MC_A to the memory cell MC_D is not limited to approximately 1:2:4:8, and another ratio may be employed. For example, the ratio of the capacitance values of the capacitors in the memory cell MC_A to the memory cell MC_D may be approximately 1:2:3:4 or approximately 1:1:8:8. In such a manner, when a capacitor with a small capacitance value or a capacitor with a large capacitance value is included in a plurality of memory cells stacked, which one of the memory cell MC_A to the memory cell MC_D retains data can be selected in accordance with the access frequency of the data described above.

### <Structure Example 2 of Memory Device>

The memory device of one embodiment of the present invention is not limited to the structure example in FIG. 1 and FIG. 2. The memory device of one embodiment of the present invention may have a structure obtained by changing the memory device MDV illustrated in FIG. 1 and FIG. 2.

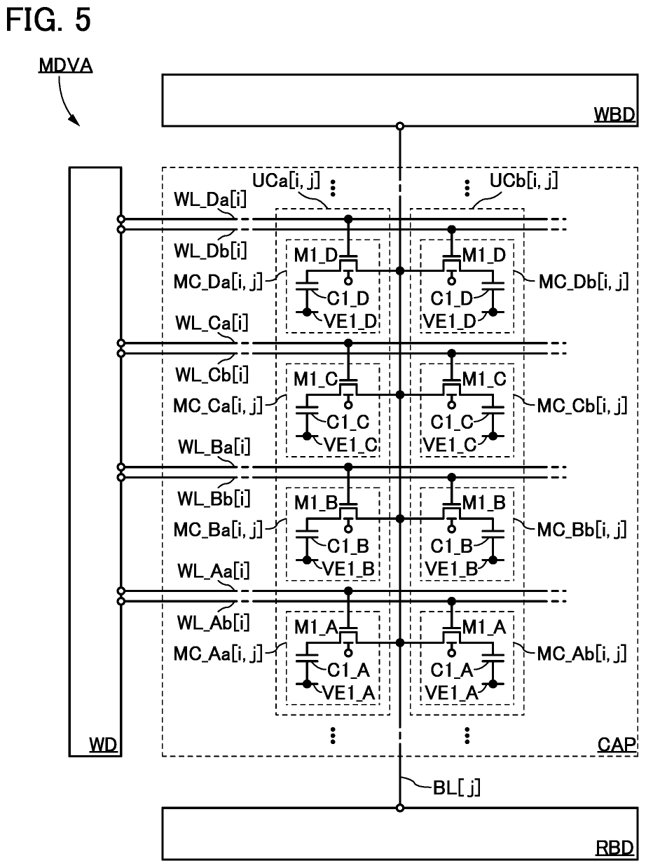

FIG. 5 is a circuit diagram obtained by changing the memory device MDV in FIG. 1 and FIG. 2, for example. A memory device MDVA illustrated in FIG. 5 is different from the memory device MDV in FIG. 1 and FIG. 2 in that a circuit UCa[i,j] and a circuit UCb[i,j] are electrically connected to the wiring BL[j] extending in one column.

Specifically, the circuit UCa[i,j] and the circuit UCb[i,j] are positioned in the i-th row and the j-th column of the cell array portion CAP of the memory device MDVA. Thus, in the case where the cell array portion CAP has a matrix of m rows and n columns, the total number of circuits UCa and UCb in the cell array portion CAP is m×2n.

The circuit UCa[i,j] includes, for example, a memory cell MC_Aa[i,j], a memory cell MC_Ba[i,j], a memory cell MC_Ca[i,j], and a memory cell MC_Da[i,j]. The circuit UCb[i,j] includes, for example, a memory cell MC_Ab[i,j], a memory cell MC_Bb[i,j], a memory cell MC_Cb[i,j], and a memory cell MC_Db[i,j]. For the structures of the memory cell MC_Aa[i,j] and the memory cell MC_Ab[i,j], the description of the memory cell MC_A[i,j] in FIG. 2 can be referred to. Similarly, for the structures of the memory cell MC_Ba[i,j] and the memory cell MC_Bb[i,j], the description of the memory cell MC_B[i,j] in FIG. 2 can be referred to; for the structures of the memory cell MC_Ca[i,j] and the memory cell MC_Cb[i,j], the description of the memory cell MC_C[i,j] in FIG. 2 can be referred to; and for the structures of the memory cell MC_Da[i,j] and the memory cell MC_Db[i,j], the description of the memory cell MC_D[i,j] in FIG. 2 can be referred to.

A wiring WL_Aa[i] and a wiring WL_Ab[i] in FIG. 5 correspond to the wiring WL_A[i] in FIG. 2. Similarly, a wiring WL_Ba[i] and a wiring WL_Bb[i] in FIG. 5 correspond to the wiring WL_B[i] in FIG. 2; a wiring WL_Ca[i] and a wiring WL_Cb[i] in FIG. 5 correspond to the wiring WL_C[i] in FIG. 2; and a wiring WL_Da[i] and a wiring WL_Db[i] in FIG. 5 correspond to the wiring WL_D[i] in FIG. 2.

The gate of the transistor M1_A of the memory cell MC_Aa[i,j] is electrically connected to the wiring WL_Aa[i], and the gate of the transistor M1_A of the memory cell MC_Ab[i,j] is electrically connected to the wiring WL_Ab[i]. Similarly, the gate of the transistor M1_B of the memory cell MC_Ba[i,j] is electrically connected to the wiring WL_Ba[i], and the gate of the transistor M1_B of the memory cell MC_Bb[i,j] is electrically connected to the wiring WL_Bb[i]. Similarly, the gate of the transistor M1_C of the memory cell MC_Ca[i,j] is electrically connected to the wiring WL_Ca[i], and the gate of the transistor M1_C of the memory cell MC_Cb[i,j] is electrically connected to the wiring WL_Cb[i]. Similarly, the gate of the transistor M1_D of the memory cell MC_Da[i,j] is electrically connected to the wiring WL_Da[i], and the gate of the transistor M1_D of the memory cell MC_Db[i,j] is electrically connected to the wiring WL_Db[i].

As in the above description and FIG. 5, since the memory cell MC_Aa[i,j] and the memory cell MC_Ab[i,j] are respectively electrically connected to the wiring WL_Aa[i] and the wiring WL_Ab[i], which are wirings different from each other, on/off switching control of the transistor M1_A in the memory cell MC_Aa[i,j] and on/off switching control of the transistor M1_A in the memory cell MC_Ab[i,j] can be independently performed. The same applies to the transistor M1_B to the transistor M1_D included in the circuit UCa[i,j] and the transistor M1_B to the transistor M1_D included in the circuit UCb[i,j].

Therefore, for example, when data is written to the circuit UCa[i,j], only the circuit UCa[i,j] can be selected as a memory circuit to which the data is written in the following manner: non-selection signals (low-level potentials) are supplied from the driver circuit WD to the wiring WL_Ab[i] to the wiring WL_Db[i] to turn off the transistor M1_A to the transistor M1_D included in the circuit UCb[i,j], and selection signals (high-level potentials) are sequentially supplied from the driver circuit WD to the wiring WL_Aa[i] to the wiring WL_Da[i] to sequentially turn on the transistor M1_A to the transistor M1_D included in the circuit UCa[i,j].

For example, when data is read from the circuit UCb[i,j], only the circuit UCb[i,j] can be selected as a memory circuit from which the data is read in the following manner: non-selection signals (low-level potentials) are supplied from the driver circuit WD to the wiring WL_Aa[i] to the wiring WL_Da[i] to turn off the transistor M1_A to the transistor M1_D included in the circuit UCa[i,j], and selection signals (high-level potentials) are concurrently supplied from the driver circuit WD to the wiring WL_Ab[i] to the wiring WL_Db[i] to concurrently turn on the transistor M1_A to the transistor M1_D included in the circuit UCb[i,j].

### <Cross-Sectional Structure Example 1 of Memory Device>

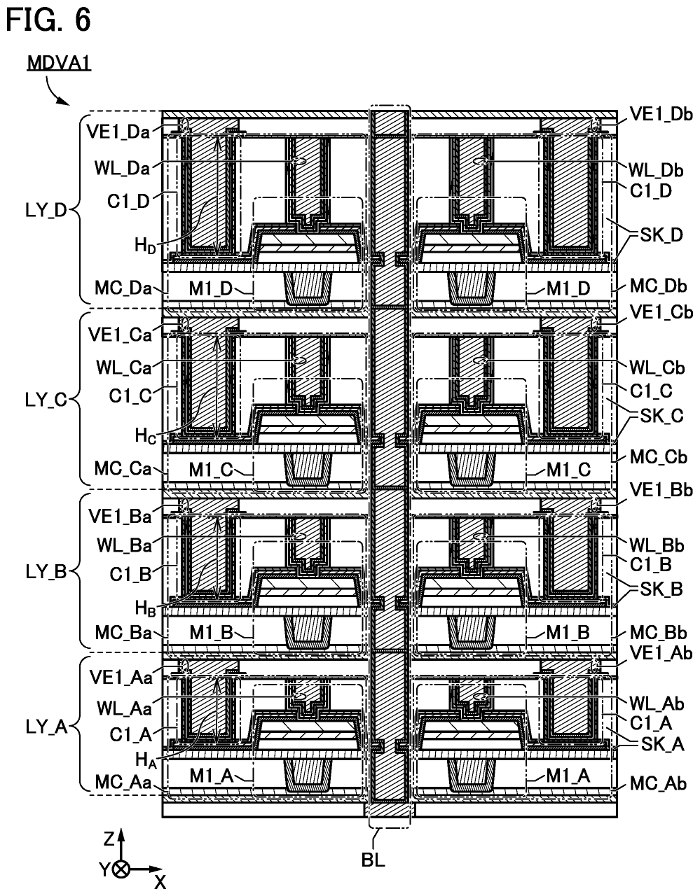

Here, an example of a cross-sectional structure of the memory device MDVA in FIG. 5 is described. FIG. 6 is a schematic cross-sectional view of a memory device MDVA1, which is an example of the memory device MDVA in FIG. 5.

Note that in the schematic cross-sectional view in FIG. 6, arrows showing the X direction, the Y direction, and the Z direction are added. Here, the X direction, the Y direction, and the Z direction are shown as directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The memory device MDVA1 includes a layer LY_A, a layer LY_B, a layer LY_C, and a layer LY_D. The layer LY_B is positioned above the layer LY_A, the layer LY_C is positioned above the layer LY_B, and the layer LY_D is positioned above the layer LY_C.

The layer LY_A includes the memory cell MC_Aa and the memory cell MC_Ab, the layer LY_B includes the memory cell MC_Ba and the memory cell MC_Bb, the layer LY_C includes the memory cell MC_Ca and the memory cell MC_Cb, and the layer LY_D includes the memory cell MC_Da and the memory cell MC_Db.

Each of the memory cell MC_Aa and the memory cell MC_Ab includes the transistor M1_A and the capacitor C1_A. Each of the memory cell MC_Ba and the memory cell MC_Bb includes the transistor M1_B and the capacitor C1_B. Each of the memory cell MC_Ca and the memory cell MC_Cb includes the transistor M1_C and the capacitor C1_C. Each of the memory cell MC_Da and the memory cell MC_Db includes the transistor M1_D and the capacitor C1_D. In particular, the transistor M1_A to the transistor M1_D are preferably positioned in their respective regions overlapping with each other. The capacitor C1_A to the capacitor C1_D are preferably positioned in their respective regions overlapping with each other.

In particular, FIG. 6 is a schematic cross-sectional view of the transistor M1_A to the transistor M1_D in the channel length direction. Each of the transistor M1_A to the transistor M1_D includes a stacked body of an island-shaped first insulator and an island-shaped semiconductor, and a pair of first conductors are positioned on the side surface of the first insulator and the top and side surfaces of the semiconductor. A stacked body of a second insulator and a second conductor is positioned between the pair of first conductors. A third insulator is positioned below the stacked body of the island-shaped first insulator and the island-shaped semiconductor, and a third conductor is positioned in a region, below the third insulator, overlapping with the stacked body of the second insulator and the second conductor.

Note that in each of the transistor M1_A to the transistor M1_D, one of the pair of first conductors functions as one of a source electrode and a drain electrode, and the other of the pair of first conductors functions as the other of the source electrode and the drain electrode. The second conductor functions as a first gate electrode (sometimes simply referred to as a gate electrode), and the second insulator functions as a first gate insulating film. The third conductor functions as a second gate electrode (sometimes referred to as a back gate electrode), and part or the whole of each of the first insulator and the third insulator functions as a second gate insulator (sometimes referred to as a back gate insulator).

Note that the details of the transistor M1_A to the transistor M1_D are described in Embodiment 3.

In each of the layer LY_A to the layer LY_D, the one of the pair of first conductors is positioned in part of a region over the third insulator. In the region, a stacked body of a fourth conductor, a fourth insulator, and a fifth conductor is positioned over part of a region of the one of the pair of first conductors. In particular, in the region, the fourth conductor functions as one of a pair of electrodes of the capacitor C1_A (the capacitor C1_B, the capacitor C1_C, or the capacitor C1_D), the fifth conductor functions as the other of the pair of electrodes of the capacitor C1_A (the capacitor C1_B, the capacitor C1_C, or the capacitor C1_D), and the fourth insulator functions as a dielectric included in the capacitor C1_A (the capacitor C1_B, the capacitor C1_C, or the capacitor C1_D).

Note that the details of the capacitor C1_A to the capacitor C1_D are described in Embodiment 3.

In the layer LY_A, an insulating layer SK_A is positioned over the first conductor and the third insulator. Similarly, an insulating layer SK_B is positioned over the first conductor and the third insulator in the layer LY_B, an insulating layer SK_C is positioned over the first conductor and the third insulator in the layer LY_C, and an insulating layer SK_D is positioned over the first conductor and the third insulator in the layer LY_D. Note that in FIG. 6, the insulating layer SK_A to the insulating layer SK_D each have a stacked-layer structure of a barrier insulator (corresponding to an insulator 275 to be described later) protecting a lower conductor (corresponding to a conductor 242a and a conductor 242b to be described later) and an interlayer film (corresponding to an insulator 280 to be described later).

Each of the insulating layer SK_A to the insulating layer SK_D includes a first opening and a second opening. In each of the insulating layer SK_A to the insulating layer SK_D, the stacked body of the second insulator and the second conductor is embedded in the first opening, and the stacked body of the fourth conductor, the fourth insulator, and the fifth conductor is embedded in the second opening. That is, it can be said that at least part of the capacitor C1 is included inside the second opening in each of the insulating layer SK_A to the insulating layer SK_D.

In particular, in FIG. 6, the first opening is preferably formed along the Y direction (the channel width direction of the transistor M1_A to the transistor M1_D). For example, when the first opening is formed along the Y direction, the second conductor can be formed along the Y direction.

Thus, for example, in the memory cell MC_Aa of the layer LY_A, the second conductor functions as not only the first gate electrode of the transistor M1_A but also the wiring WL_Aa. Similarly, for example, in the memory cell MC_Ab of the layer LY_A, the second conductor functions as not only the first gate electrode of the transistor M1_A but also the wiring WL_Ab.

For example, in the memory cell MC_Ba of the layer LY_B, the second conductor functions as not only the first gate electrode of the transistor M1_B but also the wiring WL_Ba. Similarly, for example, in the memory cell MC_Bb of the layer LY_B, the second conductor functions as not only the first gate electrode of the transistor M1_B but also the wiring WL_Bb.

For example, in the memory cell MC_Ca of the layer LY_C, the second conductor functions as not only the first gate electrode of the transistor M1_C but also the wiring WL_Ca. Similarly, for example, in the memory cell MC_Cb of the layer LY_C, the second conductor functions as not only the first gate electrode of the transistor M1_C but also the wiring WL_Cb.

For example, in the memory cell MC_Da of the layer LY_D, the second conductor functions as not only the first gate electrode of the transistor M1_D but also the wiring WL_Da. Similarly, for example, in the memory cell MC_Db of the layer LY_D, the second conductor functions as not only the first gate electrode of the transistor M1_D but also the wiring WL_Db.

The second opening in FIG. 6 can have, for example, a cylindrical shape, a polygonal shape (including a polygonal shape with rounded corners), or the like in a top view. Accordingly, the capacitor C1_A to the capacitor C1_D included in the memory device MDVA1 can each be a trench capacitor. Note that in this specification and the like, the second opening is rephrased as a trench in a capacitor in some cases.

The fifth conductor is positioned above the second opening of each of the insulating layer SK_A to the insulating layer SK_D. In particular, the fifth conductor positioned above the second opening is preferably formed along the Y direction. Accordingly, the fifth conductor positioned above the second opening also functions as the wiring VE1 (a wiring VE1_Aa to a wiring VE1_Da or a wiring VE1_Ab to a wiring VE1_Db).

Each of the layer LY_A to the layer LY_D includes a third opening. Specifically, for example, in the layer LY_A, the third opening is formed in a region including the other of the pair of first conductors included in the memory cell MC_Aa and the other of the pair of first conductors included in the memory cell MC_Ab. Similarly, in the layer LY_B, the third opening is formed in a region including the other of the pair of first conductors included in the memory cell MC_Ba and the other of the pair of first conductors included in the memory cell MC_Bb; in the layer LY_C, the third opening is formed in a region including the other of the pair of first conductors included in the memory cell MC_Ca and the other of the pair of first conductors included in the memory cell MC_Cb; and in the layer LY_D, the third opening is formed in a region including the other of the pair of first conductors included in the memory cell MC_Da and the other of the pair of first conductors included in the memory cell MC_Db. Specifically, the third openings of the layer LY_A to the layer LY_D are formed to overlap with each other.

In each of the layer LY_A to the layer LY_D, a sixth conductor is embedded in the third opening. Thus, electrical continuity is established between the other of the pair of first conductors included in each of the memory cell MC_Aa to the memory cell MC_Da and the sixth conductor of each of the layer LY_A to the layer LY_D. Similarly, electrical continuity is established between the other of the pair of first conductors included in each of the memory cell MC_Ab to the memory cell MC_Db and the sixth conductor of each of the layer LY_A to the layer LY_D. This can form the wiring BL electrically connected to the second terminals of the transistor M1_A to the transistor M1_D.

In the memory device MDVA1 in FIG. 6, the length of the second opening in the insulating layer SK_A (the trench length in the capacitor C1_A) is referred to as H_{A}, the length of the second opening in the insulating layer SK_B (the trench length in the capacitor C1_B) is referred to as H_{B}, the length of the second opening in the insulating layer SK_C (the trench length in the capacitor C1_C) is referred to as H_{C}, and the length of the second opening in the insulating layer SK_D (the trench length in the capacitor C1_D) is referred to as H_{D}.

Note that in the memory device MDVA1 in FIG. 6, for example, H_{A} can be the vertical distance from the bottom surface of the fourth conductor to the top surface of the insulating layer SK_A in the second opening of the insulating layer SK_A. Similarly, for example, H_{B} can be the vertical distance from the bottom surface of the fourth conductor to the top surface of the insulating layer SK_B in the second opening of the insulating layer SK_B. Similarly, for example, H_{C} can be the vertical distance from the bottom surface of the fourth conductor to the top surface of the insulating layer SK_C in the second opening of the insulating layer SK_C. For example, H_{D} can be the vertical distance from the bottom surface of the fourth conductor to the top surface of the insulating layer SK_D in the second opening of the insulating layer SK_D.

In H_{A}, H_{B}, H_{C}, and H_{D} in the memory device MDVA1, H_{A} is the shortest, H_{B} is the second shortest, He is the second longest, and H_{D} is the longest. Note that H_{A} is determined in accordance with the thickness of the insulating layer SK_A. Similarly, H_{B} is determined in accordance with the thickness of the insulating layer SK_B, He is determined in accordance with the thickness of the insulating layer SK_C, and H_{D} is determined in accordance with the thickness of the insulating layer SK_D. Therefore, the thickness (the formation time) of the insulating layer SK_D is the largest (the longest), followed in order by those of the insulating layer SK_C, the insulating layer SK_B, and the insulating layer SK_A.

Note that in this case, the thickness of the second conductor included in each of the layer LY_A to the layer LY_D is also determined in accordance with the thicknesses of the insulating layer SK_A to the insulating layer SK_D. Specifically, the thickness of the second conductor of the insulating layer SK_D is the largest, followed in order by those of the second conductor of the insulating layer SK_C, the second conductor of the insulating layer SK_B, and the second conductor of the insulating layer SK_A. As the second conductor has a larger thickness, the resistance of the second conductor becomes lower; thus, power consumption needed for transmitting a signal to the memory cell MC can be reduced. In other words, the power consumption needed for transmitting a signal from the driver circuit WD to the memory cell MC_D is the lowest, the power consumption needed for transmitting a signal from the driver circuit WD to the memory cell MC_C is the second lowest, and the power consumption needed for transmitting a signal from the driver circuit WD to the memory cell MC_B is the third lowest.

The capacitance value of the capacitor C1_A included in the layer LY_A is determined depending on H_{A}. Similarly, the capacitance value of the capacitor C1_B included in the layer LY_B is determined depending on H_{B}, the capacitance value of the capacitor C1_C included in the layer LY_C is determined depending on H_{C}, and the capacitance value of the capacitor C1_D included in the layer LY_D is determined depending on H_{D}. In particular, H_{A} is the shortest, H_{B} is the second shortest, H_{C} is the second longest, and H_{D} is the longest; therefore, when the capacitor C1_A to the capacitor C1_D each include the same dielectric, the capacitance value of the capacitor C1_D is the largest, followed in order by those of the capacitor C1_C, the capacitor C1_B, and the capacitor C1_A.

Thus, as in the description of the capacitor C1_A to the capacitor C1_D in FIG. 2, when the thickness of each of the insulating layer SK_A to the insulating layer SK_D is determined such that the ratio of the capacitance values of the capacitor C1_A to the capacitor C1_D is approximately 1:2:4:8, the circuit UC[i,j] capable of retaining 16-level data can be formed. As described above, one embodiment of the present invention is not limited to the structure of the memory device MDVA1 in FIG. 6, and may be a memory device capable of retaining 2-level data, 4-level data, or 8-level data, for example. Alternatively, for example, a memory device capable of retaining data of 17 or more levels may be provided. Specifically, in the case of 2-level (1-bit) data, for example, the cell array portion CAP includes any one of the layer LY_A to the layer LY_D in the memory device. In the case of 4-level (2-bit) data, for example, the cell array portion CAP includes a set of the layer LY_A and the layer LY_B, a set of the layer LY_B and the layer LY_C, or a set of the layer LY_C and the layer LY_D in the memory device. In the case of 8-level (3-bit) data, the cell array portion CAP includes a set of the layer LY_A, the layer LY_B, and the layer LY_C or a set of the layer LY_B, the layer LY_C, and the layer LY_D. In the case of the 256-level (8-bit) data, which is an example of data of 17 or more levels, the memory device has the ratio of the capacitance values of the capacitors included in eight memory cells of approximately 1:2:4:8:16:32:64:128, and the eight memory cells are stacked.

Specifically, the layer LY_A to the layer LY_D are different from each other only in the thickness of each of the insulating layer SK_A to the insulating layer SK_D, and the other components are substantially the same. Therefore, the layer LY_A to the layer LY_D can be formed with the same layout pattern (a layout pattern does not need to be different between the manufacturing processes of the layer LY_A to the layer LY_D); thus, the manufacturing cost of the memory device MDVA1 can be reduced.

Therefore, for example, the component of the transistor M1_A or the capacitor C1_A included in the layer LY_A and the components of the transistors M1 or the capacitors C1 included in the layer LY_B to the layer LY_D overlap with each other. For example, the semiconductor included in the transistor M1_A and the semiconductors of the transistor M1_B to the transistor M1_D overlap with each other. For example, the first conductor to the third conductor included in the transistor M1_A and the first conductors to the third conductors of the transistor M1_B to the transistor M1_D overlap with each other. For example, the fourth conductor or the fifth conductor of the capacitor C1_A and the fourth conductors or the fifth conductors of the capacitor C1_B to the capacitor C1_D overlap with each other. For example, the dielectric of the capacitor C1_A and the dielectrics of the capacitor C1_B to the capacitor C1_D overlap with each other. For example, the second opening of the insulating layer SK_A and the second openings of the insulating layer SK_B to the insulating layer SK_D overlap with each other.

Note that in the layer LY_A to the layer LY_D, a region where the components of the transistors M1 and the capacitors C1 do not overlap with each other in two layers selected from the layer LY_A to the layer LY_D might be partly generated due to deviation of the layout patterns in the manufacturing process. For example, in the case where there is no deviation in the rotation direction, the deviation amount of the layout patterns of the same components included in the two layers selected from the layer LY_A to the layer LY_D is preferably less than or equal to 5 μm, less than or equal to 1 μm, less than or equal to 500 nm, less than or equal to 100 nm, less than or equal to 50 nm, or less than or equal to 10 nm. Note that the deviation amount is preferably as small as possible, but may be greater than 5 μm depending on the case.

For example, in the case where the layout patterns of the same components included in the two layers selected from the layer LY_A to the layer LY_D deviate from each other in the rotation direction, the deviation amount is preferably less than or equal to 1°, less than or equal to 0.5°, less than or equal to 0.1°, less than or equal to 0.05°, less than or equal to 0.01°, or less than or equal to 0.005°. Note that the deviation amount is preferably as small as possible, but may be greater than 1° depending on the case.

For example, the proportion of the area of a region where the layout patterns of the same components included in the two layers selected from the layer LY_A to the layer LY_D overlap with each other to the area of each of the layout patterns of the components is preferably greater than or equal to 90%, greater than or equal to 95%, greater than or equal to 99%, greater than or equal to 99.9%, greater than or equal to 99.99%, or greater than or equal to 99.999%. Note that the above proportion is preferably as close to 100% as possible, but may be less than 90% depending on the case.

Note that in the memory device MDVA1, the thickness of the insulating layer SK_D is the largest, followed in order by those of the insulating layer SK_C, the insulating layer SK_B, and the insulating layer SK_A; however, the memory device of one embodiment of the present invention is not limited thereto. In other words, although in the memory device MDVA1, the layer LY_A, the layer LY_B, the layer LY_C, and the layer LY_D are stacked in this order from the bottom, the stacking order in the memory device of one embodiment of the present invention is not limited thereto.

For example, the memory device MDVA1 may have a structure in which the layer LY_D, the layer LY_C, the layer LY_B, and the layer LY_A are stacked in this order from the bottom. In this case, the memory device MDVA1 has a structure in which the capacitor C1_D having the largest capacitance value (the thickest insulating layer SK_D), the capacitor C1_C having the second largest capacitance value (the second thickest insulating layer SK_C), the capacitor C1_B having the second smallest capacitance value (the second thinnest insulating layer SK_B), and the capacitor C1_A having the smallest capacitance value (the thinnest insulating layer SK_A) are stacked in this order from the bottom.

In the case where the transistor M1_A to the transistor M1_D are OS transistors, each of the insulating layer SK_A to the insulating layer SK_D preferably includes an insulator with a low hydrogen concentration and a high oxygen concentration. Although described in detail in Embodiment 3, with the use of an insulator with a low hydrogen concentration and a high oxygen concentration for each of the insulating layer SK_A to the insulating layer SK_D, hydrogen can be inhibited from entering from the insulator into an oxide of a channel formation region of the OS transistor and oxygen can be supplied from the insulator to the oxide of the channel formation region of the OS transistor. Thus, the electrical characteristics and reliability of the OS transistor can be favorably maintained.

However, in the manufacturing steps of the insulating layer SK_A to the insulating layer SK_D, heat treatment is performed once or a plurality times; thus, among the insulating layer SK_A to the insulating layer SK_D, the insulating layer at a lower position is subjected to the heat treatment a larger number of times. By the heat treatment, oxygen is released in the insulating layer, and thus the insulating layer at a lower position loses more oxygen in some cases.

Therefore, the layer LY_D that includes the insulating layer SK_D having the largest thickness (having the largest oxygen content), the layer LY_C that includes the insulating layer SK_C having the second largest thickness (having the second largest oxygen content), the layer LY_B that includes the insulating layer SK_B having the second smallest thickness (having the second smallest oxygen content), and the layer LY_A that includes the insulating layer SK_A having the smallest thickness (having the smallest oxygen content) are formed in this order, whereby oxygen depletion in the insulating layer SK_A to the insulating layer SK_D can be inhibited in the manufacturing process of the layer LY_A to the layer LY_D.

Meanwhile, impurities such as hydrogen contained in the insulating layer SK_A to the insulating layer SK_D can be released by heat treatment in the manufacturing process of the insulating layer SK_A to the insulating layer SK_D. In particular, the thicker insulating layer contains the larger amount of impurities; thus, for example, among the insulating layer SK_A to the insulating layer SK_D, the insulating layer at a lower position is preferably subjected to heat treatment a larger number of times.

In view of this, the layer LY_D that includes the insulating layer SK_D having the largest thickness (having the largest oxygen content), the layer LY_C that includes the insulating layer SK_C having the second largest thickness (having the second largest oxygen content), the layer LY_B that includes the insulating layer SK_B having the second smallest thickness (having the second smallest oxygen content), and the layer LY_A that includes the insulating layer SK_A having the smallest thickness (having the smallest oxygen content) are preferably formed in this order. Accordingly, impurities such as hydrogen in the insulating layer SK_A to the insulating layer SK_D can be effectively removed in the manufacturing process of the layer LY_A to the layer LY_D.

In the memory device of one embodiment of the present invention, the layer LY_B, the layer LY_D, the layer LY_A, and the layer LY_C may be stacked in this order from the bottom, for example. That is, the stacking order of the layer LY_A to the layer LY_D in the memory device MDVA1 may be freely determined regardless of the thickness of each of the insulating layer SK_A to the insulating layer SK_D.

### <Cross-Sectional Structure Example 2 of Memory Device>

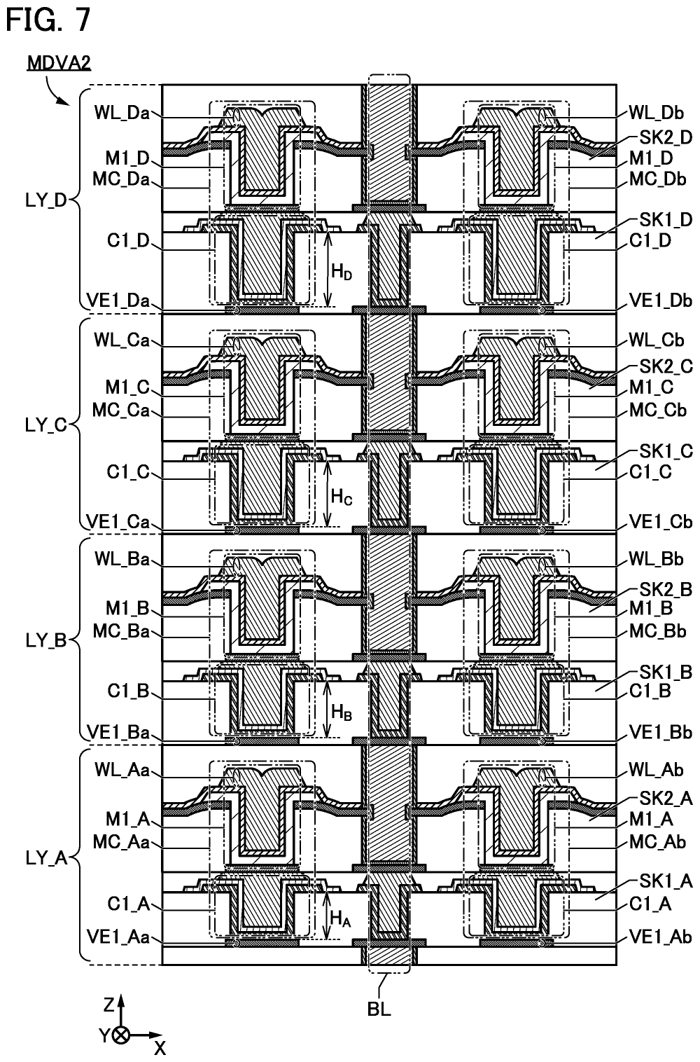

FIG. 7 is a schematic cross-sectional view illustrating an example of the memory device MDVA in FIG. 5 that is different from that in FIG. 6.

In FIG. 7, a memory device MDVA2 includes the layer LY_A to the layer LY_D as in the memory device MDVA1 in FIG. 6. The layer LY_B is positioned above the layer LY_A, the layer LY_C is positioned above the layer LY_B, and the layer LY_D is positioned above the layer LY_C.

As in the memory device MDVA1, in the memory device MDVA2, the layer LY_A includes the memory cell MC_Aa and the memory cell MC_Ab, the layer LY_B includes the memory cell MC_Ba and the memory cell MC_Bb, the layer LY_C includes the memory cell MC_Ca and the memory cell MC_Cb, and the layer LY_D includes the memory cell MC_Da and the memory cell MC_Db.

As in the memory device MDVA1, in the memory device MDVA2, each of the memory cell MC_Aa and the memory cell MC_Ab includes the transistor M1_A and the capacitor C1_A. Each of the memory cell MC_Ba and the memory cell MC_Bb includes the transistor M1_B and the capacitor C1_B. Each of the memory cell MC_Ca and the memory cell MC_Cb includes the transistor M1_C and the capacitor C1_C. Each of the memory cell MC_Da and the memory cell MC_Db includes the transistor M1_D and the capacitor C1_D.

The memory device MDVA2 is different from the memory device MDVA1 in the structure of the transistor included in each of the memory cell MC_A to the memory cell MC_D. In FIG. 7, the transistor included in each of the memory cell MC_A to the memory cell MC_D has a structure in which the source electrode and the drain electrode are positioned at different levels, and a current flowing through a semiconductor layer flows in the height direction. In other words, the channel length direction includes a height (vertical) component, so that the transistor can also be referred to as a vertical field effect transistor (VFET), a vertical transistor, a vertical-channel transistor, or the like.

Note that the details of the transistor M1_A to the transistor M1_D illustrated in FIG. 7 are described in Embodiment 3.

In the memory device MDVA2, the layer LY_A includes an insulating layer SK_A1 and an insulating layer SK_A2 positioned above the insulating layer SK_A1, the layer LY_B includes an insulating layer SK_B1 and an insulating layer SK_B2 positioned above the insulating layer SK_B1, the layer LY_C includes an insulating layer SK_C1 and an insulating layer SK_C2 positioned above the insulating layer SK_C1, and the layer LY_D includes an insulating layer SK_D1 and an insulating layer SK_D2 positioned above the insulating layer SK_D1.

In each of the memory cell MC_Aa and the memory cell MC_Ab in the layer LY_A, the insulating layer SK_A1 includes the first opening in a region where the capacitor C1_A is positioned. A stacked body including the one of the pair of electrodes of the capacitor C1_A, the dielectric of the capacitor C1_A, and the other of the pair of electrodes of the capacitor C1_A is embedded in the first opening. Note that in the stacked body, the other of the pair of electrodes of the capacitor C1_A, the dielectric of the capacitor C1_A, and the one of the pair of electrodes of the capacitor C1_A are stacked in this order. As described here, the capacitor C1_A can be a trench capacitor.

The first conductor functioning as the wiring VE1_Aa extends along the Y direction in the bottom portion of the first opening.

In each of the memory cell MC_Aa and the memory cell MC_Ab in the layer LY_A, the second conductor is formed above the insulating layer SK1_A.

In each of the memory cell MC_Aa and the memory cell MC_Ab in the layer LY_A, the insulating layer SK2_A and the third conductor include the second opening in a region overlapping with the capacitor C1_A. The fourth conductor is positioned over the one of the pair of electrodes of the capacitor C1_A and in the bottom portion of the second opening.

Note that the fourth conductor functions as one of a source and a drain of the transistor M1_A, and the third conductor functions as the other of the source and the drain of the transistor M1_A.

A semiconductor including a channel formation region of the transistor M1_A, an insulator functioning as a gate insulator of the transistor M1_A, and the fifth conductor functioning as the gate electrode of the transistor M1_A are embedded in the second opening. In addition, the semiconductor is formed over part of the second conductor, and the insulator is formed to cover the second conductor and the semiconductor. Accordingly, the transistor M1_A can be formed as a vertical-channel transistor.

In addition, the fifth conductor is also formed above the second opening. In particular, the fifth conductor formed above the second opening extends along the Y direction. Accordingly, the fifth conductor positioned above the second opening functions as the wiring WL_Aa.

The memory cell MC_Ba and the memory cell MC_Bb in the layer LY_B, the memory cell MC_Ca and the memory cell MC_Cb in the layer LY_C, and the memory cell MC_Da and the memory cell MC_Db in the layer LY_D can also have structures similar to those of the memory cell MC_Aa and the memory cell MC_Ab in the layer LY_A.

With the above structure, the transistor M1 is provided above the capacitor C1 in each of the layer LY_A to the layer LY_D.

The layer LY_A includes the third opening between the memory cell MC_Aa and the memory cell MC_Ab. In particular, part of the third conductor functioning as the other of the source and the drain of the transistor M1_A is included inside the third opening. The sixth conductor is embedded in the third opening.

The third openings are provided also between the memory cell MC_Ba and the memory cell MC_Bb in the layer LY_B, between the memory cell MC_Ca and the memory cell MC_Cb in the layer LY_C, and between the memory cell MC_Da and the memory cell MC_Db in the layer LY_D, and the sixth conductors are embedded in the third openings. The sixth conductors of the layer LY_A to the layer LY_D overlap with each other. Thus, electrical continuity is established between the third conductor included in each of the memory cell MC_Aa to the memory cell MC_Da and the sixth conductor of each of the layer LY_A to the layer LY_D. Similarly, electrical continuity is established between the sixth conductor included in each of the memory cell MC_Ab to the memory cell MC_Db and the sixth conductor of each of the layer LY_A to the layer LY_D. This can form the wiring BL electrically connected to the second terminals of the transistor M1_A to the transistor M1_D.

In the memory device MDVA2 in FIG. 7, the length of the first opening in the insulating layer SK1_A is referred to as H_{A}, the length of the first opening in the insulating layer SK1_B is referred to as H_{B}, the length of the first opening in the insulating layer SK1_C is referred to as H_{C}, and the length of the first opening in the insulating layer SK1_D is referred to as H_{D}. In H_{A}, H_{B}, H_{C}, and H_{D} in the memory device MDVA2, H_{A} is the shortest, H_{B} is the second shortest, H_{C} is the second longest, and H_{D} is the longest.

Note that in the memory device MDVA2 in FIG. 7, for example, H_{A} can be the vertical distance from the bottom surface of the one of the pair of electrodes of the capacitor C1_A to the top surface of the insulating layer SK1_A in the first opening of the insulating layer SK1_A. Similarly, for example, H_{B} can be the vertical distance from the bottom surface of the one of the pair of electrodes of the capacitor C1_B to the top surface of the insulating layer SK1_B in the first opening of the insulating layer SK1_B. Similarly, for example, H_{C} can be the vertical distance from the bottom surface of the one of the pair of electrodes of the capacitor C1_C to the top surface of the insulating layer SK1_C in the first opening of the insulating layer SK1_C. Similarly, for example, H_{D} can be the vertical distance from the bottom surface of the one of the pair of electrodes of the capacitor C1_D to the top surface of the insulating layer SK1_D in the first opening of the insulating layer SK1_D.

For the capacitance values of the capacitor C1_A to the capacitor C1_D included in the layer LY_A to the layer LY_D, the description of the capacitor C1_A to the capacitor C1_D included in the layer LY_A to the layer LY_D in the memory device MDVA1 in FIG. 6 can be referred to.

Thus, also in the memory device MDVA2 in FIG. 7, the circuit UC[i,j] capable of retaining 16-level data can be formed.

As described above, one embodiment of the present invention is not limited to the structure of the memory device MDVA2 in FIG. 7, and may be a memory device capable of retaining 2-level data, 4-level data, or 8-level data, for example. Alternatively, for example, a memory device capable of retaining data of 17 or more levels.

Specifically, the layer LY_A to the layer LY_D are different from each other only in the thickness of each of the insulating layer SK1_A to the insulating layer SK1_D, and the other components are substantially the same. Therefore, the layer LY_A to the layer LY_D can be formed with the same layout pattern (a layout pattern does not need to be different between the manufacturing processes of the layer LY_A to the layer LY_D); thus, the manufacturing cost of the memory device MDVA2 can be reduced.

Therefore, for example, the component of the transistor M1_A or the capacitor C1_A included in the layer LY_A and the components of the transistors M1 or the capacitors C1 included in the layer LY_B to the layer LY_D overlap with each other. For example, the semiconductor included in the transistor M1_A and the semiconductors of the transistor M1_B to the transistor M1_D overlap with each other. For example, the third conductor to the fifth conductor included in the transistor M1_A and the third conductors to the fifth conductors of the transistor M1_B to the transistor M1_D overlap with each other. For example, the one of the pair of electrodes of the capacitor C1_A and the one of the pair of electrodes of each of the capacitor C1_B to the capacitor C1_D overlap with each other. For example, the dielectric of the capacitor C1_A and the dielectrics of the capacitor C1_B to the capacitor C1_D overlap with each other. For example, the other of the pair of electrodes of the capacitor C1_A and the other of the pair of electrodes of each of the capacitor C1_B to the capacitor C1_D overlap with each other. For example, the first opening of the insulating layer SK1_A and the first openings of the insulating layer SK1_B to the insulating layer SK1_D overlap with each other. For example, the second opening of the insulating layer SK2_A and the second openings of the insulating layer SK2_B to the insulating layer SK2_D overlap with each other.

Note that in the layer LY_A to the layer LY_D, a region where the components of the transistors M1 and the capacitors C1 do not overlap with each other might be partly generated due to deviation of the layout patterns in the manufacturing process. For example, in the case where there is no deviation in the rotation direction, the deviation amount of the component included in the layer LY_A and the component same as that in the layer LY_A included in any one of the layer LY_B to the layer LY_D is preferably less than or equal to 5 μm, less than or equal to 1 μm, less than or equal to 500 nm, less than or equal to 100 nm, less than or equal to 50 nm, or less than or equal to 10 nm. Note that the deviation amount is preferably as small as possible, but may be greater than 5 μm depending on the case.

For example, in the case where there is deviation in the rotation direction, the deviation amount of the component included in the layer LY_A and the component same as that in the layer LY_A included in any one of the layer LY_B to the layer LY_D is preferably less than or equal to 1°, less than or equal to 0.5°, less than or equal to 0.1°, less than or equal to 0.05°, less than or equal to 0.01°, or less than or equal to 0.005°. Note that the deviation amount is preferably as small as possible, but may be greater than 1° depending on the case.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, a structure example and an operation example of a reading circuit (the driver circuit RBD) provided in the memory device described in the above embodiment are described.

### Structure Example

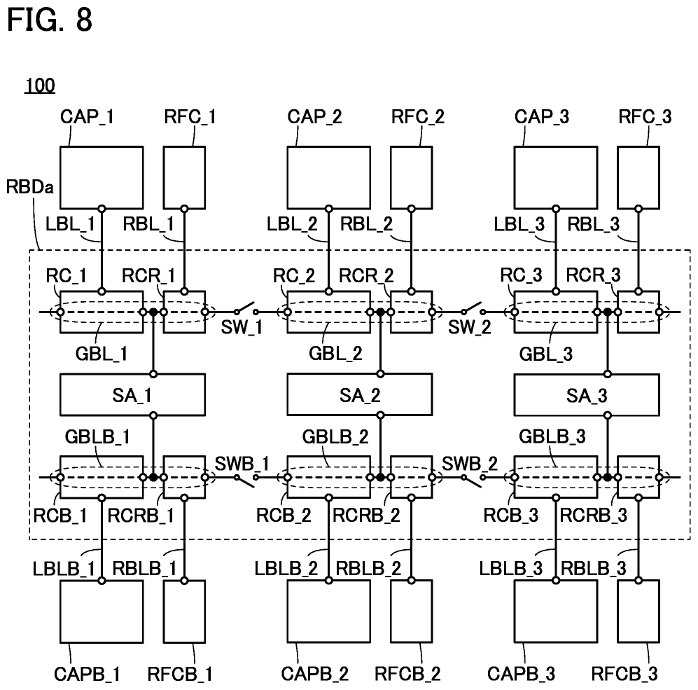

FIG. 8 is a block diagram illustrating an example of a memory device 100, and the memory device 100 is a memory device that can write and read a 4-level potential as data.

Specifically, the memory device 100 has a function of writing 4-level data (here, “0”, “1”, “2”, or “3”) to a memory circuit included in the memory device 100 and a function of reading the 4-level data written to the memory circuit, for example.

The memory device 100 includes, for example, a cell array portion CAP_1 to a cell array portion CAP_3, a cell array portion CAPB_1 to a cell array portion CAPB_3, a reference cell portion RFC_1 to a reference cell portion RFC_3, a reference cell portion RFCB_1 to a reference cell portion RFCB_3, and a driver circuit RBDa.

The driver circuit RBDa is a reading circuit in the memory device 100 and corresponds to the driver circuit RBD of the memory device MDV described in Embodiment 1.

The driver circuit RBDa includes a circuit RC_1 to a circuit RC_3, a circuit RCB_1 to a circuit RCB_3, a circuit RCR_1 to a circuit RCR_3, a circuit RCRB_1 to a circuit RCRB_3, a sense amplifier SA_1 to a sense amplifier SA_3, a switch SW_1, a switch SW_2, a switch SWB_1, and a switch SWB_2.

As the switch SW_1, the switch SW_2, the switch SWB_1, and the switch SWB_2, an electrical switch or a mechanical switch can be used, for example.

The cell array portion CAP_1 is electrically connected to the circuit RC_1 through a wiring LBL_1. The reference cell portion RFC_1 is electrically connected to the circuit RCR_1 through a wiring RBL_1. The circuit RC_1 and the circuit RCR_1 are electrically connected to a wiring GBL_1. The wiring GBL_1 is electrically connected to the sense amplifier SA_1.

The cell array portion CAPB_1 is electrically connected to the circuit RCB_1 through a wiring LBLB_1. The reference cell portion RFCB_1 is electrically connected to the circuit RCRB_1 through a wiring RBLB_1. The circuit RCB_1 and the circuit RCRB_1 are electrically connected to a wiring GBLB_1. The wiring GBLB_1 is electrically connected to the sense amplifier SA_1.

As illustrated in FIG. 8, the electrical connection structure of the cell array portion CAP_2, the reference cell portion RFC_2, the circuit RC_2, the circuit RCR_2, and the sense amplifier SA_2 can be similar to the electrical connection structure of the cell array portion CAP_1, the reference cell portion RFC_1, the circuit RC_1, the circuit RCR_1, and the sense amplifier SA_1. The electrical connection structure of the cell array portion CAPB_2, the reference cell portion RFCB_2, the circuit RCB_2, the circuit RCRB_2, and the sense amplifier SA_2 can be similar to the electrical connection structure of the cell array portion CAPB_1, the reference cell portion RFCB_1, the circuit RCB_1, the circuit RCRB_1, and the sense amplifier SA_1. Note that a wiring LBL_2 functions as a wiring that establishes electrical continuity between the cell array portion CAP_2 and the circuit RC_2, and a wiring RBL_2 functions as a wiring that establishes electrical continuity between the reference cell portion RFC_2 and the circuit RCR_2. A wiring LBLB_2 functions as a wiring that establishes electrical continuity between the cell array portion CAPB_2 and the circuit RCB_2, and a wiring RBLB_2 functions as a wiring that establishes electrical continuity between the reference cell portion RFCB_2 and the circuit RCRB_2.

As illustrated in FIG. 8, the electrical connection structure of the cell array portion CAP_3, the reference cell portion RFC_3, the circuit RC_3, the circuit RCR_3, and the sense amplifier SA_3 can be similar to the electrical connection structure of the cell array portion CAP_1, the reference cell portion RFC_1, the circuit RC_1, the circuit RCR_1, and the sense amplifier SA_1. The electrical connection structure of the cell array portion CAPB_3, the reference cell portion RFCB_3, the circuit RCB_3, the circuit RCRB_3, and the sense amplifier SA_3 can be similar to the electrical connection structure of the cell array portion CAPB_1, the reference cell portion RFCB_1, the circuit RCB_1, the circuit RCRB_1, and the sense amplifier SA_1. Note that a wiring LBL_3 functions as a wiring that establishes electrical continuity between the cell array portion CAP_3 and the circuit RC_3, and a wiring RBL_3 functions as a wiring that establishes electrical continuity between the reference cell portion RFC_3 and the circuit RCR_3. A wiring LBLB_3 functions as a wiring that establishes electrical continuity between the cell array portion CAPB_3 and the circuit RCB_3, and a wiring RBLB_3 functions as a wiring that establishes electrical continuity between the reference cell portion RFCB_3 and the circuit RCRB_3.

A first terminal of the switch SW_1 is electrically connected to the wiring GBL_1, and a second terminal of the switch SW_1 is electrically connected to a wiring GBL_2. A first terminal of the switch SW_2 is electrically connected to the wiring GBL_2, and a second terminal of the switch SW_2 is electrically connected to a wiring GBL_3. A first terminal of the switch SWB_1 is electrically connected to the wiring GBLB_1, and a second terminal of the switch SWB_1 is electrically connected to a wiring GBLB_2. A first terminal of the switch SWB_2 is electrically connected to the wiring GBLB_2, and a second terminal of the switch SWB_2 is electrically connected to a wiring GBLB_3.

### <<Cell Array Portion CAP and Cell Array Portion CAPB>>

Next, the cell array portion CAP_1 to the cell array portion CAP_3 and the cell array portion CAPB_1 to the cell array portion CAPB_3 that are included in the memory device 100 in FIG. 8 are described.

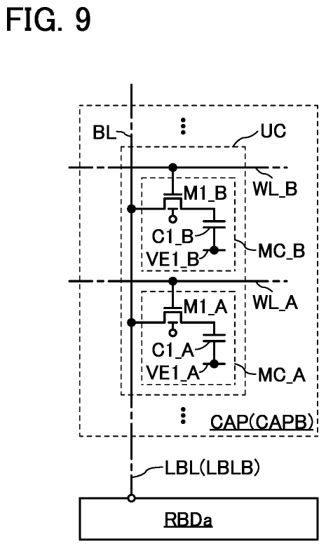

FIG. 9 illustrates a structure example of a circuit that can be used as the cell array portion CAP_1 to the cell array portion CAP_3 and the cell array portion CAPB_1 to the cell array portion CAPB_3. Note that in FIG. 9, “x” (x is 1, 2, or 3) for identification is omitted and a cell array portion CAP refers to any one of the cell array portion CAP_1 to the cell array portion CAP_3 (a cell array portion CAPB refers to any one of the cell array portion CAPB_1 to the cell array portion CAPB_3). Furthermore, a wiring LBL refers to any one of the wiring LBL_1 to the wiring LBL_3 (a wiring LBLB refers to any one of the wiring LBLB_1 to the wiring LBLB_3).

FIG. 9 also illustrates the driver circuit RBDa to illustrate a connection structure of the wiring LBL (the wiring LBLB).

Hereinafter, the circuit having the structure illustrated in FIG. 9 is described as the cell array portion CAP. Since the cell array portion CAPB can have a structure similar to that of the cell array portion CAP, the following description of the cell array portion CAP is referred to for the description of the cell array portion CAPB. In that case, the wiring LBL is replaced with the wiring LBLB in the following description.

As illustrated in FIG. 9, the cell array portion CAP includes the circuit UC that is a memory circuit, and the circuit UC includes the memory cell MC_A and the memory cell MC_B. That is, the circuit UC of the cell array portion CAP illustrated in FIG. 9 has a structure of the circuit UC[i,j] illustrated in FIG. 2 from which the memory cell MC_C and the memory cell MC_D are omitted. The wiring LBL is electrically connected to the wiring BL corresponding to the wiring BL[j] in FIG. 2.

The memory cell MC_A and the memory cell MC_B illustrated in FIG. 9 are memory cells capable of retaining 1-bit digital data similar to the memory cell MC_A to the memory cell MC_D in FIG. 2. That is, the circuit UC in FIG. 9 functions as a memory circuit capable of retaining 2-bit (22-level=4-level) digital data.

Since the circuit UC in FIG. 9 is a memory circuit capable of retaining 2-bit (22-level=4-level) digital data, the ratio of the capacitance values of the capacitor C1_A and the capacitor C1_B illustrated in FIG. 9 is 1:2 as in the memory cell MC_A and the capacitor MC_B in FIG. 2.

Note that for the operation example of the memory cell MC_A and the memory cell MC_B in FIG. 9, the operation example of the memory cell MC_A to the memory cell MC_D described in Embodiment 1 is referred to.

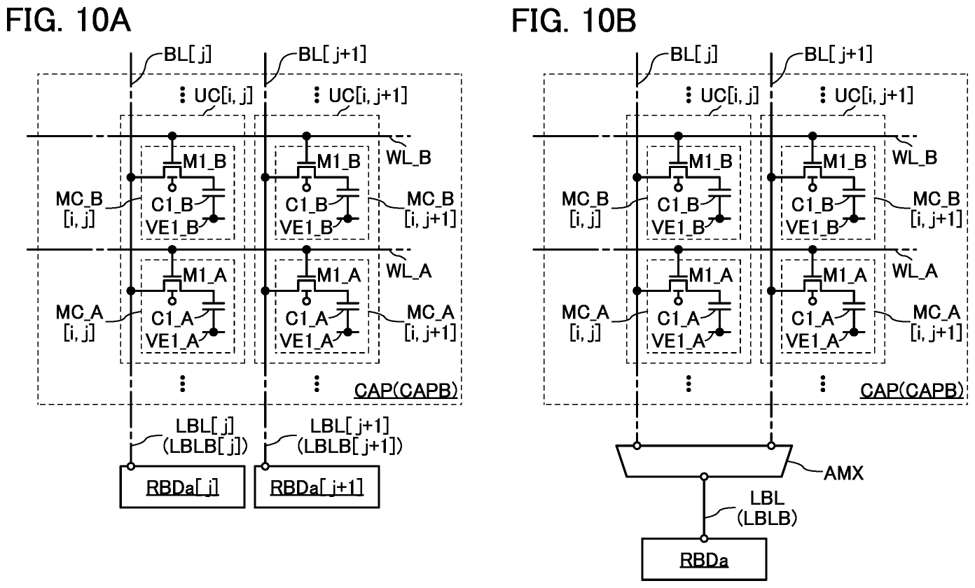

As illustrated in FIG. 10A, it is preferable that the individual driver circuits RBDa be electrically connected to the wirings BL in respective columns of the cell array portion CAP (the cell array portion CAPB) in FIG. 9.

FIG. 10A is a structure example, similar to FIG. 9, that can be used as the cell array portion CAP (the cell array portion CAPB) illustrated in FIG. 1, and a circuit diagram selectively illustrating the circuit UC[i,j] and a circuit UC[i,j+1] (here, i is an integer greater than or equal to 1 and j is an integer greater than or equal to 1). In addition, FIG. 10A only illustrates a driver circuit RBDa[j] and a driver circuit RBDa[j+1] among the individual driver circuits RBDa and a wiring LBL[j] (a wiring LBLB[j]) and a wiring LBL[j+1] (a wiring LBLB[j+1]) that are respectively electrically connected to the driver circuit RBDa[j] and the driver circuit RBDa[j+1].

In the j-th column of the cell array portion CAP (the cell array portion CAPB) in FIG. 10A, the circuit UC[i,j] is electrically connected to the wiring BL[j], and the wiring BL[j] is electrically connected to the driver circuit RBDa[j] through the wiring LBL[j] (the wiring LBLB[j]). In the j+1-th column of the cell array portion CAP (the cell array portion CAPB) in FIG. 10A, the circuit UC[i,j+1] is electrically connected to the wiring BL[j+1], and the wiring BL[j+1] is electrically connected to the driver circuit RBDa[j+1] through the wiring LBL[j+1] (the wiring LBLB[j+1])

That is, as illustrated in FIG. 10A, the driver circuit RBDa illustrated in FIG. 8 and FIG. 9 preferably has a connection structure in which data retained in the plurality of circuits UC arranged in one of the columns in the cell array portion CAP (the cell array portion CAPB) is read.

In the connection structure of the cell array portion CAP (the cell array portion CAPB) and the driver circuit RBDa, as illustrated in FIG. 10B, the wirings BL extending in the columns in the cell array portion CAP (the cell array portion CAPB) may be electrically connected to input terminals of an analog multiplexer AMX (sometimes referred to as an analog switch array), and the wiring LBL (the wiring LBLB) may be electrically connected to an output terminal of the analog multiplexer AMX. That is, the memory device 100 may have a structure in which one of the plurality of columns of the cell array portion CAP (the cell array portion CAPB) is selected by the analog multiplexer AMX and data retained in the circuit UC in the selected column is read by the driver circuit RBDa.

### <<Reference Cell Portion RFC and Reference Cell Portion RFCB>>

Next, the reference cell portion RFC_1 to the reference cell portion RFC_3 and the reference cell portion RFCB_1 to the reference cell portion RFCB_3 that are included in the memory device 100 in FIG. 8 are described.

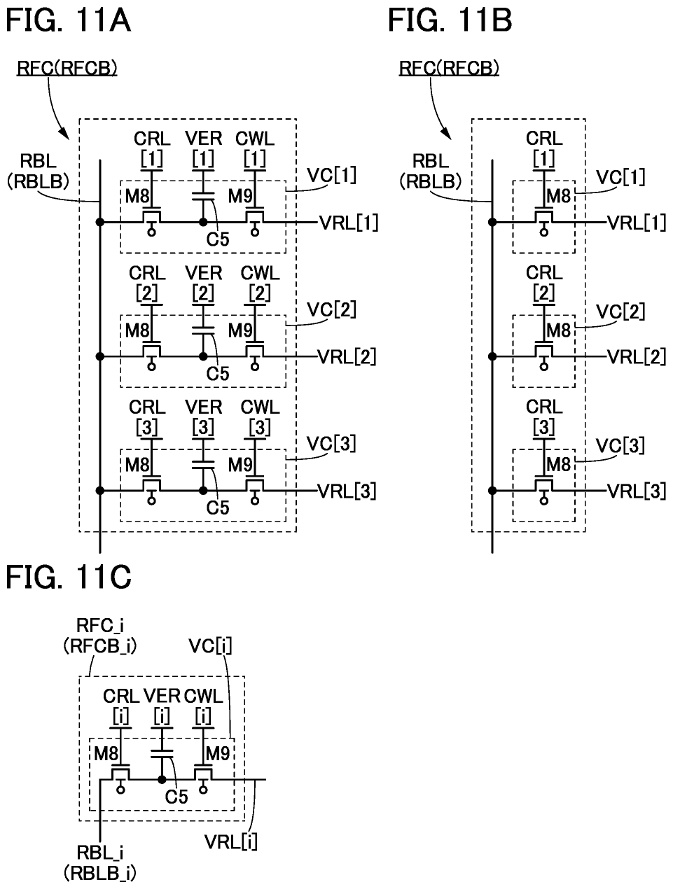

FIG. 11A illustrates a structure example of a circuit that can be used as the reference cell portion RFC_1 to the reference cell portion RFC_3 and the reference cell portion RFCB_1 to the reference cell portion RFCB_3. Note that in FIG. 11A, as in FIG. 9, “x” (x is 1, 2, or 3) for identification is omitted and a reference cell portion RFC refers to any one of the reference cell portion RFC_1 to the reference cell portion RFC_3, a reference cell portion RFCB refers to any one of the reference cell portion RFCB_1 to the reference cell portion RFCB_3, a wiring RBL refers to any one of the wiring RBL_1 to the wiring RBL_3, and a wiring RBLB refers to any one of the wiring RBLB_1 to the wiring RBLB_3.

Hereinafter, the circuit having the structure illustrated in FIG. 11A is described as the reference cell portion RFC. Since the reference cell portion RFCB can have a structure similar to that of the reference cell portion RFC, the following description of the reference cell portion RFC is referred to for the description of the reference cell portion RFCB. In that case, the wiring RBL is replaced with the wiring RBLB in the following description.

The reference cell portion RFC includes a reference cell VC[1] to a reference cell VC[3], for example.

The reference cell VC[1] includes a transistor M8, a transistor M9, and a capacitor C5, for example. A first terminal of the transistor M8 is electrically connected to a first terminal of the capacitor C5 and a first terminal of the transistor M9. A second terminal of the transistor M8 is electrically connected to the wiring RBL. A gate of the transistor M8 is electrically connected to a wiring CRL[1]. A second terminal of the transistor M9 is electrically connected to a wiring VRL[1], and a gate of the transistor M9 is electrically connected to a wiring CWL[1]. A second terminal of the capacitor C5 is electrically connected to a wiring VER[1].

Note that as each of the transistor M8 and the transistor M9, for example, a transistor usable as the transistor M1 can be used. Alternatively, like the transistor M1, the transistor M8 and the transistor M9 can each be replaced with an electrical switch other than a transistor or a mechanical switch, for example.

The wiring CRL[1] functions as a wiring for supplying a high-level potential or a low-level potential to switch an on state and an off state of the transistor M8.

The wiring CWL[1] functions as a wiring for supplying a high-level potential or a low-level potential to switch an on state and an off state of the transistor M9.

The wiring VER[1] functions as a wiring for supplying a fixed potential. The fixed potential can be a negative potential, a ground potential, a low-level potential, or a high-level potential, for example. A variable potential (e.g., pulse voltage or a pulse signal), not the fixed potential, may be supplied to the wiring VER[1], for example.

The wiring VRL[1] functions as a wiring for supplying a fixed potential. The fixed potential can be, for example, a threshold voltage for reading 4-level data retained in the circuit UC of the memory device 100. Here, the wiring VRL[1] is a wiring for supplying a first threshold voltage Vₜₕ[1] that is a fixed potential, for example. Furthermore, Vₜₕ[1] is a potential higher than a potential showing “0” that is one of the 4-level data and lower than a potential showing “1” that is one of the 4-level data.

The reference cell VC[1] has a function of retaining the first threshold voltage Vₜₕ[1]. As a method for retaining Vₜₕ[1] in the reference cell VC[1], for example, a low-level potential is supplied to the wiring CRL[1] to bring the transistor M8 into an off state and a high-level potential is supplied to the wiring CWL[1] to bring the transistor M9 into an on state so that electrical continuity is established between the wiring VRL[1] and the first terminal of the capacitor C5. Accordingly, Vₜₕ[1] supplied from the wiring VRL[1] can be written to the first terminal of the capacitor C5. After Vₜₕ[1] is written to the first terminal of the capacitor C5, a low-level potential is supplied to the wiring CWL[1] to bring the transistor M9 into an off state, whereby Vₜₕ[1] can be retained in the first terminal of the capacitor C5.

In addition, the reference cell VC[1] can supply charge accumulated in the first terminal of the capacitor C5 to the wiring RBL at a predetermined timing. Specifically, for example, after Vₜₕ[1] is retained in the first terminal of the capacitor C5, a high-level potential is supplied to the wiring CRL[1] at the timing to bring the transistor M8 into an on state. Accordingly, the charge accumulated in the first terminal of the capacitor C5 is supplied to the wiring RBL, whereby the potential of the wiring RBL can be changed.

The reference cell VC[2] and the reference cell VC[3] have a structure similar to that of the reference cell VC[1] but are connected to different wirings from the reference cell VC[1]. For example, in the reference cell VC[2], a wiring CRL[2] is electrically connected to the gate of the transistor M8, a wiring CWL[2] is electrically connected to the gate of the transistor M9, a wiring VRL[2] is electrically connected to the second terminal of the transistor M9, and a wiring VER[2] is electrically connected to the second terminal of the capacitor C5. For example, in the reference cell VC[3], a wiring CRL[3] is electrically connected to the gate of the transistor M8, a wiring CWL[3] is electrically connected to the gate of the transistor M9, a wiring VRL[3] is electrically connected to the second terminal of the transistor M9, and a wiring VER[3] is electrically connected to the second terminal of the capacitor C5.

The description of the wiring CRL[1] is referred to for the wiring CRL[2] and the wiring CRL[3], the description of the wiring CWL[1] is referred to for the wiring CWL[2] and the wiring CWL[3], and the description of the wiring VER[1] is referred to for the wiring VER[2] and the wiring VER[3].

Like the wiring VRL[1], the wiring VRL[2] functions as a wiring for supplying a threshold voltage for reading “0”, “1”, “2”, or “3” that is 4-level data retained in the circuit UC of the memory device 100, for example. Here, the wiring VRL[2] is a wiring for supplying a second threshold voltage Vₜₕ[2] that is a constant voltage, for example. Furthermore, Vₜₕ[2] is a potential higher than a potential showing “1” that is one of the 4-level data and lower than a potential showing “2” that is one of the 4-level data.

That is, the reference cell VC[2] can retain Vₜₕ[2] in the first terminal of the capacitor C5 and can supply charge accumulated in the first terminal of the capacitor C5 to the wiring RBL at a predetermined timing to change the potential of the wiring RBL.

Like the wiring VRL[1] and the wiring VRL[2], the wiring VRL[3] functions as a wiring for supplying a threshold voltage for reading “0”, “1”, “2”, or “3” that is 4-level data retained in the circuit UC of the memory device 100, for example. Here, the wiring VRL[3] is a wiring for supplying a third threshold voltage Vₜₕ[3] that is a constant voltage, for example. Furthermore, Vₜₕ[3] is a potential higher than a potential showing “2” that is one of the 4-level data and lower than a potential showing “3” that is one of the 4-level data.

That is, the reference cell VC[3] can retain Vₜₕ[3] in the first terminal of the capacitor C5 and can supply charge accumulated in the first terminal of the capacitor C5 to the wiring RBL at a predetermined timing to change the potential of the wiring RBL.

Since the reference cell portion RFC includes the reference cell VC[1] to the reference cell VC[3], the reference cell portion RFC can change a potential of the wiring RBL to a potential corresponding to any one of Vₜₕ[1] to Vₜₕ[3] owing to the functions of the reference cell VC[1] to the reference cell VC[3].

Note that the wiring VRL[1] to the wiring VRL[3] may be wirings for supplying voltages corresponding to the first threshold voltage to third threshold voltage, not wirings for supplying the first threshold voltage to third threshold voltage.

Note that the reference cell portion RFC of the memory device of one embodiment of the present invention is not limited to having the structure of the reference cell portion RFC in FIG. 11A. The reference cell portion RFC of the memory device of one embodiment of the present invention may have a structure changed from that of the reference cell portion RFC in FIG. 11A according to circumstances.

For example, as illustrated in FIG. 11B, a structure may be employed in which the transistor M9 and the capacitor C5 are not included, which is different from the reference cell portion RFC in FIG. 11A. In the reference cell portion RFC in FIG. 11B, the second terminals of the transistors M8 of the reference cell VC[1] to the reference cell VC[3] are electrically connected to the wiring VRL[1] to the wiring VRL[3], respectively. Thus, in the reference cell portion RFC in FIG. 11B, the potential of the wiring RBL can be any one of Vₜₕ[1] to Vₜₕ[3] by supplying a high-level potential to any one of the wiring CRL[1] to the wiring CRL[3] and supplying a low-level potential to the other two wirings. The reference cell portion RFC in FIG. 11B includes fewer circuit elements than the reference cell portion RFC in FIG. 11A, and thus can have a smaller circuit area.

As illustrated in FIG. 11C, the reference cell portion RFC of the memory device of one embodiment of the present invention may have a structure including a reference cell VC[i] (i is an integer greater than or equal to 1 and less than or equal to 3). FIG. 11C illustrates a circuit structure example of a reference cell portion RFC_i (a reference cell portion RFCB_i), and [i] of the reference cell VC[i], a wiring RBL_i, a wiring VRL[i], a wiring CRL[i], a wiring VER[i], and a wiring CWL[i] illustrated in FIG. 11C can be the same number as “i” of the reference cell portion RFC_i. For example, when the reference cell portion RFC_i in FIG. 11C is used as the reference cell portion RFC_1 to the reference cell portion RFC_3 of the memory device 100 in FIG. 1, the potential of the wiring RBL_1 can be changed to a potential corresponding to Vₜₕ[1] because the reference cell portion RFC_1 includes the reference cell VC[1]; the potential of the wiring RBL_2 can be changed to a potential corresponding to Vₜₕ[2] because the reference cell portion RFC_2 includes the reference cell VC[2]; and the potential of the wiring RBL_3 can be changed to a potential corresponding to Vₜₕ[3] because the reference cell portion RFC_3 includes the reference cell VC[3]. In addition, as in FIG. 11B, the reference cell portion RFC_i in FIG. 11C includes fewer wirings and circuit elements than the reference cell portion RFC in FIG. 11A, and thus can have a smaller circuit area. Moreover, the reference cell portion RFC_i in FIG. 11C can include fewer wirings than the reference cell portion RFC in FIG. 11A, and thus can have a lower power consumption needed for supplying potentials to the wirings.

### <<Circuit RC, Circuit RCR, Circuit RCB Circuit RCRB>>

Next, the circuit RC_1 to the circuit RC_3, the circuit RCR_1 to the circuit RCR_3, the circuit RCB_1 to the circuit RCB_3, and the circuit RCRB_1 to the circuit RCRB_3 that are included in the memory device in FIG. 8 are described.

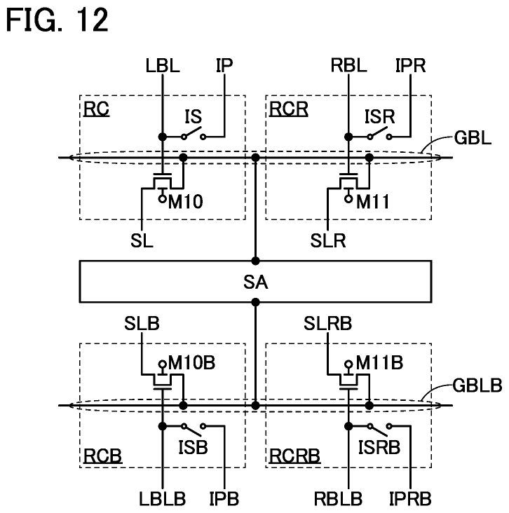

FIG. 12 illustrates circuit structures of the circuit RC, the circuit RCR, the circuit RCB, and the circuit RCRB. FIG. 12 also illustrates the sense amplifier SA to show the electrical connections of the circuit RC, the circuit RCR, the circuit RCB, and the circuit RCRB.

The circuit structures of the circuit RC, the circuit RCR, the circuit RCB, and the circuit RCRB illustrated in FIG. 12 are examples that can be applied to the circuit RC_1, the circuit RCR_1, the circuit RCB_1, and the circuit RCRB_1 in FIG. 8, respectively. Similarly, the circuit RC, the circuit RCR, the circuit RCB, and the circuit RCRB in FIG. 12 can be used as the circuit RC_2, the circuit RCR_2, the circuit RCB_2, and the circuit RCRB_2 in FIG. 8, respectively. Similarly, the circuit RC, the circuit RCR, the circuit RCB, and the circuit RCRB in FIG. 12 can be used as the circuit RC_3, the circuit RCR_3, the circuit RCB_3, and the circuit RCRB_3 in FIG. 8, respectively. Therefore, in FIG. 12, as in FIG. 9, “_x” (x is 1, 2, or 3) for identification is omitted and a circuit RC refers to any one of the circuit RC_1 to the circuit RC_3, a circuit RCR refers to any one of the circuit RCR_1 to the circuit RCR_3, a circuit RCB refers to any one of the circuit RCB_1 to the circuit RCB_3, and a circuit RCRB refers to any one of the circuit RCRB_1 to the circuit RCRB_3. A sense amplifier SA refers to any one of the sense amplifier SA_1 to the sense amplifier SA_3, a wiring LBL refers to any one of the wiring LBL_1 to the wiring LBL_3, a wiring RBL refers to any one of the wiring RBL_1 to the wiring RBL_3, a wiring LBLB refers to any one of the wiring LBLB_1 to the wiring LBLB_3, and a wiring RBLB refers to any one of the wiring RBLB_1 to the wiring RBLB_3.

The circuit RC includes a transistor M10 and a switch IS, for example. A first terminal of the transistor M10 is electrically connected to the wiring GBL, a second terminal of the transistor M10 is electrically connected to a wiring SL, and a gate of the transistor M10 is electrically connected to a first terminal of the switch IS and the wiring LBL. A second terminal of the switch IS is electrically connected to a wiring IP.

The wiring IP functions as a wiring for supplying a fixed potential. The fixed potential can be, for example, a negative potential, a ground potential, or a low-level potential. In particular, the wiring IP functions as a wiring for supplying an initialization potential to the wiring LBL and a wiring for supplying a potential that brings the transistor M10 into an off state. The transistor M10 is illustrated as an n-channel transistor in FIG. 12, but may be a p-channel transistor. In this case, a fixed potential supplied from the wiring IP is preferably a high-level potential, for example.

The wiring SL functions as a wiring for supplying a fixed potential to the circuit RC. The fixed potential can be a high-level potential, for example.

The circuit RCR includes a transistor M11 and a switch ISR, for example. A first terminal of the transistor M11 is electrically connected to the wiring GBL, a second terminal of the transistor M11 is electrically connected to a wiring SLR, and a gate of the transistor M11 is electrically connected to a first terminal of the switch ISR and the wiring RBL. A second terminal of the switch ISR is electrically connected to a wiring IPR.

Like the wiring IP, the wiring IPR functions as a wiring for supplying a fixed potential such as a ground potential or a low-level potential, for example. In particular, the wiring IPR functions as a wiring for supplying an initialization potential to the wiring RBL and a wiring for supplying a potential that brings the transistor M11 into an off state. The transistor M11 is illustrated as an n-channel transistor in FIG. 12, but may be a p-channel transistor. In this case, a fixed potential supplied from the wiring IPR is preferably a high-level potential, for example.

The wiring SLR functions as a wiring for supplying a fixed potential to the circuit RCR. The fixed potential can be a high-level potential, for example, like the fixed potential supplied from the wiring SL.

The circuit RC has a function of obtaining, from the wiring LBL, data (for example, a potential here) read from the circuit UC (the memory cell MC_A and the memory cell MC_B) of the cell array portion CAP, when the switch IS is in an off state. At this time, in the circuit RC, the potential of the wiring LBL corresponding to the data is input to the gate of the transistor M10. In advance, for example, before the potential is input to the gate of the transistor M10, the wiring GBL is precharged with a potential lower than a potential supplied from the wiring SL and the wiring SLR using the sense amplifier SA or the like, whereby the potential of the wiring GBL is finally changed to a potential corresponding to the gate potential of the transistor M10 (a potential corresponding to the data) and the fixed potential supplied from the wiring SL.

In order to initialize the potential of the wiring LBL, the switch IS is brought into an on state so that an initialization potential is supplied from the wiring IP to the wiring LBL. In this case, the second transistor M10 is brought into an off state.

That is, the circuit RC in FIG. 12 functions in the case where the circuit UC (the memory cell MC_A and the memory cell MC_B) included in the cell array portion CAP is a circuit that outputs the read data as a potential to the wiring LBL.

The circuit RCB in FIG. 12 has a structure similar to that of the circuit RC. Thus, the description of the circuit RC is referred to for the description of the circuit RCB. In the case of the circuit RCB, the transistor M10 is replaced with a transistor M10B, the switch IS is replaced with a switch ISB, the wiring LBL is replaced with the wiring LBLB, the wiring IP is replaced with a wiring IPB, and the wiring SL is replaced with a wiring SLB in the description of the circuit RC.

The circuit RCR has a function of obtaining, from the wiring RBL, the threshold voltage for reading 4-level data (“0”, “1”, “2”, or “3”) transmitted from the reference cell portion RFC (the reference cell VC[1] to the reference cell VC[3]) when the switch ISR is in an off state. At this time, in the circuit RCR, the potential of the wiring RBL corresponding to the data is input to the gate of the transistor M11. In advance, for example, before the potential is input to the gate of the transistor M11, the wiring GBL is precharged with a potential lower than a potential supplied from the wiring SL and the wiring SLR using the sense amplifier SA or the like, whereby the potential of the wiring GBL is finally changed to a potential corresponding to the gate potential of the transistor M11 (a potential corresponding to the data) and the fixed potential supplied from the wiring SL.

In order to initialize the potential of the wiring RBL, the switch ISR is brought into an on state so that an initialization potential is supplied from the wiring IPR to the wiring RBL. At this time, the transistor M11 is brought into an off state.

The circuit RCRB in FIG. 12 has a structure similar to that of the circuit RCR. Thus, the description of the circuit RCR is referred to for the description of the circuit RCRB. In the case of the circuit RCRB, the transistor M11 is replaced with a transistor M11B, the switch ISR is replaced with a switch ISRB, the wiring RBL is replaced with the wiring RBLB, the wiring IPR is replaced with a wiring IPRB, the wiring SLR is replaced with a wiring SLRB, and the wiring GBL is replaced with the wiring GBLB in the description of the circuit RCR.

As each of the transistor M10, the transistor M11, the transistor M10B, and the transistor M11B, a transistor that can be used as the transistor M1 can be used, for example. The transistor M10, the transistor M11, the transistor M10B, or the transistor M11B can be replaced with an electrical switch other than a transistor or a mechanical switch, like the transistor M1.

As each of the switch IS, the switch ISR, the switch ISB, and the switch ISRB, a switch that is similar to the switch SW_1, the switch SW_2, the switch SWB_1, or the switch SWB_2 can be used, for example.

Note that the circuit RC, the circuit RCR, the circuit RCB, and the circuit RCRB of the memory device of one embodiment of the present invention are not limited to the circuit RC, the circuit RCR, the circuit RCB, and the circuit RCRB in FIG. 12, respectively. The circuit structures of the circuit RC, the circuit RCR, the circuit RCB, and the circuit RCRB of the memory device of one embodiment of the present invention may be changed according to circumstances.

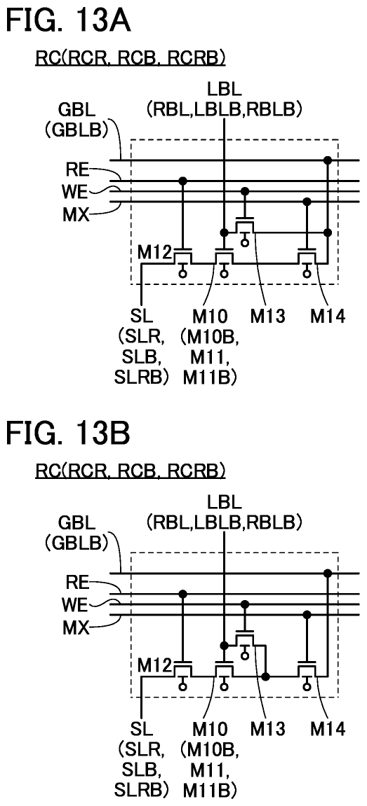

The circuit RC, the circuit RCR, the circuit RCB, or the circuit RCRB in FIG. 12 can be changed as illustrated in FIG. 13A, for example. Note that in FIG. 13A, reference numerals that differ among the circuit RC, the circuit RCR, the circuit RCB, and the circuit RCRB are shown in brackets.

The circuit RC (the circuit RCR, the circuit RCB, or the circuit RCRB) in FIG. 13A includes the transistor M10 (the transistor M10B, the transistor M11, or the transistor M11B) and the transistor M12 to a transistor M14. Depending on the case, the transistor M14 is not necessarily provided in the circuit RC (the circuit RCR, the circuit RCB, or the circuit RCRB), for example.

As each of the transistor M12 to the transistor M14, a transistor that can be used as the transistor M1 can be used, for example. Like the transistor M1, the transistor M12 to the transistor M14 can each be replaced with an electrical switch other than a transistor or a mechanical switch, for example.

A first terminal of the transistor M12 is electrically connected to the wiring SL (the wiring SLR, the wiring SLB, or the wiring SLRB), a second terminal of the transistor M12 is electrically connected to the first terminal of the transistor M10 (the transistor M10B, the transistor M11, or the transistor M11B), and a gate of the transistor M12 is electrically connected to a wiring RE. The second terminal of the transistor M10 (the transistor M10B, the transistor M11, or the transistor M11B) is electrically connected to a first terminal of the transistor M14, and the gate of the transistor M10 (the transistor M10B, the transistor M11, or the transistor M11B) is electrically connected to a first terminal of the transistor M13 and the wiring LBL (the wiring RBL, the wiring LBLB, or the wiring RBLB). A gate of the transistor M13 is electrically connected to a wiring WE. A second terminal of the transistor M14 is electrically connected to a second terminal of the transistor M13 and the wiring GBL (the wiring GBLB), and a gate of the transistor M14 is electrically connected to a wiring MX.

When a high-level potential is input to the wiring WE to bring the transistor M13 into an on state in the circuit in FIG. 13A, electrical continuity can be established between the wiring LBL (the wiring RBL, the wiring LBLB, or the wiring RBLB) and the wiring GBL (the wiring GBLB). In this case, when the sense amplifier SA equalizes the potentials of the wiring GBL and the wiring GBLB, for example, the wiring LBL can be precharged with an equalization potential (e.g., V_{INI} to be described later) from the wiring GBL through the transistor M14 and the transistor M13. That is, the circuit in FIG. 13A has a structure in which the wiring GBL (the wiring GBLB) serves as the wiring IP, the wiring IPR, the wiring IPB, and the wiring IPRB for supplying an initialization potential, which are described with reference to FIG. 12.

The circuit RC, the circuit RCR, the circuit RCB, or the circuit RCRB in FIG. 12 can be changed as illustrated in FIG. 13B. Note that in FIG. 13B, reference numerals that differ among the circuit RC, the circuit RCR, the circuit RCB, and the circuit RCRB are shown in brackets, as in FIG. 13A.

As in FIG. 13A, the circuit RC (the circuit RCR, the circuit RCB, or the circuit RCRB) in FIG. 13B includes the transistor M10 (the transistor M10B, the transistor M11, or the transistor M11B) and the transistor M12 to the transistor M14.

The circuit RC (the circuit RCR, the circuit RCB, or the circuit RCRB) in FIG. 13B has a structure in which a portion to which the second terminal of the transistor M13 is electrically connected in FIG. 13A is changed from the second terminal of the transistor M14 (the wiring GBL) to the second terminal of the transistor M10 (the transistor M10B, the transistor M11, or the transistor M11B) (the first terminal of the transistor M14).

Next, an operation example of the circuit RC, the circuit RCR, the circuit RCB, and the circuit RCRB in FIG. 13B is described. Note that the circuit in FIG. 13B is described as the circuit RC below, for example.

First, a high-level potential is input to the wiring WE and the wiring MX, and a low-level potential is input to the wiring RE. Accordingly, the transistor M13 and the transistor M14 are turned on and the transistor M12 is turned off. At this time, the wiring GBL and the wiring LBL are each precharged with a predetermined potential. For example, the sense amplifier SA can perform equalization to precharge the wiring LBL with an equalization potential (e.g., V_{INI} to be described later) from the wiring GBL through the transistor M14 and the transistor M13.

After that, a low-level potential is input to the wiring MX and a high-level potential is input to the wiring RE. Thus, the transistor M14 is turned off and the transistor M12 is turned on. Here, a potential supplied from the wiring SL is VSS that is a low-level potential, the gate potential of the transistor M10 is VG, and the threshold voltage of the transistor M10 is VTH. In this case, the gate-source voltage of the transistor M10 is VG-VSS, and VG-VSS is a voltage higher than VTH. Since there is electrical continuity between the wiring LBL and the wiring SL through the transistor M13, the transistor M10, and the transistor M12, the potential of the wiring LBL decreases with time. Specifically, the transistor M10 is brought into an off state when the gate-source voltage VG-VSS becomes equal to VTH in the transistor M10, and thus the gate potential decreases until the transistor M10 is brought into an off state. That is, when the transistor M10 is brought into an off state, the gate potential of the transistor M10 is VTH+VSS.

Then, a low-level potential is input to the wiring RE and a low-level potential is input to the wiring WE. Accordingly, the transistor M12 and the transistor M13 are turned off. Through the above operation, variations in the threshold voltage of the transistor M10 can be corrected. Correcting the variations in the threshold voltage of the transistor M10 enables accurate reading of data retained in the circuit UC.

### <<Sense Amplifier SA>>

The sense amplifier SA in FIG. 12 has a function of comparing a potential of the wiring GBL and a potential of the wiring GBLB, and changing one of the potential of the wiring GBL and the potential of the wiring GBLB to a high-level potential and changing the other of the potential of the wiring GBL and the potential of the wiring GBLB to a low-level potential, on the basis of the comparison result. The sense amplifier SA also has a function of equalizing the wiring GBL and the wiring GBLB to a predetermined potential. Note that, as operation before reading data from the cell array portion CAP (the cell array portion CAPB) by the circuit RC or the circuit RCB, the wiring GBL and the wiring GBLB may be precharged with a predetermined potential using the equalizing function. Similarly, as operation before reading a potential corresponding to the threshold voltage from the reference cell portion RFC (the reference cell portion RFCB) by the circuit RCR or the circuit RCRB, the wiring GBL and the wiring GBLB may be precharged with a predetermined potential using the equalizing function. The driving timing of the sense amplifier SA can be determined as appropriate in accordance with the operation of the memory device 100.

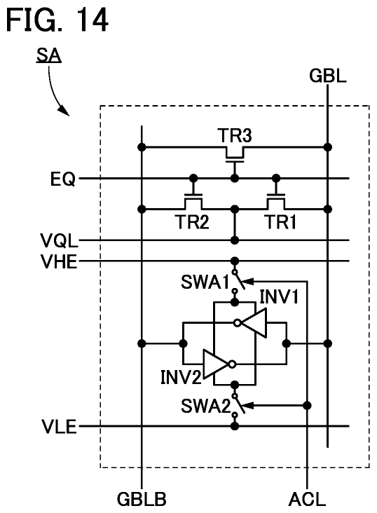

The sense amplifier SA can have a circuit structure illustrated in FIG. 14, for example. FIG. 14 also illustrates the wiring GBL and the wiring GBLB to show their electrical connection to the sense amplifier SA.

The sense amplifier SA in FIG. 14 includes a transistor TR1 to a transistor TR3, an inverter circuit INV1 and an inverter circuit INV2, and a switch SWA1 and a switch SWA2. Note that the switch SWA1 and the switch SWA2 can each be a switch that is brought into an on state when a high-level potential is input to a control terminal and brought into an off state when a low-level potential is input to the control terminal.

The transistor TR1 to the transistor TR3 are configured to function as an equalizer. Specifically, when a high-level potential is supplied to a wiring EQ, the transistor TR1 to the transistor TR3 are each brought into an on state, and accordingly the potentials of the wiring GBL and the wiring GBLB can be equalized. At this time, a wiring VQL functions as a wiring for supplying a potential to the wiring GBL and the wiring GBLB in equalizing the potentials of the wiring GBL and the wiring GBLB.

A first terminal of the transistor TR1 is electrically connected to the wiring GBL, and a first terminal of the transistor TR2 is electrically connected to the wiring GBLB. A second terminal of the transistor TR1 is electrically connected to a second terminal of the transistor TR2 and the wiring VQL, and a gate of the transistor TR1 is electrically connected to a gate of the transistor TR2, a gate of the transistor TR3, and the wiring EQ. A first terminal of the transistor TR3 is electrically connected to the wiring GBL, and a second terminal of the transistor TR3 is electrically connected to the wiring GBLB.

An input terminal of the inverter circuit INV1 is electrically connected to an output terminal of the inverter circuit INV2 and the wiring GBL, and an input terminal of the inverter circuit INV2 is electrically connected to an output terminal of the inverter circuit INV1 and the wiring GBLB. A first terminal of the switch SWA1 is electrically connected to a high potential input terminal of the inverter circuit INV1 and a high potential input terminal of the inverter circuit INV2, and a second terminal of the switch SWA1 is electrically connected to a wiring VHE. A first terminal of the switch SWA2 is electrically connected to a low potential input terminal of the inverter circuit INV1 and a low potential input terminal of the inverter circuit INV2, and a second terminal of the switch SWA2 is electrically connected to a wiring VLE. The control terminal of the switch SWA1 and the control terminal of the switch SWA2 are electrically connected to a wiring ACL.

The wiring VHE functions as a wiring for supplying a high-level potential to the inverter circuit INV1 and the inverter circuit INV2, and the wiring VLE functions as a wiring for supplying a low-level potential to the inverter circuit INV1 and the inverter circuit INV2. The wiring ACL functions as a wiring for transmitting a signal for switching an on state and an off state of the switch SWA1 and the switch SWA2.

In FIG. 14, the sense amplifier SA can be activated by supplying a high-level potential to the wiring ACL to bring the switch SWA1 and the switch SWA2 into an on state so that a high-level potential from the wiring VHE and a low-level potential from the wiring VLE are supplied to the inverter circuit INV1 and the inverter circuit INV2. Similarly, the sense amplifier SA can be inactivated by supplying a low-level potential to the wiring ACL to bring the switch SWA1 and the switch SWA2 into an off state so that power supply from the wiring VHE and the wiring VLE to the inverter circuit INV1 and the inverter circuit INV2 is stopped.

Note that the transistor TR1 to the transistor TR3 included in the sense amplifier SA and transistors included in the inverter circuit INV1 and the inverter circuit INV2 can each be a transistor that can be used as the transistor M1, for example. In particular, the transistor TR1 to the transistor TR3 included in the sense amplifier SA and the transistors included in the inverter circuit INV1 and the inverter circuit INV2 are preferably Si transistors. Since a Si transistor has high field-effect mobility and high reliability, it is particularly preferable to use a Si transistor in the circuit structure of the sense amplifier SA.

Note that the sense amplifier SA of the memory device of one embodiment of the present invention is not limited to the sense amplifier SA in FIG. 14. The sense amplifier of the memory device of one embodiment of the present invention may have a circuit structure changed from the structure of the sense amplifier SA in FIG. 14, according to circumstances.

### Operation Example

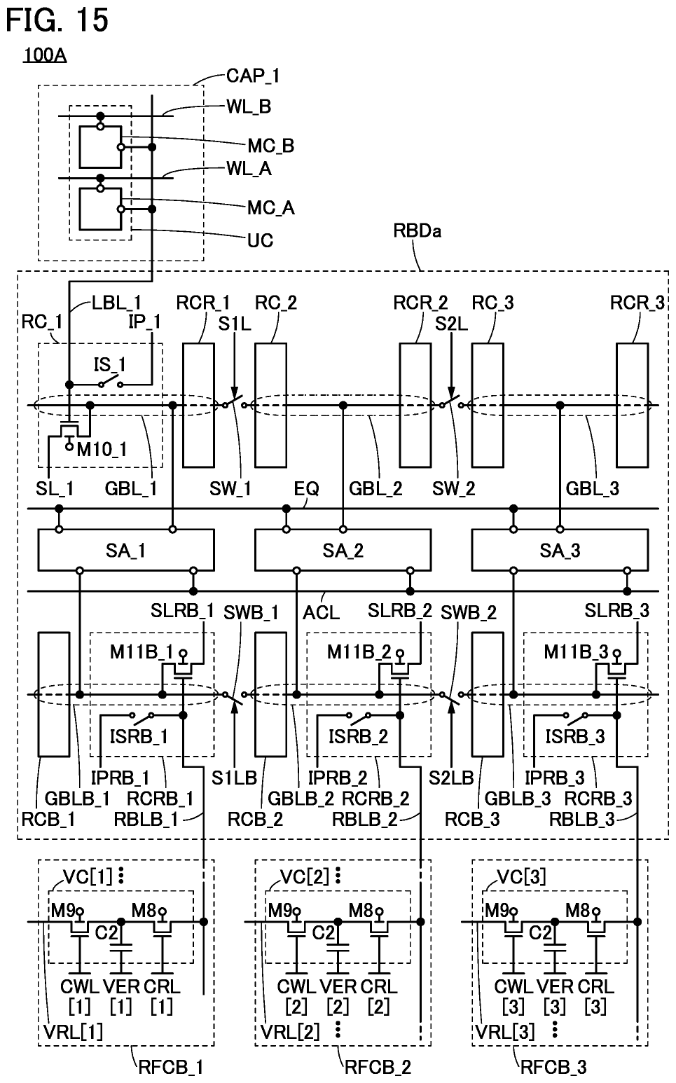

Here, an operation example of the memory device of one embodiment of the present invention is described. The memory device is a memory device 100A illustrated in FIG. 15, for example.

The memory device 100A illustrated in FIG. 15 has a structure of the memory device 100 in FIG. 8 in which the circuit UC in FIG. 9 is used as the circuit UC included in the cell array portion CAP_1, the reference cell portion RFC in FIG. 11A is used as the reference cell portion RFC_1 to the reference cell portion RFC_3, the circuit RC in FIG. 12 is used as the circuit RC_1, and the circuit RCRB in FIG. 12 is used as the circuit RCRB_1 to the circuit RCRB_3.

To the reference numerals of the circuit symbols and the wirings shown in the circuit RC_1 and the circuit RCRB_1 to the circuit RCRB_3 in FIG. 15, “_x” (x is 1, 2 or 3) for identification is added.

FIG. 15 illustrates a wiring S1L, a wiring S2L, a wiring S1LB, and a wiring S2LB that are electrically connected to the control terminals of the switch SW_1, the switch SW_2, the switch SWB_1, and the switch SWB_2, respectively. Note that the switch SW_1, the switch SW_2, the switch SWB_1, and the switch SWB_2 are turned on when a high-level potential is input to their control terminals, and are turned off when a low-level potential is input to their control terminals.

FIG. 15 also illustrates the wiring EQ and the wiring ACL. The wiring EQ is electrically connected to the sense amplifier SA_1 to the sense amplifier SA_3, and the wiring ACL is electrically connected to the sense amplifier SA_1 to the sense amplifier SA_3.

As the sense amplifier SA_1 to the sense amplifier SA_3 illustrated in FIG. 15, the sense amplifier in FIG. 14 is used. That is, the wiring EQ functions as a wiring for transmitting a signal that enables or disables equalization. In this operation example, the sense amplifier SA_1 to the sense amplifier SA_3 perform equalization when a high-level potential is input to the wiring EQ, and the sense amplifier SA_1 to the sense amplifier SA_3 stop equalization when a low-level potential is input to the wiring EQ.

The wiring ACL functions as a wiring for transmitting a signal that activates or inactivates the sense amplifier SA_1 to the sense amplifier SA_3. In this operation example, the sense amplifier SA_1 to the sense amplifier SA_3 are activated when a high-level potential is input to the wiring ACL, and the sense amplifier SA_1 to the sense amplifier SA_3 are inactivated when a low-level potential is input to the wiring ACL.

In FIG. 15, the circuit structures of the circuit RC_2, the circuit RC_3, the circuit RCR_1 to the circuit RCR_3, and the circuit RCB_1 to the circuit RCB_3 are not illustrated.

In addition, only the reference cell VC[1] is illustrated in the reference cell portion RFC_1, only the reference cell VC[2] is illustrated in the reference cell portion RFC_2, and only the reference cell VC[3] is illustrated in the reference cell portion RFC_3.

The circuit RC_2 and the circuit RC_3 can have a circuit structure similar to that of the circuit RC_1, for example; however, in this operation example, no current is supplied to the wiring GBL_2 and no current is released from the wiring GBL_2 in the circuit RC_2, and no current is supplied to the wiring GBL_3 and no current is released from the wiring GBL_3 in the circuit RC_3. Similarly, the circuit RCB_1 to the circuit RCB_3 can have a circuit structure similar to that of the circuit RC_1; however, in this operation example, no current is supplied to the wiring GBLB_1 and no current is released from the wiring GBLB_1 in the circuit RCB_1, no current is supplied to the wiring GBLB_2 and no current is released from the wiring GBLB_2 in the circuit RCB_2, and no current is supplied to the wiring GBLB_3 and no current is released from the wiring GBLB_3 in the circuit RCB_3.

The circuit RCR_1 to the circuit RCR_3 can have a circuit structure similar to those of the circuit RCRB_1 to the circuit RCRB_3, for example; however, in this operation example, no current is supplied to the wiring GBL_1 and no current is released from the wiring GBL_1 in the circuit RCR_1, no current is supplied to the wiring GBL_2 and no current is released from the wiring GBL_2 in the circuit RCR_2, and no current is supplied to the wiring GBL_3 and no current is released from the wiring GBL_3 in the circuit RCR_3.

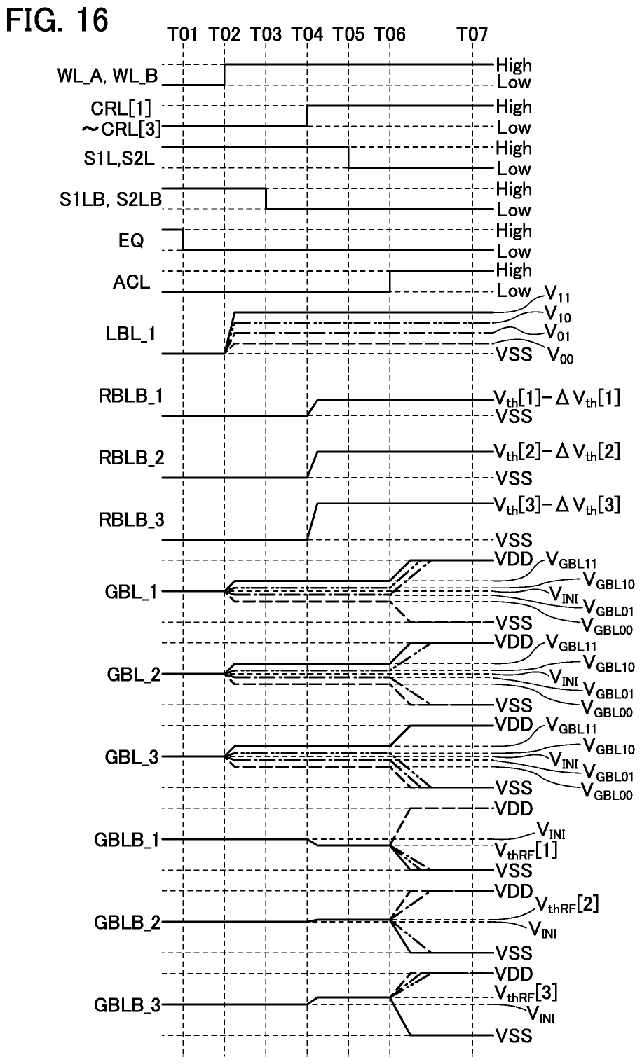

FIG. 16 is a timing chart showing an operation example of the memory device 100A. The timing chart in FIG. 16 shows changes in the potentials of the wiring WL_A, the wiring WL_B, the wiring CRL[1] to the wiring CRL[3], the wiring S1L, the wiring S2L, the wiring S1LB, the wiring S2LB, the wiring EQ, the wiring ACL, the wiring LBL_1, the wiring RBLB_1, the wiring RBLB_2, the wiring RBLB_3, the wiring GBL_1, the wiring GBL_2, the wiring GBL_3, the wiring GBLB_1, the wiring GBLB_2, and the wiring GBLB_3 from Time T01 to Time T07 and around the period. Note that in FIG. 16, “High” indicates a high-level potential and “Low” indicates a low-level potential. The potentials of the wiring CRL[1] to the wiring CRL[3] change at the same timing in the same manner in this operation example, and thus the wirings are collectively shown in the timing chart in FIG. 16. Similarly, a set of the wiring WL_A and the wiring WL_B, a set of the wiring S1L and the wiring S2L, and a set of the wiring S1LB and the wiring S2LB are each collectively shown.

In this operation example, a constant potential supplied from each of the wiring VE1_A electrically connected to the second terminal of the capacitor C1_A of the memory cell MC_A, the wiring VE1_B electrically connected to the second terminal of the capacitor C1_B of the memory cell MC_B, a wiring IP_1, a wiring IPRB_1 to a wiring IPRB_3, and the wiring VER[1] to the wiring VER[3] is VSS. The constant voltage supplied from the wiring VRL[1] is the first threshold voltage Vin[1], the constant voltage supplied from the wiring VRL[2] is the second threshold voltage Vₜₕ[2], and the constant voltage supplied from the wiring VRL[3] is the third threshold voltage Vₜₕ[3]. A constant potential supplied from each of a wiring SL_1 and a wiring SLRB_1 to a wiring SLRB_3 is a high-level potential (hereinafter, referred to as VDD). A constant potential supplied to one of the wiring GBL_1 and the wiring GBLB_1 by the sense amplifier SA_1 is VDD, and a constant potential supplied to the other of the wiring GBL_1 and the wiring GBLB_1 by the sense amplifier SA_1 is VSS. Similarly, a constant potential supplied to one of the wiring GBL_2 and the wiring GBLB_2 by the sense amplifier SA_2 is VDD, and a constant potential supplied to the other of the wiring GBL_2 and the wiring GBLB_2 by the sense amplifier SA_2 is VSS. Similarly, a constant potential supplied to one of the wiring GBL_3 and the wiring GBLB_3 by the sense amplifier SA_3 is VDD, and a constant potential supplied to the other of the wiring GBL_3 and the wiring GBLB_3 by the sense amplifier SA_3 is VSS.

At time before Time T01, any one of the 4-level data (“0”, “1”, “2”, or “3”) is retained in the circuit UC in advance. Thus, a low-level potential is input to the wiring WL_A and the wiring WL_B to turn off the transistor M1, and a potential corresponding to the 4-level data is retained in the first terminal of the capacitor C1 in each of the memory cell MC_A and the memory cell MC_B.

At time before Time T01, Vₜₕ[1] to Vₜₕ[3] are retained respectively in the reference cell VC[1] to the reference cell VC[3] in advance. Specifically, in the reference cell portion RFC_1, a high-level potential is input to the wiring CWL[1] to bring the transistor M9 into an on state, so that Vₜₕ[1] is supplied from the wiring VRL[1] to the first terminal of the capacitor C2. Similarly, in the reference cell portion RFC_2, a high-level potential is input to the wiring CWL[2] to bring the transistor M9 into an on state, so that Vₜₕ[2] is supplied from the wiring VRL[2] to the first terminal of the capacitor C2. In the reference cell portion RFC_3, a high-level potential is input to the wiring CWL[3] to bring the transistor M9 into an on state, so that Vₜₕ[3] is supplied from the wiring VRL[3] to the first terminal of the capacitor C2. After Vₜₕ[1] to Vₜₕ[3] are written respectively to the reference cells VC[1] to VC[3], low-level potentials are input to the wiring CWL[1] to the wiring CWL[3] to bring the transistors M9 in the reference cell VC[1] to the reference cell VC[3] into an off state, so that Vₜₕ[1] to Vₜₕ[3] can be retained in the first terminals of the capacitors C2 of the reference cell VC[1] to the reference cell VC[3].

At time before Time T01, the wiring LBL_1 and the wiring RBLB_1 to the wiring RBLB_3 are precharged with VSS that is an initialization potential. Specifically, the switch IS_1 is brought into an on state so that VSS is supplied from the wiring IP_1 to the wiring LBL_1, and the switch ISRB_1 to the switch ISRB_3 are each brought into an on state so that VSS is supplied from the wiring IPRB_1 to the wiring IPRB_3 respectively to the wiring RBLB_1 to the wiring RBLB_3. After VSS is supplied to the wiring LBL_1 and the wiring RBLB_1 to the wiring RBLB_3, the switch IS_1 and the switch ISRB_1 to the switch ISRB_3 are each brought into an off state to bring the wiring LBL_1 and the wiring RBLB_1 to the wiring RBLB_3 into a floating state.

In addition, the wiring LBL_1 and the wiring RBLB_1 to the wiring RBLB_3 are precharged with VSS, and accordingly a transistor M10_1 and a transistor M11B_1 to a transistor M11B_3 are brought into an off state.

At time before Time T01, a high-level potential is input to the wiring S1L, the wiring S2L, the wiring S1LB, and the wiring S2LB. Thus, the switch SW_1, the switch SW_2, the switch SWB_1, and the switch SWB_2 are each brought into an on state. Accordingly, the potentials of the wiring GBL_1 to the wiring GBL_3 become equal to each other, and potentials of the wiring GBLB_1 to the wiring GBLB_3 also become equal to each other.

Furthermore, at time before Time T01, a high-level potential is input to the wiring EQ and a low-level potential is input to the wiring ACL. Thus, the sense amplifier SA_1 to the sense amplifier SA_3 are inactivated, and the sense amplifier SA_1 to the sense amplifier SA_3 perform equalization. Specifically, in the sense amplifier SA_1 to the sense amplifier SA_3, a set of the wiring GBL_1 and the wiring GBLB_1, a set of the wiring GBL_2 and the wiring GBLB_2, and a set of the wiring GBL_3 and the wiring GBLB_3 are each equalized, so that the potentials of the wiring GBL_1 to the wiring GBL_3 and the wiring GBLB_1 to the wiring GBLB_3 are set to V_{INI} that is a potential higher than VSS and lower than VDD. For example, V_{INI} may be a potential of (VDD−VSS)/2.

From Time T01 to Time T02, the potential of the wiring EQ changes from a high-level potential to a low-level potential. Accordingly, the sense amplifier SA_1 to the sense amplifier SA_3 stop equalization. Thus, supply of the potential V_{INI} from the sense amplifier SA_1 to the wiring GBL_1 and the wiring GBLB_1 stops, supply of the potential V_{INI} from the sense amplifier SA_2 to the wiring GBL_2 and the wiring GBLB_2 stops, and supply of the potential V_{INI} from the sense amplifier SA_3 to the wiring GBL_3 and the wiring GBLB_3 stops.

From Time T02 to Time T03, a high-level potential is input to the wiring WL_A and the wiring WL_B. Thus, electrical continuity is established between the first terminal of the capacitor C1 in the memory cell MC_A and the wiring LBL_1, and electrical continuity is established between the first terminal of the capacitor C1 in the memory cell MC_B and the wiring LBL_1; thus, a read signal corresponding to a potential retained in each of the memory cell MC_A and the memory cell MC_B is output from the circuit UC to the wiring LBL_1. Specifically, the potential of the first terminal of the capacitor C1_A in the memory cell MC_A, the potential of the first terminal of the capacitor C1_B in the memory cell MC_B, and the potential of the wiring LBL_1 are changed. The amount of change in the potentials depends on the value of data retained in the circuit UC (any one of “0”, “1”, “2”, and “3”).

Here, when the data retained in the circuit UC is “0”, the potential of the wiring LBL_1 changes to V₀₀. When the data retained in the circuit UC is “1”, the potential of the wiring LBL_1 changes to V₀₁. When the data retained in the circuit UC is “2”, the potential of the wiring LBL_1 changes to V₁₀. When the data retained in the circuit UC is “3”, the potential of the wiring LBL_1 changes to Vn. Note that among V₀₀, V₀₁, V₁₀, and V₁₁, V₀₀ is the lowest potential, V₀₁ is the second lowest potential, V₁₀ is the second highest potential, and V₁₁ is the highest potential.

In the timing chart in FIG. 16, the change in the potential of the wiring LBL_1 in the case where the data retained in the circuit UC is any one of “0”, “1”, “2”, and “3” is shown. Specifically, as for the wiring LBL_1 in the timing chart in FIG. 16, the change in the potential of the wiring LBL_1 when the data retained in the circuit UC is “3” is indicated by a thick solid line; the change in the potential of the wiring LBL_1 when the data retained in the circuit UC is “2” is indicated by a thick dashed double-dotted line; the change in the potential of the wiring LBL_1 when the data retained in the circuit UC is “1” is indicated by a thick dashed-dotted line; and the change in the potential of the wiring LBL_1 when the data retained in the circuit UC is “0” is indicated by a thick dashed line.

At this time, the potentials V_{INI} of the wiring GBL_1 to the wiring GBL_3 each increase or decrease to a potential corresponding to the potential VDD of the wiring SL_1 and the gate potential of the transistor M10_1 (the potential of the wiring LBL_1). When the potential of the wiring LBL_1 is any one of V₀₀, V₀₁, V₁₀, and V₁₁, the potentials of the wiring GBL_1 to the wiring GBL_3 are each V_{GBL00}, V_{GBL01}, V_{GBL10}, or V_{GBL11}. As for the potential level of V_{GBL00}, V_{GBL01}, V_{GBL10}, and V_{GBL11}, V_{GBL11} is the highest, V_{GBL10} is the second highest, V_{GBL01} is the second lowest, and V_{GBL00} is the lowest. The timing chart in FIG. 16 shows changes in the potentials of the wiring GBLB_1 to the wiring GBLB_3 for the case where the potentials of the wiring LBL_1 are V₀₀, V₀₁, V₁₀, and V₁₁. Specifically, as for the wiring GBLB_1 to the wiring GBLB_3 in the timing chart in FIG. 16, the changes in the potentials of the wiring GBLB_1 to the wiring GBLB_3 when the potential of the wiring LBL_1 is V₁₁ are indicated by thick solid lines; the changes in the potentials of the wiring GBLB_1 to the wiring GBLB_3 when the potential of the wiring LBL_1 is V₁₀ are indicated by thick dashed double-dotted lines; the changes in the potentials of the wiring GBLB_1 to the wiring GBLB_3 when the potential of the wiring LBL_1 is V₀₁ are indicated by thick dashed-dotted lines; and the changes in the potentials of the wiring GBLB_1 to the wiring GBLB_3 when the potential of the wiring LBL_1 is V₀₀ are indicated by thick dashed lines. Note that in the timing chart in FIG. 16, although V_{INI} is higher than V_{GBL01} and lower than V_{GBL10}, V_{INI} may be lower than or equal to V_{GBL01} or higher than or equal to V_{GBL10} depending on the case.

From Time T03 to Time T04, a low-level potential is input to the wiring S1LB and the wiring S2LB. Accordingly, the switch SWB_1 and the switch SWB_2 are brought into an off state, and electrical continuity between the wiring GBLB_1 and the wiring GBLB_2 and between the wiring GBLB_2 and the wiring GBLB_3 is broken.

From Time T04 to Time T05, a high-level potential is input to the wiring CRL[1] to the wiring CRL[3]. Accordingly, electrical continuity is established between the first terminal of the capacitor C2 of the reference cell VC[1] and the wiring RBLB_1, electrical continuity is established between the first terminal of the capacitor C2 of the reference cell VC[2] and the wiring RBLB_2, and electrical continuity is established between the first terminal of the capacitor C2 of the reference cell VC[3] and the wiring RBLB_3. Thus, a signal corresponding to Vₜₕ[1] is output from the reference cell VC[1] to the wiring RBLB_1, a signal corresponding to Vₜₕ[2] is output from the reference cell VC[2] to the wiring RBLB_2, and a signal corresponding to Vₜₕ[3] is output from the reference cell VC[3] to the wiring RBLB_3. Specifically, the potential of the first terminal of the capacitor C2 of the reference cell VC[1] and the potential of the wiring RBLB_1 change, the potential of the first terminal of the capacitor C2 of the reference cell VC[2] and the potential of the wiring RBLB_2 change, and the potential of the first terminal of the capacitor C2 of the reference cell VC[3] and the potential of the wiring RBLB_3 change. At this time, the potential of the first terminal of the capacitor C2 of the reference cell VC[1] changes from Vₜₕ[1] to Vₜₕ[1]−ΔVₜₕ[1], the potential of the first terminal of the capacitor C2 of the reference cell VC[2] changes from Vₜₕ[2] to Vₜₕ[2]−ΔVₜₕ[2], and the potential of the first terminal of the capacitor C2 of the reference cell VC[3] changes from Vₜₕ[3] to Vₜₕ[3]−ΔVₜₕ[3]. Thus, the potential of the wiring RBLB_1 changes from VSS to Vₜₕ[1]−ΔVₜₕ[1], the potential of the wiring RBLB_2 changes from VSS to Vₜₕ[2]−ΔVₜₕ[2], and the potential of the wiring RBLB_3 changes from VSS to Vₜₕ[3]−ΔVₜₕ[3]. Note that ΔVₜₕ[1] to ΔVₜₕ[3] denote the amount of change in the potentials that are determined in accordance with parasitic resistance or the like around the wiring RBLB_1 to the wiring RBLB_3.

At this time, the potentials V_{INI} of the wiring GBLB_1 to the wiring GBLB_3 increase to potentials corresponding to the potentials VDD of the wiring SLRB_1 to the wiring SLRB_3 and the potentials of the wiring RBLB_1 to the wiring RBLB_3. Here, the potentials of the wiring GBLB_1 to the wiring GBLB_3 change to V_{thRF}[1], V_{thRF}[2], and V_{thRF}[3], respectively. That is, V_{thRF}[1] is a potential corresponding to Vin[1]−ΔVₜₕ[1] that is the gate potential of the transistor M11B_1, V_{thRF}[2] is a potential corresponding to Vₜₕ[2]−ΔVₜₕ[2] that is the gate potential of the transistor M11B_2, and V_{thRF}[3] is a potential corresponding to Vₜₕ[3]−ΔVₜₕ[3] that is the gate potential of the transistor M11B_3. In other words, V_{thRF}[1] is a potential corresponding to the first threshold voltage Vₜₕ[1], V_{thRF}[2] is a potential corresponding to the second threshold voltage Vₜₕ[2], and V_{thRF}[3] is a potential corresponding to the third threshold voltage Vₜₕ[3].

Here, V_{thRF}[1] is a potential higher than V_{GBL00} and lower than V_{GBL01}. In addition, V_{thRF}[2] is a potential higher than V_{GBL01} and lower than V_{GBL10}. Moreover, V_{thRF}[3] is a potential higher than V_{GBL10} and lower than V_{GBL11}. Note that in the timing chart in FIG. 16, although V_{thRF}[2] is shown as a potential higher than V_{INI}, V_{thRF}[2] may be a potential lower than or equal to V_{INI}.

From Time T05 to Time T06, a low-level potential is input to the wiring S1L and the wiring S2L. Accordingly, the switch SW_1 and the switch SW_2 are brought into an off state, so that electrical continuity between the wiring GBL_1 and the wiring GBL_2 and between the wiring GBL_2 and the wiring GBL_3 is broken.

From Time T06 to Time T07, the potential of the wiring ACL changes from a low-level potential to a high-level potential. Thus, the sense amplifier SA_1 to the sense amplifier SA_3 are activated. When the sense amplifier SA_1 is activated, one of the potential of the wiring GBL_1 and the potential of the wiring GBLB_1 changes to VDD, and the other of the potential of the wiring GBL_1 and the potential of the wiring GBLB_1 changes to VSS. Similarly, when the sense amplifier SA_2 is driven, one of the potential of the wiring GBL_2 and the potential of the wiring GBLB_2 changes to VDD, and the other of the potential of the wiring GBL_2 and the potential of the wiring GBLB_2 changes to VSS. Similarly, when the sense amplifier SA_3 is driven, one of the potential of the wiring GBL_3 and the potential of the wiring GBLB_3 changes to VDD, and the other of the potential of the wiring GBL_3 and the potential of the wiring GBLB_3 changes to VSS.

Here, the changes in the potential of the wiring GBL_1 and the potential of the wiring GBLB_1 are described. The potential of the wiring GBLB_1 is V_{thRF}[1] corresponding to the first threshold voltage. In the case where the potential of the wiring GBL_1 is higher than V_{thRF}[1], the potential of the wiring GBL_1 changes to VDD and the potential V_{thRF}[1] of the wiring GBLB_1 changes to VSS. In the case where the potential of the wiring GBL_1 is lower than V_{thRF}[1], the potential of the wiring GBL_1 changes to VSS and the potential V_{thRF}[1] of the wiring GBLB_1 changes to VDD. That is, the potential of the wiring GBL_1 changes to VSS when the potential of the wiring GBL_1 is V_{GBL00}, and the potential of the wiring GBL_1 changes to VDD when the potential of the wiring GBL_1 is any one of V_{GBL01}, V_{GBL10}, and V_{GBL11}.

Next, the changes in the potential of the wiring GBL_2 and the potential of the wiring GBLB_2 are described. The potential of the wiring GBLB_2 is V_{thRF}[2] corresponding to the second threshold voltage. In the case where the potential of the wiring GBL_2 is higher than V_{thRF}[2], the potential of the wiring GBL_2 changes to VDD and the potential V_{thRF}[2] of the wiring GBLB_2 changes to VSS. In the case where the potential of the wiring GBL_2 is lower than V_{thRF}[2], the potential of the wiring GBL_2 changes to VSS and the potential V_{thRF}[2] of the wiring GBLB_2 changes to VDD. That is, the potential of the wiring GBL_2 changes to VSS when the potential of the wiring GBL_2 is V_{GBL00} Or V_{GBL01}, and the potential of the wiring GBL_2 changes to VDD when the potential of the wiring GBL_2 is V_{GBL10} Or V_{GBL11}.

Next, the changes in the potential of the wiring GBL_3 and the potential of the wiring GBLB_3 are described. The potential of the wiring GBLB_3 is V_{thRF}[3] corresponding to the third threshold voltage. In the case where the potential of the wiring GBL_3 is higher than V_{thRF}[3], the potential of the wiring GBL_3 changes to VDD and the potential V_{thRF}[3] of the wiring GBLB_3 changes to VSS. In the case where the potential of the wiring GBL_3 is lower than V_{thRF}[3], the potential of the wiring GBL_3 changes VSS and the potential V_{thRF}[3] of the wiring GBLB_3 changes to VDD. That is, the potential of the wiring GBL_3 changes to VSS when the potential of the wiring GBL_3 is any one of V_{GBL00}, V_{GBL01}, and V_{GBL10}, and the potential of the wiring GBL_3 changes to VDD when the potential of the wiring GBL_3 is V_{GBL11}.

Specifically, as for the wiring GBL_1 to the wiring GBL_3 in the timing chart in FIG. 16, the changes in the potentials of the wiring GBL_1 to the wiring GBL_3 when the potentials of the wiring GBL_1 to the wiring GBL_3 are V_{GBL11} are indicated by thick solid lines; the changes in the potentials of the wiring GBL_1 to the wiring GBL_3 when the potentials of the wiring GBL_1 to the wiring GBL_3 are V_{GBL10} are indicated by thick dashed double-dotted lines; the changes in the potentials of the wiring GBL_1 to the wiring GBL_3 when the potentials of the wiring GBL_1 to the wiring GBL_3 are V_{GBL01} are indicated by thick dashed-dotted lines; and the changes in the potentials of the wiring GBL_1 to the wiring GBL_3 when the potentials of the wiring GBL_1 to the wiring GBL_3 are V_{GBL00} are indicated by thick dashed lines.

As for the wiring GBLB_1 in the timing chart in FIG. 16, the change in the potential of the wiring GBLB_1 when the potential of the wiring GBL_1 is V_{GBL11} is indicated by a thick solid line; the change in the potential of the wiring GBLB_1 when the potential of the wiring GBL_1 is V_{GBL10} is indicated by a thick dashed double-dotted line; the change in the potential of the wiring GBLB_1 when the potential of the wiring GBL_1 is V_{GBL01} is indicated by a thick dashed-dotted line; and the change in the potential of the wiring GBLB_1 when the potential of the wiring GBL_1 is V_{GBL00} is indicated by a thick dashed line. Similarly, as for the wiring GBLB_2 (the wiring GBLB_3) in the timing chart in FIG. 16, the change in the potential of the wiring GBLB_2 (the wiring GBLB_3) when the potential of the wiring GBL_2 (the wiring GBL_3) is V_{GBL11} is indicated by a thick solid line; the change in the potential of the wiring GBLB_2 (the wiring GBLB_3) when the potential of the wiring GBL_2 (the wiring GBL_3) is V_{GBL10} is indicated by a thick dashed double-dotted line; the change in the potential of the wiring GBLB_2 (the wiring GBLB_3) when the potential of the wiring GBL_2 (the wiring GBL_3) is V_{GBL01} is indicated by a thick dashed-dotted line; and the change in the potential of the wiring GBLB_2 (the wiring GBLB_3) when the potential of the wiring GBL_2 (the wiring GBL_3) is V_{GBL00} is indicated by a thick dashed line.

From Time T06 to Time T07 in the timing chart in FIG. 16, for example, the change in the potential of the wiring GBL_1 caused by the sense amplifier SA_1 is shown such that the potentials V_{GBL11}, V_{GBL10}, V_{GBL01}, and V_{GBL00} have different rising speed and falling speed to clearly show the changes of the potentials V_{GBL11}, V_{GBL10}, V_{GBL01}, and V_{GBL00} to VDD or VSS. Therefore, in actual operation, the speed of rise and fall of the potential of the wiring GBL_1 due to the sense amplifier SA_1 does not necessarily depend on the potentials V_{GBL11}, V_{GBL10}, V_{GBL01}, and V_{GBL00}.

Data retained in the circuit UC of the memory device 100A can be read through the above-described operation example in which the potentials of the wiring GBL_1 to the wiring GBL_3 and the potentials of the wiring GBLB_1 to the wiring GBLB_3 from Time T06 to Time T07 are obtained. In the case where any one of “0”, “1”, “2”, and “3”, which is 4-level data, is retained in the circuit UC, the potentials of the wiring GBL_1 to the wiring GBL_3 obtained by reading in the above-described operation example are shown in the following table.

TABLE 1

| Potential | Potential | Potential | Potential |
|---|---|---|---|
| retained in | of wiring | of wiring | of wiring |
| circuit UC | GBL[1] | GBL[2] | GBL[3] |
| V₀₀ | VSS | VSS | VSS |
| V₀₁ | VDD | VSS | VSS |
| V₁₀ | VDD | VDD | VSS |
| V₁₁ | VDD | VDD | VDD |
| Potential | Potential | Potential | Potential |
| retained in | of wiring | of wiring | of wiring |
| circuit UC | GBLB[1] | GBLB[2] | GBLB[3] |
| V₀₀ | VDD | VDD | VDD |
| V₀₁ | VSS | VDD | VDD |
| V₁₀ | VSS | VSS | VDD |
| V₁₁ | VSS | VSS | VSS |

In the case of configuring a memory device that reads a 4-level potential, as in the memory device 100 in FIG. 8 and the memory device 100A in FIG. 15, the same number of sense amplifiers as the number of the threshold voltages for reading the 4-level potential (in this case, three threshold voltages Vₜₕ[1] to Vₜₕ[3]) are provided, and the levels of a potential read from a memory cell (e.g., the circuit UC) and potentials corresponding to Vₜₕ[1] to Vₜₕ[3] are compared using the sense amplifiers, so that the potential retained in the memory cell can be read.

Note that the operation method of the structure example of the memory device described in this embodiment is not limited to the operation from Time T01 to Time T07 and around the period shown in the timing chart shown in FIG. 16. Specifically, in the timing chart described in this specification and the like, a wiring whose potential changes, operation of changing a potential, a timing when a potential changes, or the like can be changed according to circumstances. For example, from Time T01 to Time T02 in the timing chart in FIG. 16, the potential of the wiring EQ is changed from a high-level potential to a low-level potential, and then the potentials of the wiring S1LB and the wiring S2LB are changed from a high-level potential to a low-level potential, whereby signals corresponding to Vₜₕ[1] to Vₜₕ[3] can be output from the reference cell portion RFCB_1 to the reference cell portion RFCB_3 to the gates of the transistor M11B_1 to the transistor M11B_3 from Time T02 to Time T03. That is, in the operation method of the structure example of the memory device described in this embodiment, data reading from the circuit UC can be performed concurrently with reading of Vₜₕ[1] to Vₜₕ[3] respectively from the reference cell portion RFC_1 to the reference cell portion RFC_3.

In this embodiment, the structure examples of the memory device that can write and read a 4-level potential as data, which is the memory device of one embodiment of the present invention, and the operation example of the memory device are described. Note that one embodiment of the present invention is not limited to the memory device 100 illustrated in FIG. 8 and the memory device 100A illustrated in FIG. 15, and one embodiment of the present invention may have a circuit structure changed from those of the memory devices according to circumstances.

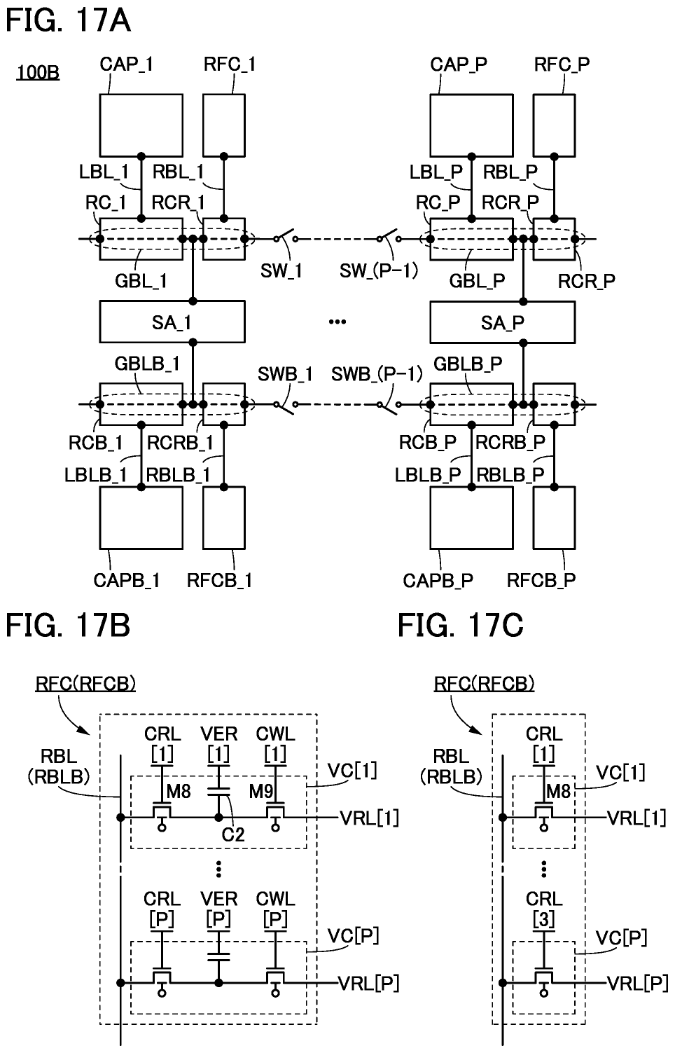

For example, in the case where a memory device that can write and read a (P+1)-level potential (P is an integer of 1 or more), the circuit structure of the memory device 100 illustrated in FIG. 8 can be changed to that of a memory device 100B illustrated in FIG. 17A. The memory device 100B includes P sense amplifiers to read a (P+1)-level potential.

Specifically, the memory device 100B in FIG. 17A includes the cell array portion CAP_1 to a cell array portion CAP_P, the cell array portion CAPB_1 to a cell array portion CAPB_P, the reference cell portion RFC_1 to a reference cell portion RFC_P, the reference cell portion RFCB_1 to a reference cell portion RFCB_P, the circuit RC_1 to a circuit RC_P, the circuit RCB_1 to a circuit RCB_P, the circuit RCR_1 to a circuit RCR_P, the circuit RCRB_1 to a circuit RCRB_P, the sense amplifier SA_1 to a sense amplifier SA_P, the switch SW_1 to a switch SW_(P−1), and the switch SWB_1 to a switch SWB_(P−1), for example. For the electrical connection relation of these circuits and circuit elements, the description of the memory device 100 in FIG. 8 is referred to.

Note that FIG. 17A illustrates only the cell array portion CAP_1, the cell array portion CAP_P, the cell array portion CAPB_1, the cell array portion CAPB_P, the reference cell portion RFC_1, the reference cell portion RFC_P, the reference cell portion RFCB_1, the reference cell portion RFCB_P, the circuit RC_1, the circuit RC_P, the circuit RCB_1, the circuit RCB_P, the circuit RCR_1, the circuit RCR_P, the circuit RCRB_1, the circuit RCRB_P, the switch SW_1, the switch SW_(P−1), the switch SWB_1 to the switch SWB_(P−1), the wiring LBL_1, a wiring LBL_P, the wiring LBLB_1, a wiring LBLB_P, the wiring RBL_1, a wiring RBL_P, the wiring RBLB_1, a wiring RBLB_P, the wiring GBL_1, a wiring GBL_P, the wiring GBLB_1, and a wiring GBLB_P; and the other circuits, wiring, and the like are omitted.

For the memory device 100B that reads a (P+1)-level potential, P threshold voltages need to be set. The P threshold voltages of the memory device 100B are defined as the first threshold voltage Vₜₕ[1] to the P-th threshold voltage Vₜₕ[P], for example.

Thus, the reference cell portion RFC_1 to the reference cell portion RFC_P and the reference cell portion RFCB_1 to the reference cell portion RFCB_P included in the memory device 100B preferably have a circuit structure of the reference cell portion RFC (the reference cell portion RFCB) illustrated in FIG. 10B. The reference cell portion RFC (the reference cell portion RFCB) includes the reference cell VC[1] to a reference cell VC[P]. The reference cell VC[1] to the reference cell VC[P] have circuit structures similar to those of the reference cell VC[1] to the reference cell VC[3] included in the reference cell portion RFC (the reference cell portion RFCB) in FIG. 11A. Here, voltages supplied from the wiring VRL[1] to a wiring VRL[P] are the first threshold voltage to the P-th threshold voltage or voltages corresponding to the threshold voltages. That is, in the reference cell portion RFC (the reference cell portion RFCB), by changing potentials supplied from a wiring CWL[P] and a wiring CRL[P] while a predetermined potential is applied to a wiring VER[P], the potential of the wiring RBL (the wiring RBLB) can be changed to a potential corresponding to any one of Vₜₕ[1] to Vₜₕ[P].

When P−2, for example, the memory device 100B is a memory device that can read and write a 3-level potential as data. As another example, when P=4, the memory device 100B is a memory device that can write and read a 5-level potential as data.

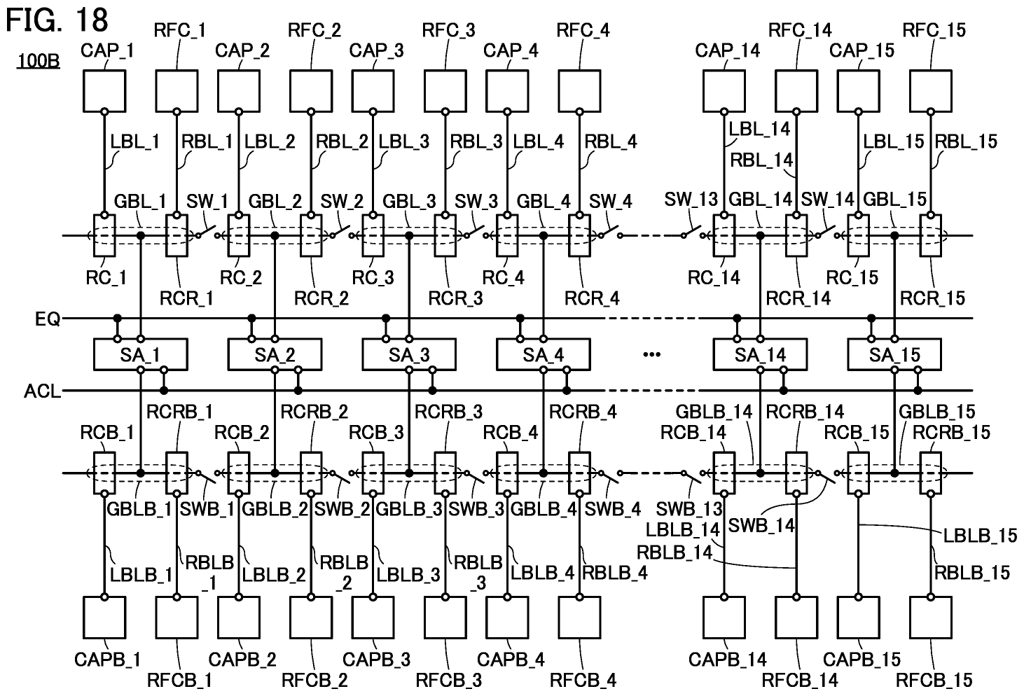

In the case where the circuit UC included in the cell array portion CAP retains 16-level data as in the memory device MDV in FIG. 1 described in Embodiment 1, the memory device 100B illustrated in FIG. 17A can be the memory device 100B illustrated in FIG. 18 with P=15.

The memory device 100B in FIG. 18 includes the cell array portion CAP_1 to a cell array portion CAP_15, the cell array portion CAPB_1 to a cell array portion CAPB_15, the reference cell portion RFC_1 to a reference cell portion RFC_15, the reference cell portion RFCB_1 to a reference cell portion RFCB_15, the circuit RC_1 to a circuit RC_15, the circuit RCB_1 to a circuit RCB_15, the circuit RCR_1 to a circuit RCR 15, the circuit RCRB_1 to a circuit RCRB 15, the sense amplifier SA_1 to a sense amplifier SA_15, the switch SW_1 to a switch SW_14, and the switch SWB_1 to a switch SWB_14, for example.

Note that FIG. 18 also illustrates the wiring LBL_1 to a wiring LBL_15, the wiring LBLB_1 to a wiring LBLB_15, the wiring RBL_1 to a wiring RBL_15, the wiring RBLB_1 to a wiring RBLB_15, the wiring GBL_1 to a wiring GBL_15, the wiring GBLB_1 to a wiring GBLB_15, the wiring EQ, and the wiring ACL.

Like the reference cell portion RFC (the reference cell portion RFCB) in FIG. 17C, the reference cell portion RFC and the reference cell portion RFCB of the memory device 100B in FIG. 17A may each be a circuit in which the reference cell portion RFC (the reference cell portion RFCB) in FIG. 11B and the reference cell portion RFC (the reference cell portion RFCB) in FIG. 17B are combined.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 3

In this embodiment, structure examples of the memory devices described in the above embodiments and structure examples of transistors and capacitors that are included in the memory devices are described.

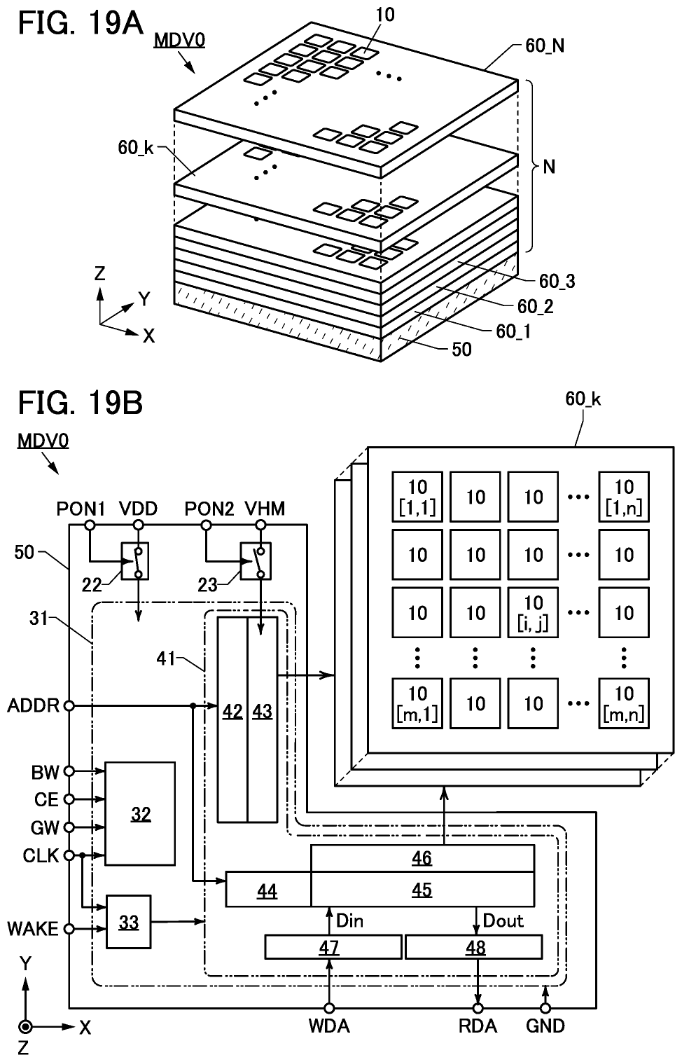

FIG. 19A is a schematic perspective view illustrating a structure example of a memory device MDV0. FIG. 19B is a block diagram illustrating the structure example of the memory device MDV0. The memory device MDV0 includes a driver circuit layer 50 and the N memory layers 60 (N is an integer greater than or equal to 1). One memory layer 60 includes a plurality of memory cells 10 arranged in a matrix of m rows and n columns. Note that FIG. 19B illustrates an example in which a memory cell 10[1,1], a memory cell 10[m,1] (here, m is an integer greater than or equal to 1), a memory cell 10[1,n] (here, n is an integer greater than or equal to 1), a memory cell 10[m,n], and a memory cell 10[i,j] (here, i is an integer greater than or equal to 1 and less than or equal to m, and j is an integer greater than or equal to 1 and less than or equal to n) are provided in a memory layer 60_k.

Note that the memory layers 60 corresponds to the layer LY_A to the layer LY_D described in Embodiment 1. The memory cells 10 corresponds to the memory cell MC_A to the memory cell MC_D (or the memory cell MC_Aa to the memory cell MC_Da and the memory cell MC_Ab to the memory cell MC_Db) described in Embodiment 1.

The N memory layers 60 are provided over the driver circuit layer 50. Provision of the N memory layers 60 over the driver circuit layer 50 can reduce the area occupied by the memory device 100. Furthermore, the memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. In this embodiment and the like, the “memory layer 60” is merely stated in some cases when describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device MDV0, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs logical operation on the signal CE, the signal GW, and the signal BW to determine an operation mode (e.g., writing operation or reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

The row driver 43 has a function of selecting write and read word line specified by the row decoder 42 (e.g., the wiring WL_A[1] to the wiring WL_A[m], the wiring WL_B[1] to the wiring WL_B[m], the wiring WL_C[1] to the wiring WL_C[m], the wiring WL_D[1] to the wiring WL_D[m] illustrated in FIG. 1 or the wiring WL_A[i], the wiring WL_B[i], the wiring WL_C[i], and the wiring WL_D[i] illustrated in FIG. 2 and FIG. 5). That is, the row driver 43 corresponds to the driver circuit WD illustrated in FIG. 1, FIG. 2, and FIG. 5 described in Embodiment 1.

The column driver 45 has a function of writing data to the memory cells 10, a function of reading data from the memory cells 10, and a function of retaining the read data. The column driver 45 has a function of selecting a write and read bit line specified by the column decoder 44 (e.g., the wiring BL[1] to the wiring BL[n] illustrated in FIG. 1 or the wiring BL[j] illustrated in FIG. 2 and FIG. 5). That is, the column driver 45 corresponds to the driver circuit WBD and the driver circuit RBD illustrated in FIG. 1, FIG. 2, and FIG. 5.

The input circuit 47 has a function of retaining the signal WDA. Data retained by the input circuit 47 (the first data in the above embodiment) is output to the column driver 45. Data output from the input circuit 47 is data (Din) to be written to the memory cells 10. Data (Dout) read from the memory cells 10 by the column driver 45 is amplified by the sense amplifier 46 and output to the output circuit 48. The output circuit 48 has a function of retaining Dout. In addition, the output circuit 48 has a function of outputting Dout to the outside of the memory device 100. Data output from the output circuit 48 is the signal RDA.

Note that the sense amplifier 46 illustrated in FIG. 19B corresponds to the sense amplifier SA_1 to the sense amplifier SA_3 illustrated in FIG. 8 and FIG. 15, the sense amplifier SA_1 to the sense amplifier SA_P illustrated in FIG. 17A, and the sense amplifier SA_1 to the sense amplifier SA_15 illustrated in FIG. 18.

The PSW 22 has a function of controlling supply of VDD to the peripheral circuit 31. The PSW 23 has a function of controlling supply of VHM to the row driver 43. In the memory device 100, a high power supply voltage is VDD and a low power supply voltage is GND (ground potential). In addition, VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 19B but can be more than one. In this case, a power switch is provided for each power domain.

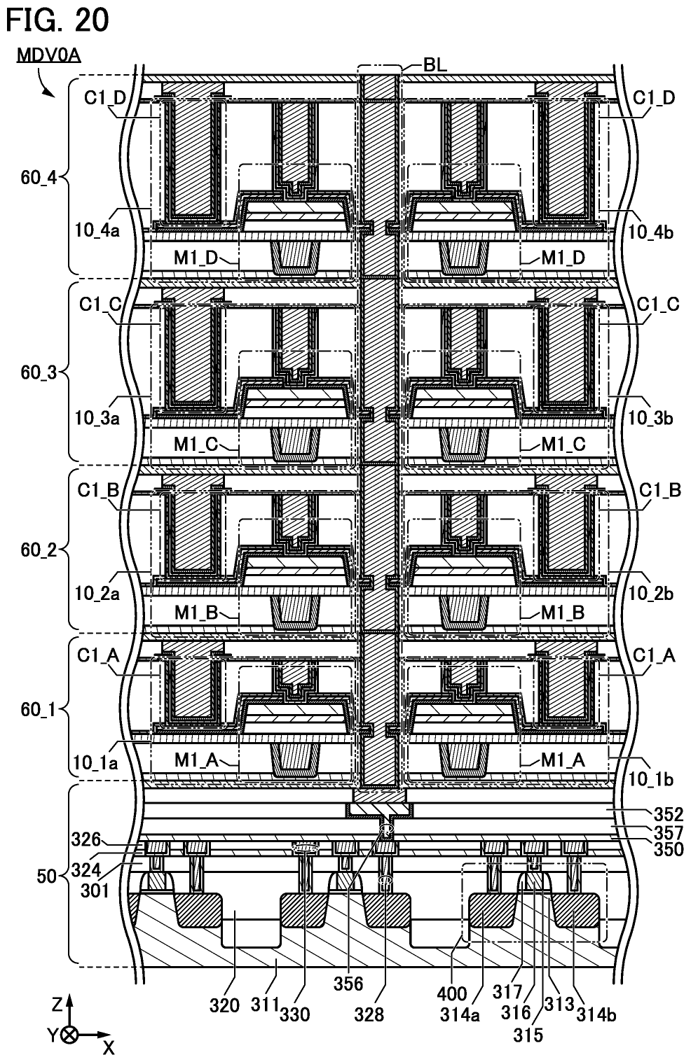

Next, FIG. 20 illustrates a cross-sectional structure example of the memory device MDV0 of one embodiment of the present invention. A memory device MDV0A illustrated in FIG. 20 is an example of the memory device MDV0 in which the driver circuit layer 50 shown in the memory device MDV0 in FIG. 19A or 19B is provided in the memory device MDVA1 in FIG. 6 described in Embodiment 1. In FIG. 20, the memory device MDV0A includes a plurality of memory layers 60 above the driver circuit layer 50. In FIG. 20, the memory layer 60_1 corresponds to the layer LY_A in FIG. 6, the memory layer 60_2 corresponds to the layer LY_B in FIG. 6, the memory layer 60_3 corresponds to the layer LY_C in FIG. 6, and a memory layer 60_4 corresponds to the layer LY_D in FIG. 6. The description of the memory layers 60 in this embodiment is omitted in order to reduce repeated description.

FIG. 20 illustrates a transistor 400 included in the driver circuit layer 50 as an example. The transistor 400 is provided over a substrate 311 and includes a conductor 316 functioning as a gate, an insulator 315 functioning as a gate insulator, an insulator 317 formed on the side surface of the gate, a semiconductor region 313 that includes part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

In the transistor 400 illustrated in FIG. 20, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. The transistor 400 is also referred to as a FIN transistor because it utilizes a protruding portion of the semiconductor substrate. An insulator functioning as a mask for forming the protruding portion may be provided in contact with the top surface of the protruding portion. Although the case where the protruding portion is formed by processing part of the semiconductor substrate is described here, a semiconductor film having a protruding shape may be formed by processing a silicon-on-insulator (SOI) substrate.

Note that the transistor 400 illustrated in FIG. 20 is just an example and is not limited to the structure illustrated therein; an appropriate transistor is used in accordance with a circuit structure or a driving method.

Wiring layers including an interlayer film, a wiring, and a plug may be provided between the structure bodies. A plurality of wiring layers can be provided in accordance with the design. Furthermore, in this specification and the like, a wiring and a plug electrically connected to the wiring may be a single component. That is, in some cases, part of a conductor functions as a wiring or part of a conductor functions as a plug.

For example, an insulator 320, an insulator 301, an insulator 324, and an insulator 326 are stacked over the transistor 400 in this order as interlayer films. A conductor 328 or the like is embedded in the insulator 320 and the insulator 301. A conductor 330 or the like is embedded in the insulator 324 and the insulator 326. Note that the conductor 328 and the conductor 330 function as contact plugs or wirings.

The insulator functioning as an interlayer film may function as a planarization film that covers a roughness thereunder. For example, the top surface of the insulator 301 may be planarized by planarization treatment using a chemical mechanical polishing (CMP) method or the like to increase the level of planarity.

A wiring layer may be provided over the insulator 326 and the conductor 330. For example, in FIG. 20, an insulator 350, an insulator 357, and an insulator 352 are stacked in this order over the insulator 326 and the conductor 330. A conductor 356 is formed in the insulator 350, the insulator 357, and the insulator 352. The conductor 356 functions as a contact plug or a wiring. For example, the transistor 400 is electrically connected to the wiring BL through the conductor 356, the conductor 330, and the like. Although FIG. 20 illustrates the structure in which the transistor 400 is electrically connected to the wiring BL, the transistor 400 may be electrically connected to the wiring WL_A, the wiring WL_B, the wiring WL_C, and the wiring WL_D.

### <Structure Example 1 of Memory Layer 60>

Next, the memory layer 60_1 to the memory layer 60_4 are described.

In FIG. 20, the memory layer 60_1 includes a memory cell 10_1a and a memory cell 10_1b as memory cells 10 illustrated in FIGS. 19A and 19B. Note that the memory cell 10_1a and the memory cell 10_1b corresponds to the memory cell MC_Aa and the memory cell MC_Ab illustrated in FIG. 6, respectively. Similarly, the memory layer 60_2 includes a memory cell 10_2a and a memory cell 10_2b corresponding to the memory cell MC_Ba and the memory cell MC_Bb illustrated in FIG. 6, respectively; the memory layer 60_3 includes a memory cell 10_3a and a memory cell 10_3b corresponding to the memory cell MC_Ca and the memory cell MC_Cb illustrated in FIG. 6, respectively; and the memory layer 60_4 includes a memory cell 10_4a and a memory cell 10_4b corresponding to the memory cell MC_Da and the memory cell MC_Db illustrated in FIG. 6, respectively.

Therefore, in FIG. 20, the memory cell 10_1a and the memory cell 10_1b each include the transistor M1_A and the capacitor C1_A, the memory cell 10_2a and the memory cell 10_2b each include the transistor M1_B and the capacitor C1_B, the memory cell 10_3a and the memory cell 10_3b each include the transistor M1_C and the capacitor C1_C, and the memory cell 10_4a and the memory cell 10_4b each include the transistor M1_D and the capacitor C1_D.

Next, specific structure examples of the transistor M1 and the capacitor C1 included in the memory layer 60 are described.

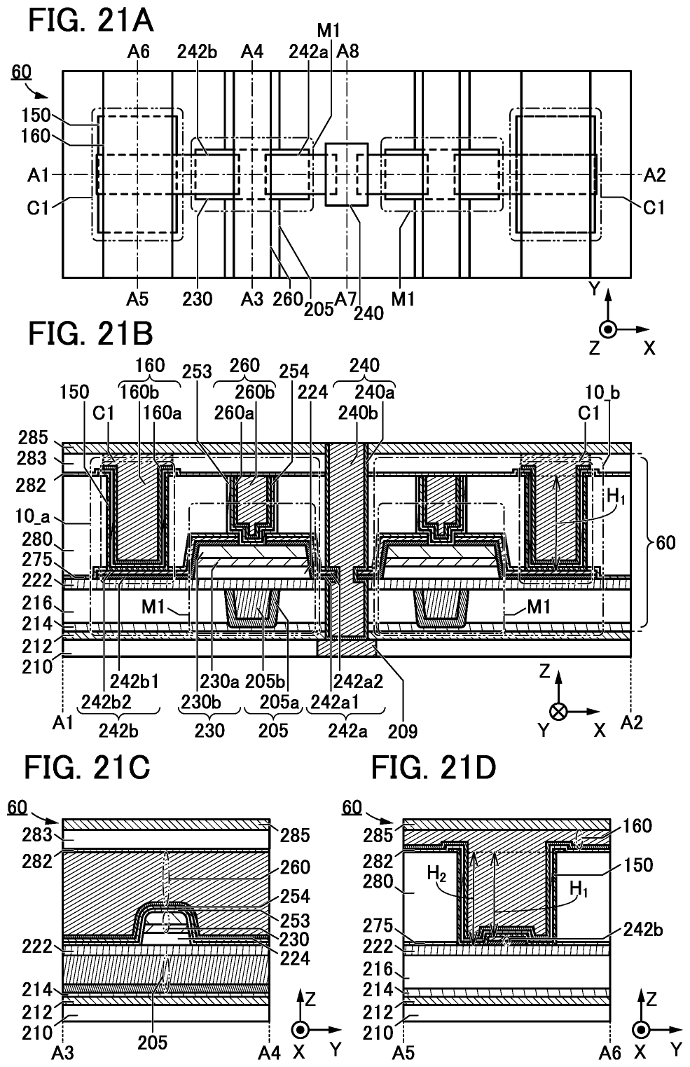

FIGS. 21A to 21D are a schematic plan view and schematic cross-sectional views of any one of the memory layer 60_1 to the memory layer 60_4 each including the transistor M1 and the capacitor C1 in the memory device MDV0A in FIG. 20. FIG. 21A is a schematic plan view of the memory layer 60. FIGS. 21B to 21D are schematic cross-sectional views of the memory layer 60. FIG. 21B is a schematic cross-sectional view taken along dashed-dotted line A1-A2 illustrated in FIG. 21A, which corresponds to a schematic cross-sectional view of the transistor M1 in the channel length direction. FIG. 21C is a schematic cross-sectional view taken along dashed-dotted line A3-A4 illustrated in FIG. 21A, which corresponds to a schematic cross-sectional view of the transistor M1 in the channel width direction. FIG. 21D is a schematic cross-sectional view taken along dashed-dotted line A5-A6 illustrated in FIG. 21A, which corresponds to a schematic cross-sectional view of the capacitor C1. Note that for simplification, some components are not illustrated in the plan view of FIG. 21A.

The X direction illustrated in FIGS. 21A to 21D is parallel to the channel length direction of the transistor M1.

A semiconductor device of one embodiment of the present invention includes an insulator 210 over a substrate (not illustrated), an insulator 212 over the insulator 210, an insulator 214 over the insulator 212, the transistor M1 and the capacitor C1 over the insulator 214, the insulator 280 over the insulator 275, an insulator 282 over the capacitor C1 and over the insulator 280, an insulator 283 over the insulator 282, an insulator 285 over the insulator 283, and an conductor 240 (a conductor 240a and a conductor 240b). The insulator 210, the insulator 212, the insulator 214, the insulator 280, the insulator 282, and the insulator 285 each function as an interlayer film. As illustrated in FIG. 21B, at least parts of the transistor M1 and the capacitor C1 are placed to be embedded in the insulator 280.

Here, the transistor M1 includes an oxide 230 (an oxide 230a and an oxide 230b) functioning as a semiconductor layer, a conductor 260 (a conductor 260a and a conductor 260b) functioning as a first gate (also referred to as a top gate) electrode, a conductor 205 (a conductor 205a and a conductor 205b) functioning as a second gate (also referred to as a back gate) electrode, the conductor 242a (a conductor 242al and a conductor 242a2) functioning as one of a source electrode and a drain electrode, and the conductor 242b (a conductor 242b1 and a conductor 242b2) functioning as the other of the source electrode and the drain electrode. An insulator 253 and an insulator 254 functioning as a first gate insulator are also included. An insulator 222 and an insulator 224 functioning as a second gate insulator are also included. Note that the gate insulator is also referred to as a gate insulating layer or a gate insulating film in some cases.

Note that since two transistors M1 illustrated in FIGS. 21A and 21B have the same structure, a common part of the two transistors M1 is described below without distinguishing them.

The insulator 280 corresponds to any one of the insulating layer SK_A to the insulating layer SK_D in the memory device MDVA1 in FIG. 6 described in Embodiment 1. The insulator 224 corresponds to the first insulator in the memory device MDVA1 in FIG. 6 described in Embodiment 1. The oxide 230 corresponds to the semiconductor in the memory device MDVA1 in FIG. 6 described in Embodiment 1. The conductor 242b corresponds to the one of the pair of first conductors in the memory device MDVA1 in FIG. 6 described in Embodiment 1. The conductor 242a corresponds to the other of the pair of first conductors in the memory device MDVA1 in FIG. 6 described in Embodiment 1. The insulator 253 and the insulator 254 each correspond to the second insulator in the memory device MDVA1 in FIG. 6 described in Embodiment 1. The conductor 260 corresponds to the second conductor in the memory device MDVA1 in FIG. 6 described in Embodiment 1. The insulator 222 corresponds to the third insulator in the memory device MDVA1 in FIG. 6 described in Embodiment 1. The conductor 205 corresponds to the third conductor in the memory device MDVA1 in FIG. 6 described in Embodiment 1. The conductor 150 corresponds to the fourth conductor in the memory device MDVA1 in FIG. 6 described in Embodiment 1. The insulator 282 corresponds to the fourth insulator in the memory device MDVA1 in FIG. 6 described in Embodiment 1. The conductor 160 corresponds to the fifth conductor in the memory device MDVA1 in FIG. 6 described in Embodiment 1. The conductor 240 corresponds to the sixth conductor in the memory device MDVA1 in FIG. 6 described in Embodiment 1.

The first gate electrode and the first gate insulating film are placed inside a first opening formed in the insulator 280 and the insulator 275. That is, the conductor 260, the insulator 254, and the insulator 253 are placed inside the first opening.

Inside a second opening formed in the insulator 280 and the insulator 275, a dielectric and a pair of electrodes of the capacitor C1 are provided. In other words, at least part of the capacitor C1 is included inside the second opening. For example, in FIGS. 21B and 21D, the insulator 282 functioning as the dielectric of the capacitor C1, the conductor 150 functioning as one of the pair of electrodes of the capacitor C1, and the conductor 160 (a conductor 160a and a conductor 160b) functioning as the other of the pair of electrodes of the capacitor C1 are placed inside the second opening. That is, in FIGS. 21A to 21D, the capacitor C1 has a metal-insulator-metal (MIM) capacitor. In FIGS. 21A to 21D, the capacitor C1 forms a trench capacitor.

Note that since two capacitors C1 illustrated in FIGS. 21A and 21B have the same structure, a common part of the two capacitors C1 is described below without distinguishing them.

The memory device of one embodiment of the present invention also includes the conductor 240 functioning as a plug electrically connected to the transistor M1. The conductor 240 includes a region in contact with the conductor 242a.

The memory device of one embodiment of the present invention includes the insulator 212, the insulator 210, and a conductor 209 between the substrate (not illustrated) and the insulator 214. In particular, the conductor 209 is provided to be embedded in the insulator 210. The conductor 209 includes a region in contact with the conductor 240. In FIG. 21B, the insulator 212 is positioned over the insulator 210 and the conductor 209.

In the memory device of one embodiment of the present invention, the conductor 160 is embedded in the insulator 283 positioned over the insulator 282. The insulator 285 is positioned over the insulator 283 and the conductor 160.

The memory device described in this embodiment has a line-symmetric structure with respect to dashed-dotted line A7-A8 illustrated in FIG. 21A. The conductor 240 functioning as the wiring BL is positioned between the one of the source electrode and the drain electrode of one of the two transistors M1 and the one of the source electrode and the drain electrode of the other of the two transistors M1. With the above connection structure between the two transistors and the plug, a memory device that can be miniaturized or highly integrated can be provided.

### <<Transistor M1>>

As illustrated in FIGS. 21A to 21D, the transistor M1 includes an insulator 216 over the insulator 214, the conductor 205 (the conductor 205a and the conductor 205b) provided to be embedded in the insulator 216, the insulator 222 over the insulator 216 and the conductor 205, the insulator 224 over the insulator 222, the oxide 230a over the insulator 224, the oxide 230b over the oxide 230a, the conductor 242a (the conductor 242a1 and the conductor 242a2) and the conductor 242b (the conductor 242b1 and the conductor 242b2) over the oxide 230b, the insulator 253 over the oxide 230b, the insulator 254 over the insulator 253, the conductor 260 (the conductor 260a and the conductor 260b) positioned over the insulator 254 and overlapping with part of the oxide 230b, and the insulator 275 over the insulator 222, the insulator 224, the oxide 230a, the oxide 230b, the conductor 242a, and the conductor 242b.

In this specification and the like, the conductor 242a and the conductor 242b are collectively referred to as a conductor 242 in some cases.

The first opening reaching the oxide 230b is provided in the insulator 280 and the insulator 275. That is, the first opening includes a region overlapping with the oxide 230b. The insulator 275 includes an opening overlapping with the opening included in the insulator 280. The insulator 253, the insulator 254, and the conductor 260 are provided inside the first opening. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor M1. The insulator 254 includes a region in contact with the side surface of the conductor 260 and a region in contact with the bottom surface of the conductor 260. Note that as illustrated in FIG. 21C, the insulator 253 is provided on the top surface of the insulator 222 in a region of the first opening that does not overlap with the oxide 230.

The conductor 260 functions as the first gate electrode and the conductor 205 functions as the second gate electrode. The insulator 253 and the insulator 254 function as the first gate insulator, and the insulator 222 and the insulator 224 function as the second gate insulator. The conductor 242a functions as the one of the source electrode and the drain electrode, and the conductor 242b functions as the other of the source electrode and the drain electrode. A region of the oxide 230 that overlaps with the conductor 260 at least partly functions as a channel formation region.

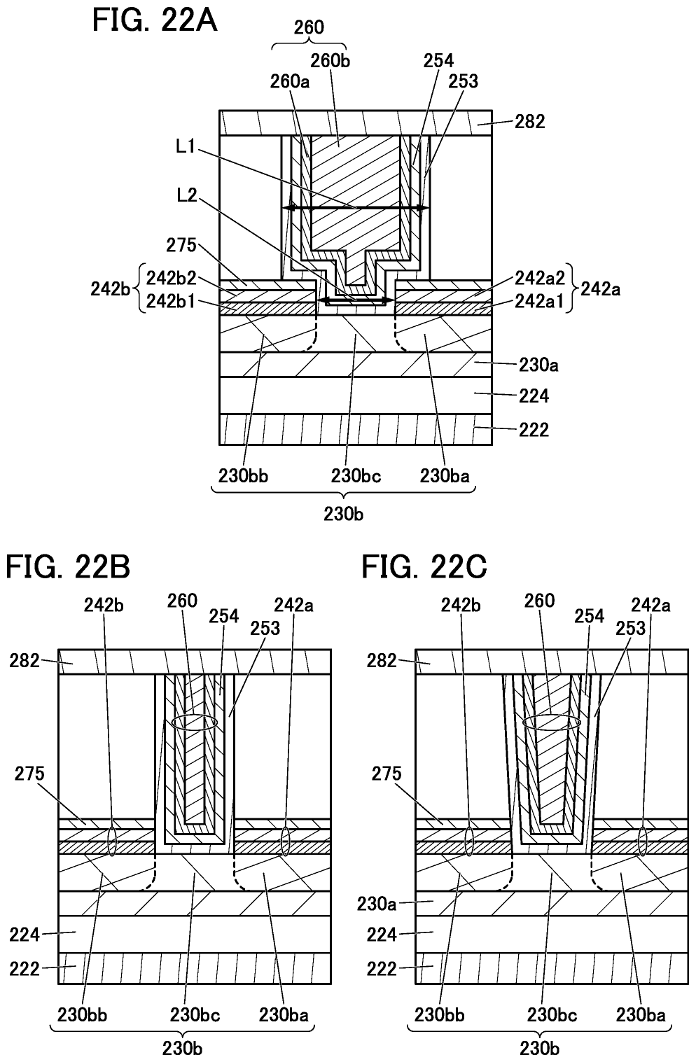

FIG. 22A is an enlarged view of the vicinity of the channel formation region in FIG. 21B. As illustrated in FIG. 22A, in the cross-sectional view of the transistor M1 in the channel length direction, distance L2 between the conductor 242a and the conductor 242b is preferably smaller than the width of the first opening in the insulator 280. Here, the width of the first opening corresponds to distance L1 between an interface between the insulator 280 and the insulator 253 on the conductor 242a side and an interface between the insulator 280 and the insulator 253 on the conductor 242b side, which is illustrated in FIG. 22A. Note that in this embodiment, channel etching for forming the conductor 242a and the conductor 242b is performed after the formation of the first opening. With such a structure, extremely small distance L2 between the conductor 242a and the conductor 242b (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm) can be relatively easily achieved. Since the conductor 260 includes a region having the distance L1 larger than the distance L2, a reduction in the conductivity of the conductor 260 positioned in the region having the distance L1 can be inhibited and the conductor 260 can function as a wiring.

As illustrated in FIG. 22A, the first opening can be also regarded as having a shape in which part of a structure body including the insulator 224, the oxide 230, the conductor 242, and the insulator 275 protrudes in an opening having the insulator 222 as its bottom surface and the insulator 280 as its side surface. The structure body including the insulator 224, the oxide 230, the conductor 242, and the insulator 275 has a shape in which the top surface of the oxide 230 sandwiched between the conductor 242a and the conductor 242b is in contact with the insulator 253 to be formed in a later step.

The channel formation region is formed in a region of the oxide 230b that is in contact with the insulator 253 or in the vicinity thereof. Thus, the channel formation region of the transistor M1 is extremely minute. Accordingly, the transistor M1 can have a higher on-state current and higher frequency characteristics.

Note that the shape of the first opening is not limited to the shape illustrated in FIG. 22A. As illustrated in FIG. 22B, in the first opening, the distance L1 and the distance L2 may be equal. At this time, as illustrated in FIG. 22B, the side surface of the conductor 242a and the side surface of the insulator 275 are substantially aligned with the side surface of the insulator 280. The side surface of the conductor 242b and the side surface of the insulator 275 are substantially aligned with the side surface of the insulator 280. With this structure, the manufacturing process of the semiconductor device can be simplified and the productivity can be improved. Moreover, a plurality of transistors M1 can be provided at higher density in a smaller area.

Although FIG. 22B illustrates a structure in which the sidewall of the first opening is substantially perpendicular to the top surface of the insulator 222, the present invention is not limited thereto. As illustrated in FIG. 22C, the sidewall of the first opening may have a tapered shape. With such a tapered sidewall of the first opening, the coverage with the insulator 253 and the like can be improved in a later step, so that the number of defects such as voids can be reduced.

In this specification and the like, a tapered shape indicates a shape in which at least part of a side surface of a structure body is inclined to a substrate surface. For example, a tapered shape preferably includes a region where the angle between the inclined side surface of the structure body and the substrate surface (the bottom surface) (hereinafter, such an angle is referred to as a taper angle in some cases) is less than 90°. Note that the side surface of the structure body and the substrate surface (the bottom surface) are not necessarily completely flat and may be substantially flat with a slight curvature or with slight unevenness.

The oxide 230 preferably includes the oxide 230a provided over the insulator 224 and the oxide 230b provided over the oxide 230a. The oxide 230a under the oxide 230b inhibits diffusion of impurities into the oxide 230b from the components formed below the oxide 230a.

Although the oxide 230 of the transistor M1 has a structure in which two layers, the oxide 230a and the oxide 230b, are stacked, the present invention is not limited to this structure. For example, the oxide 230 may have a single-layer structure of the oxide 230b or a stacked-layer structure of three or more layers, or the oxide 230a and the oxide 230b may each have a stacked-layer structure.

Then, the oxide 230 will be explained. As illustrated in FIG. 22A, the oxide 230b includes a region 230bc functioning as the channel formation region of the transistor M1 and a region 230ba and a region 230bb that are provided to sandwich the region 230bc and function as a source region and a drain region. At least part of the region 230bc overlaps with the conductor 260. In other words, the region 230bc is provided between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than the region 230ba and the region 230bb, i.e., is a high-resistance region with a low carrier concentration. Thus, the region 230bc can be regarded as being i-type (intrinsic) or substantially i-type.

The region 230ba and the region 230bb functioning as the source and the drain regions have a large amount of oxygen vacancies or a high concentration of impurities such as hydrogen, nitrogen, and a metal element, i.e., are low-resistance regions with a high carrier concentration. In other words, the region 230ba and the region 230bb are each an n-type region having a higher carrier concentration and a lower resistance than the region 230bc.

Here, as illustrated in FIG. 22A, the side surfaces of the conductor 242a and the conductor 242b that face each other are preferably substantially perpendicular to the top surface of the oxide 230b. With such a structure, the side end portion of the region 230ba on the region 230bc side that is formed under the conductor 242a can be inhibited from excessively receding from the side end portion of the conductor 242a on the region 230bc side. Similarly, the side end portion of the region 230bb on the region 230bc side that is formed under the conductor 242b can be inhibited from excessively receding from the side end portion of the conductor 242b on the region 230bc side. This can inhibit formation of what is called a Loff region between the region 230ba and the region 230bc and between the region 230bb and the region 230bc. Here, when the side end portion of the region 230ba on the region 230bc side recedes from the side end portion of the conductor 242a on the region 230bc side, the side end portion of the region 230ba is positioned closer to the conductor 240 than the side surface of the conductor 242a on the region 230bc side is. In addition, when the side end portion of the region 230bb on the region 230bc side recedes from the side end portion of the conductor 242b on the region 230bc side, the side end portion of the region 230bb is positioned closer to the conductor 160 than the side surface of the conductor 242b on the region 230bc side is.

Accordingly, the frequency characteristics of the transistor M1 can be improved, and the operation speed of the semiconductor device of one embodiment of the present invention can be improved. For example, in the case where the semiconductor device of one embodiment of the present invention is used as a memory cell of a memory device, the writing speed and the reading speed can be improved.

The carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. Note that the lower limit of the carrier concentration in the region 230bc functioning as the channel formation region is not particularly limited and can be, for example, 1×10⁻⁹ cm⁻³.

A region having a carrier concentration lower than or equal to those of the region 230ba and the region 230bb and higher than or equal to that of the region 230bc may be formed between the region 230bc and the region 230ba or between the region 230bc and the region 230bb. That is, the region functions as a junction region between the region 230bc and the region 230ba or between the region 230bc and the region 230bb. The hydrogen concentration in the junction region is sometimes lower than or equal to those in the region 230ba and the region 230bb and higher than or equal to that in the region 230bc. The amount of oxygen vacancies in the junction region is sometimes smaller than or equal to those in the region 230ba and the region 230bb and larger than or equal to that in the region 230bc.

Note that FIG. 22A illustrates an example where the region 230ba, the region 230bb, and the region 230bc are formed in the metal oxide 230b; however, the present invention is not limited to this. For example, the above regions may be formed not only in the oxide 230b but also in the oxide 230a.

In the oxide 230, it is sometimes difficult to clearly observe the boundaries between the regions. The concentrations of a metal element and impurity elements such as hydrogen and nitrogen, which are detected in each region, may be not only gradually changed between the regions, but also continuously changed in each region. That is, the region closer to the channel formation region preferably has lower concentrations of a metal element and impurity elements such as hydrogen and nitrogen.

In the transistor M1, the oxide 230 (the oxide 230a and the oxide 230b), which includes the channel formation region, is preferably formed using metal oxide functioning as a semiconductor (hereinafter also referred to as an oxide semiconductor).

The band gap of the metal oxide functioning as a semiconductor is preferably greater than or equal to 2 eV, further preferably greater than or equal to 2.5 eV. The use of such metal oxide having a wide band gap can reduce the off-state current of the transistor.

The metal oxide preferably contains at least indium or zinc, for example. In particular, the metal oxide preferably contains indium and zinc. In addition to them, the element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. Furthermore, the element M preferably contains one or both of gallium and tin. In particular, a metal oxide containing indium, the element M, and zinc is referred to as an In-M-Zn oxide in some cases.

The oxide 230 preferably has a stacked-layer structure of oxide layers with different chemical compositions. For example, the atomic ratio of the element M to a metal element that is the main component in the metal oxide used as the oxide 230a is preferably higher than that in the metal oxide used as the oxide 230b. The atomic ratio of the element M to In in the metal oxide used as the oxide 230a is preferably higher than that in the metal oxide used as the oxide 230b. This structure can inhibit impurities and oxygen from diffusing into the oxide 230b from the components formed below the oxide 230a.

The atomic ratio of In to the element M in the metal oxide used as the oxide 230b is preferably higher than that in the metal oxide used as the oxide 230a. With this structure, the transistor M1 can have a high on-state current and high frequency characteristics.

When the oxide 230a and the oxide 230b contain a common element as the main component besides oxygen, the density of defect states at the interface between the oxide 230a and the oxide 230b can be low. This reduces the influence of interface scattering on carrier conduction, and the transistor M1 can have a high on-state current and excellent frequency characteristics.

Specifically, as the oxide 230a, a metal oxide having an atomic ratio of In:M:Zn=1:3:4 or in the neighborhood thereof, or In:M:Zn=1:1:0.5 or in the neighborhood thereof is used. As the oxide 230b, it is preferable to use a metal oxide having an atomic ratio of In:M:Zn=1:1:1 or in the neighborhood thereof, In:M:Zn=1:1:1.2 or in the neighborhood thereof, In:M:Zn=1:1:2 or in the neighborhood thereof, or In:M:Zn=4:2:3 or in the neighborhood thereof. Note that the neighborhood of the atomic ratio includes +30% of an intended atomic ratio. Gallium is preferably used as the element M. In the case where a single layer of the oxide 230b is provided as the oxide 230, metal oxide that can be used as the oxide 230a may be used as the oxide 230b.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably exhibits crystallinity. In particular, as the oxide 230b, a c-axis-aligned crystalline oxide semiconductor (CAAC-OS) is preferably used.

The CAAC-OS is a metal oxide having a dense structure with high crystallinity and a low amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

In the CAAC-OS, a reduction in electron mobility due to a crystal grain boundary is less likely to occur because it is difficult to observe a clear crystal grain boundary. Thus, a metal oxide including the CAAC-OS is physically stable. Accordingly, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. In this case, extraction of oxygen from the oxide 230b can be inhibited even when heat treatment is performed; hence, the transistor M1 is stable against high temperatures in the manufacturing process (i.e., thermal budget).

If impurities and oxygen vacancies exist in a channel formation region of an oxide semiconductor, a transistor including the oxide semiconductor might have variable electrical characteristics and poor reliability. In some cases, hydrogen in the vicinity of an oxygen vacancy forms a defect that is an oxygen vacancy into which hydrogen enters (hereinafter sometimes referred to as V_{O}H), which generates an electron serving as a carrier. Accordingly, when the channel formation region in the oxide semiconductor includes oxygen vacancies, the transistor tends to become normally-on (in the state where a channel is generated even when no voltage is applied to a gate electrode, and a current flows through the transistor). Therefore, the impurities, oxygen vacancies, and V_{O}H are preferably reduced as much as possible in the channel formation region of the oxide semiconductor. In other words, the oxide semiconductor preferably includes an i-type (intrinsic) or substantially i-type channel formation region with a low carrier concentration.

By contrast, when an insulator containing oxygen that is released by heating (hereinafter sometimes referred to as excess oxygen) is provided in the vicinity of the oxide semiconductor and heat treatment is performed, oxygen can be supplied from the insulator to the oxide semiconductor so as to reduce oxygen vacancies and V_{O}H. Note that too much oxygen supplied to the source region or the drain region might decrease the on-state current or the field-effect mobility of the transistor M1. Furthermore, a variation in the amount of oxygen supplied to the source region or the drain region in the substrate plane leads to variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that electrical characteristics and reliability of the transistor might be adversely affected.

Hence, the region 230bc functioning as the channel formation region in the oxide semiconductor is preferably an i-type or substantially i-type region with a low carrier concentration, whereas the region 230ba and the region 230bb functioning as the source and drain regions are preferably n-type regions with a high carrier concentration. That is, the amounts of oxygen vacancies and V_{O}H in the region 230bc of the oxide semiconductor are preferably reduced. Furthermore, it is preferable that the region 230ba and the region 230bb not be supplied with an excessive amount of oxygen and the amount of V_{O}H in the region 230ba and the region 230bb not be excessively reduced. Furthermore, a reduction in the conductivity of the conductor 260, the conductor 242a, and the conductor 242b is preferably inhibited. For example, oxidation of the conductor 260, the conductor 242a, and the conductor 242b is preferably inhibited. Note that hydrogen in an oxide semiconductor can form V_{O}H; thus, the hydrogen concentration needs to be reduced in order to reduce the amount of V_{O}H.

The memory device of this embodiment has a structure in which the hydrogen concentration in the region 230bc is reduced, oxidation of the conductor 242a, the conductor 242b, and the conductor 260 is inhibited, and the hydrogen concentration in the region 230ba and the region 230bb is inhibited from being reduced.

In order to reduce the hydrogen concentration in the region 230bc, the insulator 253 preferably has a function of capturing and fixing hydrogen. As illustrated in FIG. 21C, the insulator 253 includes a region in contact with the region 230bc of the oxide 230b. With this structure, the hydrogen concentration in the region 230bc of the oxide 230b can be reduced. Accordingly, V_{O}H in the region 230bc can be reduced, so that the region 230bc can be an i-type or substantially i-type region.

Examples of an insulator having a function of capturing and fixing hydrogen include a metal oxide having an amorphous structure. For example, metal oxide, such as magnesium oxide or oxide containing aluminum and/or hafnium, is preferably used. In such a metal oxide having an amorphous structure, an oxygen atom has a dangling bond, and the metal oxide has a property of capturing or fixing hydrogen with the dangling bond in some cases. That is, the metal oxide having an amorphous structure is highly capable of capturing or fixing hydrogen.

The insulator 253 and the insulator 282 that is included in the capacitor C1 are preferably formed using the same insulating film. That is, the insulator 253 and the insulator 282 preferably contain the same material. The insulator 282 functions as the dielectric of the capacitor C1. Therefore, a high dielectric constant (high-k) material is preferably used for the insulator 282. At this time, the insulator 253 contains the high-k material. An example of the high-k material is oxide containing aluminum and/or hafnium. With use of the high-k material for the insulator 253, a gate potential applied during operation of the transistor can be reduced while the physical thickness of the gate insulator is maintained. In addition, the equivalent oxide thickness (EOT) of the insulator functioning as the gate insulator can be reduced.

As described above, for the insulator 253, oxide containing aluminum and/or hafnium is preferably used, more preferably, oxide containing aluminum and/or hafnium and having an amorphous structure is used, and further preferably, hafnium oxide having an amorphous structure is used. In this embodiment, hafnium oxide is used for the insulator 253. In this case, the insulator 253 is an insulator containing at least oxygen and hafnium. The hafnium oxide has an amorphous structure. In that case, the insulator 253 has an amorphous structure.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the memory device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a particular substance (also referred to as a function of less easily transmitting the substance). Alternatively, a barrier property in this specification and the like means a function of capturing and fixing (also referred to as gettering) a particular substance.

Examples of a barrier insulator against oxygen include oxide containing aluminum and/or hafnium, magnesium oxide, gallium oxide, indium gallium zinc oxide, silicon nitride, and silicon nitride oxide. Examples of the oxide containing aluminum and/or hafnium include aluminum oxide, hafnium oxide, oxide containing aluminum and hafnium (hafnium aluminate), and oxide containing hafnium and silicon (hafnium silicate). For example, each of the insulator 253, the insulator 254, and the insulator 275 may have a single-layer structure or a stacked-layer structure of the barrier insulator against oxygen.

The insulator 253 preferably has a barrier property against oxygen. Note that the insulator 253 is less permeable to oxygen than at least the insulator 280 is. The insulator 253 includes a region in contact with the side surface of the conductor 242a and the side surface of the conductor 242b. When the insulator 253 has a barrier property against oxygen, oxidation of the side surfaces of the conductors 242a and 242b, which forms oxide films on the side surfaces, can be inhibited. It is thus possible to inhibit a reduction in the on-state current or field-effect mobility of the transistor M1.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the region 230bc of the oxide 230b caused by heat treatment or the like can be inhibited. Thus, oxygen vacancies formed in the oxide 230a and the oxide 230b can be reduced.

Even when an excessive amount of oxygen is contained in the insulator 280, the oxygen can be inhibited from being excessively supplied to the oxide 230a and the oxide 230b. Thus, the region 230ba and the region 230bb are inhibited from being excessively oxidized, so that a reduction in the on-state current or field-effect mobility of the transistor M1 can be inhibited.

Oxide containing aluminum and/or hafnium has a barrier property against oxygen and thus can be suitably used for the insulator 253.

The insulator 254 preferably has a barrier property against oxygen. The insulator 254 is provided between the conductor 260 and the region 230bc of the oxide 230 and between the insulator 280 and the conductor 260. Such a structure can inhibit oxygen contained in the region 230bc of the oxide 230 from diffusing into the conductor 260 and thus can inhibit formation of oxygen vacancies in the region 230bc of the oxide 230. Oxygen contained in the oxide 230 and oxygen contained in the insulator 280 can be inhibit from diffusing into the conductor 260 and oxidizing the conductor 260. Note that the insulator 254 is less permeable to oxygen than at least the insulator 280 is. For example, silicon nitride is preferably used for the insulator 254. In this case, the insulator 254 is an insulator containing at least nitrogen and silicon.

The insulator 275 preferably has a barrier property against oxygen. The insulator 275 is provided between the insulator 280 and the conductor 242a and between the insulator 280 and the conductor 242b. This structure can inhibit diffusion of oxygen contained in the insulator 280 into the conductor 242a and the conductor 242b. Accordingly, oxidation of the conductor 242a and the conductor 242b by oxygen contained in the insulator 280 can be inhibited, so that an increase in resistivity and a reduction in on-state current due to the oxidation can be inhibited. The insulator 275 is less permeable to oxygen than at least the insulator 280 is. For example, silicon nitride is preferably used for the insulator 275. In that case, the insulator 275 is an insulator containing at least nitrogen and silicon.

In order to inhibit a reduction in the hydrogen concentration in the region 230ba and the region 230bb, a barrier insulator against hydrogen is preferably provided in the vicinity of each of the region 230ba and the region 230bb. In the memory device described in this embodiment, the barrier insulator against hydrogen is, for example, the insulator 275.

Examples of the barrier insulator against hydrogen include oxide such as aluminum oxide, hafnium oxide, and tantalum oxide and nitride such as silicon nitride. For example, the insulator 275 has a single-layer structure or a stacked-layer structure of the barrier insulator against hydrogen.

The insulator 275 preferably has a barrier property against hydrogen. The insulator 275 is placed in contact with the side surface of the region 230ba in the oxide 230b and the side surface of the region 230bb in the oxide 230b. The insulator 275 is placed between the insulator 253 and the side surface of the region 230ba in the oxide 230b and between the insulator 253 and the side surface of the region 230bb in the oxide 230b. When the insulator 275 has a barrier property against hydrogen, capturing and fixing of hydrogen in the region 230ba and the region 230bb by the insulator 253 can be inhibited. Thus, the region 230ba and the region 230bb can be n-type regions.

With the above structure, the region 230bc functioning as the channel formation region can be an i-type or substantially i-type region, the region 230ba and the region 230bb functioning as the source region and the drain region can be n-type regions, and thus a memory device with favorable electrical characteristics can be provided. The memory device with the above structure can have favorable electrical characteristics even when being miniaturized or highly integrated. For example, even when the distance L2 illustrated in FIG. 22A is less than or equal to 20 nm, less than or equal to 15 nm, less than or equal to 10 nm, or less than or equal to 7 nm, and greater than or equal to 2 nm, greater than or equal to 3 nm, or greater than or equal to 5 nm, favorable electrical characteristics can be obtained.

Furthermore, miniaturization of the transistor M1 can improve the high-frequency characteristics. Specifically, the cutoff frequency can be improved. When the gate length is within the above range, the cutoff frequency of the transistor can be greater than or equal to 50 GHz or greater than or equal to 100 GHz at room temperature, for example.

The insulator 253 functions as part of a gate insulator. As illustrated in FIG. 21B, the insulator 253 is provided in contact with the side surface and part of the top surface of the insulator 275 and the side surface of the insulator 280.

Furthermore, the insulator 253 needs to be provided in the first opening formed in the insulator 280 and the like, together with the insulator 254 and the conductor 260. The thickness of the insulator 253 is preferably thin for miniaturization of the transistor M1. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than 5.0 nm, still further preferably greater than or equal to 1.0 nm and less than or equal to 3.0 nm. In that case, at least part of the insulator 253 has the thickness described above.

To form the insulator 253 having a small thickness as the above, an atomic layer deposition (ALD) method is preferably used for deposition. As the ALD method, a thermal ALD method, in which a precursor and a reactant react with each other only by a thermal energy, a PEALD method, in which a reactant excited by plasma is used, or the like can be used. The use of plasma is sometimes preferable because deposition at a lower temperature is possible in a PEALD method.

An ALD method enables a single atomic layer to be formed at a time, and has various advantages such as deposition of an extremely thin film, deposition on a component with a high aspect ratio, deposition of a film with a small number of defects such as pinholes, deposition with excellent coverage, and low-temperature deposition. Thus, the insulator 253 can be formed on the side surface of the opening formed in the insulator 280 and the like and the side end portion of the conductor 242 and the like to have a small thickness as described above and to have excellent coverage.

Note that a precursor used in the ALD method sometimes contains impurities such as carbon. Thus, a film formed by the ALD method may contain impurities such as carbon in a larger amount than a film formed by another deposition method. Note that impurities can be quantified by secondary ion mass spectrometry (SIMS), X-ray photoelectron spectroscopy (XPS), or Auger electron spectroscopy (AES).

The insulator 254 functions as part of a gate insulator. The insulator 254 preferably has a barrier property against hydrogen. This can prevent diffusion of impurities contained in the conductor 260, such as hydrogen, into the oxide 230b.

Furthermore, the insulator 254 needs to be provided together with the insulator 253 and the conductor 260 in the opening formed in the insulator 280 and the like. The thickness of the insulator 254 is preferably thin for miniaturization of the transistor M1. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In that case, at least part of the insulator 254 preferably includes a region having the above-described thickness.

For example, silicon nitride deposited by a PEALD method may be used as the insulator 254.

When an insulator having a function of inhibiting the passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the memory device.

The insulator 275 is provided to cover the insulator 224, the oxide 230a, the oxide 230b, and the conductor 242. Specifically, the insulator 275 includes a region in contact with the side surface of the oxide 230b, the side surface of the conductor 242a, and the side surface of the conductor 242b.

In the first opening, the insulator 275 overlaps with the conductor 242. With this structure, the physical distance between the conductor 242 and the conductor 260 is increased, so that the parasitic capacitance between the conductor 242 and the conductor 260 can be reduced. Therefore, a memory device with excellent electrical characteristics can be provided.

A conductive material that is less likely to be oxidized, a conductive material having a function of inhibiting diffusion of oxygen, or the like is preferably used for the conductor 242a, the conductor 242b, and the conductor 260. Examples of the conductive material include a conductive material containing nitrogen, a conductive material containing oxygen, and the like. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

One or both of the conductor 242 and the conductor 260 may have a stacked-layer structure. For example, as illustrated in FIG. 21B, the conductor 242a and the conductor 242b may each have a stacked-layer structure of two layers. In this case, for a layer (the conductor 242al and the conductor 242b1) in contact with the oxide 230b, a conductive material that is less likely to be oxidized, a conductive material having a function of inhibiting diffusion of oxygen, or the like is preferably used. For example, in the case where the conductor 260 has a stacked-layer structure of the conductor 260a and the conductor 260b as illustrated in FIG. 21B, a conductive material that is less likely to be oxidized, a conductive material having a function of inhibiting diffusion of oxygen, or the like is preferably used for the conductor 260a.

To inhibit a decrease in the conductivity of the conductor 242, oxide having crystallinity, such as a CAAC-OS, is preferably used as the oxide 230b. As the oxide, a metal oxide that can be used as the oxide 230 is preferably used. Specifically, metal oxide containing one or more selected from indium, zinc, gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting oxygen from the oxide 230b. In addition, a decrease in conductivity of the conductor 242a and the conductor 242b can be inhibited.

In this embodiment, microwave treatment is performed in an atmosphere containing oxygen in a state where the conductor 242a and the conductor 242b are provided over the oxide 230b so that oxygen vacancies and V_{O}H in the region 230bc are reduced. Here, the microwave treatment refers to, for example, treatment using an apparatus including a power source that generates high-density plasma with the use of a microwave.

The microwave treatment in an oxygen-containing atmosphere converts an oxygen gas into plasma using a high-frequency wave such as a microwave or RF and activates the oxygen plasma. At this time, the region 230bc can be irradiated with the high-frequency wave such as the microwave or RF. By the effect of the plasma, the microwave, or the like, V_{O}H in the region 230bc can be divided into oxygen vacancy and hydrogen; the hydrogen can be removed from the region 230bc and the oxygen vacancy can be filled with oxygen. As a result, the hydrogen concentration, oxygen vacancies, and V_{O}H in the region 230bc can be reduced to lower the carrier concentration.

In the microwave treatment in an oxygen-containing atmosphere, the effect of the high-frequency wave such as the microwave or RF, the oxygen plasma, and the like is blocked by the conductor 242a and the conductor 242b and does not reach the region 230ba and the region 230bb. In addition, the effect of the oxygen plasma can be reduced by the insulator 275 and the insulator 280 that are provided to cover the oxide 230b and the conductor 242. Hence, a reduction in V_{O}H and supply of too much oxygen due to the microwave treatment do not occur in the region 230ba and the region 230bb, preventing a decrease in carrier concentration therein.

After formation of an insulating film to be the insulator 253, microwave treatment is preferably performed in an oxygen-containing atmosphere. When such microwave treatment in an oxygen-containing atmosphere is performed with the insulator 253 being provided, oxygen can be efficiently injected into the region 230bc. In addition, the insulator 253 is placed to be in contact with the side surface of the conductor 242 and the surface of the region 230bc, whereby an excess amount of oxygen is inhibited from being supplied to the region 230bc, and the side surface of the conductor 242 can be inhibited from being oxidized.

Oxygen injected into the region 230bc can be in any of various forms such as an oxygen atom, an oxygen molecule, or an oxygen radical (also referred to as O radical which is an atom, a molecule, or an ion having an unpaired electron). The oxygen supplied to the region 230bc preferably has one or more of the above forms. An oxygen radical is particularly preferable. In addition, the insulator 253 can have improved film quality, which increases the reliability of the transistor M1.

In the above manner, oxygen vacancies and V_{O}H can be selectively removed from the region 230bc in the oxide semiconductor, whereby the region 230bc can be an i-type or substantially i-type region. Furthermore, supply of an excess amount of oxygen to the region 230ba and the region 230bb functioning as the source and drain regions can be inhibited and the n-type regions before the microwave treatment can be maintained. As a result, a change in the electrical characteristics of the transistor M1 can be inhibited, and thus variation in the electrical characteristics of the transistors M1 in the substrate plane can be inhibited.

The above structure allows the memory device to have a small variation in transistor characteristics. A memory device with excellent frequency characteristics can be provided. A memory device that operates at high speed can be provided. A memory device with high reliability can be provided. A memory device with excellent electrical characteristics can be provided. A memory device that can be miniaturized or highly integrated can be provided.

As illustrated in FIG. 21C, a curved surface may be provided between the side and top surfaces of the oxide 230b in a cross-sectional view in the channel width direction of the transistor M1. In other words, the end portion of the side surface and the end portion of the top surface may be curved (rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 253, the insulator 254, and the conductor 260.

In a manufacturing process of the transistor M1, the heat treatment is preferably performed with the surface of the oxide 230 exposed. The heat treatment is performed at a temperature higher than or equal to 100° C. and lower than or equal to 600° C., preferably higher than or equal to 350° C. and lower than or equal to 550° C., for example. The heat treatment is performed in a nitrogen gas atmosphere, an inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 230 to reduce oxygen vacancies. The heat treatment may be performed under a reduced pressure. Alternatively, the heat treatment may be performed in such a manner that heat treatment is performed in a nitrogen gas atmosphere or an inert gas atmosphere, and then another heat treatment is performed in an atmosphere containing an oxidation gas at 10 ppm or more, 1% or more, or 10% or more in order to compensate for released oxygen. Alternatively, the heat treatment may be performed in such a manner that heat treatment is performed in an atmosphere containing an oxidation gas at 10 ppm or more, 1% or more, or 10% or more, and then another heat treatment is successively performed in a nitrogen gas atmosphere or an inert gas atmosphere.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of V_{O}H.

As illustrated in FIG. 21C or the like, the insulator 253 is provided in contact with the top and side surfaces of the oxide 230, whereby indium contained in the oxide 230 is unevenly distributed, in some cases, at the interface between the oxide 230 and the insulator 253 and in its vicinity. Accordingly, the vicinity of the surface of the oxide 230 comes to have an atomic ratio close to that of an indium oxide or that of an In—Zn oxide. Such an increase in the atomic ratio of indium in the vicinity of the surface of the oxide 230, especially the vicinity of a surface of the oxide 230b, can increase the field-effect mobility of the transistor M1.

In addition to the above structure, the memory device of this embodiment preferably has a structure in which hydrogen is inhibited from entering the transistor M1 and the like. For example, an insulator having a function of inhibiting diffusion of hydrogen is preferably provided to cover the transistor M1. In the memory device described in this embodiment, the insulator is, for example, the insulator 212.

As the insulator 212, an insulator having a function of inhibiting hydrogen diffusion is preferably used. This can inhibit diffusion of hydrogen into the transistor M1 from below the insulator 212. Any of the above-described insulators that can be used for the insulator 275 is used as the insulator 212.

At least one selected from the insulator 212, the insulator 214, the insulator 282, and the insulator 285 preferably functions as a barrier insulating film that inhibits diffusion of impurities such as water and hydrogen from the substrate side or above the transistor M1 into the transistor M1. Thus, at least one selected from the insulator 212, the insulator 214, the insulator 282, and the insulator 285 are each preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are less likely to pass). Alternatively, it is preferable to use an insulating material having a function of inhibiting diffusion of oxygen (e.g., at least one of an oxygen atom, an oxygen molecule, and the like) (an insulating material through which the above oxygen is less likely to pass).

An insulator having a function of inhibiting diffusion of oxygen and impurities such as water and hydrogen is preferably used as the insulator 212, the insulator 214, the insulator 282, and the insulator 285, and examples of the insulator include aluminum oxide, magnesium oxide, hafnium oxide, gallium oxide, indium gallium zinc oxide, silicon nitride, and silicon nitride oxide. For example, silicon nitride, which has a higher hydrogen barrier property, is preferably used for the insulator 212. For example, aluminum oxide or magnesium oxide, which has an excellent function of capturing and fixing hydrogen, is preferably used for the insulator 214, the insulator 282, and the insulator 285. Accordingly, impurities such as water and hydrogen can be inhibited from diffusing to the transistor M1 side from the substrate side through the insulator 212 and the insulator 214. Furthermore, impurities such as water and hydrogen can be inhibited from diffusing to the transistor M1 side from an interlayer insulating film and the like placed outward from the insulator 285. In addition, oxygen contained in the insulator 224 and the like can be inhibited from diffusing to the substrate side through the insulator 212 and the insulator 214. Oxygen contained in the insulator 280 and the like can be inhibited from diffusing to above the transistor M1 through the insulator 282 and the like. In this manner, the transistor M1 is preferably surrounded by the insulator 212, the insulator 214, the insulator 282, and the insulator 285 having a function of inhibiting diffusion of oxygen and impurities such as water and hydrogen.

Here, oxide having an amorphous structure is preferably used as the insulator 212, the insulator 214, the insulator 282, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond, and the metal oxide has a property of capturing or fixing hydrogen with the dangling bond in some cases. When such a metal oxide having an amorphous structure is used as the component of the transistor M1 or provided in the vicinity of the transistor M1, hydrogen contained in the transistor M1 or hydrogen in the vicinity of the transistor M1 can be captured or fixed. In particular, hydrogen contained in the channel formation region of the transistor M1 is preferably captured or fixed. The metal oxide having an amorphous structure is used as the component of the transistor M1 or provided in the vicinity of the transistor M1, whereby the transistor M1 and the memory device with favorable characteristics and high reliability can be manufactured.

Each of the insulator 212, the insulator 214, the insulator 282, and the insulator 285 preferably has an amorphous structure, but may partly include a region with a polycrystalline structure. Alternatively, the insulator 212, the insulator 214, the insulator 282, and the insulator 285 may have a multilayer structure in which a layer having an amorphous structure and a layer having a polycrystalline structure are stacked. For example, a stacked-layer structure in which a layer with a polycrystalline structure is formed over a layer with an amorphous structure may be employed.

The insulator 212, the insulator 214, the insulator 282, and the insulator 285 can be formed by a sputtering method, for example. A deposition gas in a sputtering method need not include molecules containing hydrogen; thus, the hydrogen concentrations in the insulator 212, the insulator 214, the insulator 282, and the insulator 285 can be reduced. Note that the deposition method is not limited to a sputtering method, and a chemical vapor deposition (CVD) method, a molecular beam epitaxy (MBE) method, a pulsed laser deposition (PLD) method, an atomic layer deposition (ALD) method, or the like may be used as appropriate.

The resistivity of the insulator 212 is preferably low in some cases. For example, the insulator 212 with a resistivity approximately 1×10¹³ Ωcm can sometimes reduce charge up of the conductor 205, the conductor 242, the conductor 260, or the conductor 240 in the treatment using plasma or the like in the manufacturing process of a memory device. The resistivity of the insulator 212 is preferably higher than or equal to 1×10¹⁰ Ωcm and lower than or equal to 1×10¹⁵ Ωcm.

The dielectric constants of the insulator 216, the insulator 280, and the insulator 283 are preferably lower than that of the insulator 214. In the case where a material with a low dielectric constant is used for an interlayer film, the parasitic capacitance between wirings can be reduced. For example, for the insulator 216, the insulator 280, and the insulator 283, silicon oxide, silicon oxynitride, silicon oxide to which fluorine is added, silicon oxide to which carbon is added, silicon oxide to which carbon and nitrogen are added, porous silicon oxide, or the like is used as appropriate.

The conductor 205 is placed to overlap with the oxide 230 and the conductor 260. Here, the conductor 205 is preferably provided to fill an opening formed in the insulator 216. Part of the conductor 205 is embedded in the insulator 214 in some cases.

The conductor 205 includes the conductor 205a and the conductor 205b. The conductor 205a is provided in contact with the bottom surface and the side wall of the opening. The conductor 205b is provided to be embedded in a recessed portion formed in the conductor 205a. Here, the top surface of the conductor 205b is substantially level with the top surfaces of the conductor 205a and the insulator 216.

Here, the conductor 205a is preferably formed using a conductive material which has a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 205a is preferably formed using a conductive material having a function of inhibiting diffusion of oxygen (e.g., oxygen atoms, oxygen molecules, or both).

When the conductor 205a is formed using a conductive material having a function of inhibiting diffusion of hydrogen, impurities such as hydrogen contained in the conductor 205b can be prevented from diffusing into the oxide 230 through the insulator 216 and the insulator 224. When a conductive material having a function of inhibiting oxygen diffusion is used for the conductor 205a, a reduction in conductivity of the conductor 205b due to oxidation of the conductor 205b can be inhibited. As the conductive material having a function of inhibiting diffusion of oxygen, for example, titanium, titanium nitride, tantalum, tantalum nitride, ruthenium, or ruthenium oxide is preferably used. The conductor 205a can therefore be a single layer or a stack of the above conductive materials. For example, titanium nitride may be used for the conductor 205a.

A conductive material containing tungsten, copper, or aluminum as its main component is preferably used for the conductor 205b. For example, tungsten may be used for the conductor 205b.

The conductor 205 functions as the second gate electrode in some cases. In that case, by changing a potential applied to the conductor 205 independently of a potential applied to the conductor 260, the threshold voltage (Vₜₕ) of the transistor M1 can be controlled. In particular, by applying a negative potential to the conductor 205, Vₜₕ of the transistor M1 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. The insulator 216 with a reduced thickness contains a smaller absolute amount of impurities such as hydrogen, inhibiting the diffusion of the impurity into the oxide 230.

As illustrated in FIG. 21A, the size of the conductor 205 is preferably larger than the size of a region of the oxide 230 that does not overlap with the conductor 242a and the conductor 242b. As illustrated in FIG. 22C, it is particularly preferable that the conductor 205 extend beyond the end portions of the oxide 230a and the oxide 230b in the channel width direction. That is, the conductor 205 and the conductor 260 preferably overlap with each other with the insulator positioned therebetween, in a region beyond the side surface of the oxide 230 in the channel width direction. With this structure, the channel formation region in the oxide 230 can be electrically surrounded by the electric field of the conductor 260 functioning as the first gate electrode and the electric field of the conductor 205 functioning as the second gate electrode.

In this specification and the like, a transistor structure where a channel formation region is electrically surrounded by at least the electric field of the first gate electrode is referred to as a surrounded channel (S-channel) structure. The S-channel structure disclosed in this specification and the like is different from a Fin structure or a planar structure. The S-channel structure disclosed in this specification and the like can also be regarded as a kind of the Fin structure. In this specification and the like, the Fin structure refers to a structure where two or more surfaces (specifically, two surfaces, three surfaces, or four or more surfaces) of a channel are covered with a gate electrode. With the use of the Fin structure and the S-channel structure, a transistor with high resistance to a short-channel effect, i.e., a transistor in which a short-channel effect is unlikely to occur, can be obtained.

When the transistor M1 has the above-described S-channel structure, the channel formation region can be electrically surrounded. Since the S-channel structure is a structure with the electrically surrounded channel formation region, the S-channel structure is, in a sense, equivalent to a gate all around (GAA) structure or a lateral gate all around (LGAA) structure. When the transistor M1 has any of an S-channel structure, a GAA structure, and an LGAA structure, the channel formation region formed at the interface between the oxide 230 and the gate insulator or in the vicinity thereof can correspond to the whole of bulk in the oxide 230. Consequently, the density of current flowing through the transistor can be improved, so that the on-state current or the field-effect mobility of the transistor can be increased.

Note that although FIG. 21B illustrates a transistor with an S-channel structure as the transistor M1, the memory device of one embodiment of the present invention is not limited to this. For example, a transistor structure that can be employed in one embodiment of the present invention is one or more selected from a planar structure, a Fin-type structure, and a GAA structure.

As illustrated in FIG. 21C, the conductor 205 is extended to have a function of a wiring. However, without limitation to this structure, a structure where a conductor functioning as a wiring is provided below the conductor 205 may be employed. In addition, the conductor 205 is not necessarily provided in each transistor. For example, the conductor 205 may be shared by a plurality of transistors.

Although the conductor 205a and the conductor 205b are stacked as the conductor 205 in the transistor M1, the present invention is not limited thereto. For example, the conductor 205 may have a single-layer structure or a stacked-layer structure of three or more layers.

The insulator 222 and the insulator 224 function as a gate insulator.

The insulator 222 preferably has a function of inhibiting diffusion of hydrogen (e.g., one or both of hydrogen atoms and hydrogen molecules). The insulator 222 also preferably has a function of inhibiting diffusion of oxygen (e.g., one or both of oxygen atoms and oxygen molecules). For example, the insulator 222 preferably has a function of inhibiting diffusion of much hydrogen and/or oxygen compared to the insulator 224.

As the insulator 222, an insulator containing an oxide of aluminum and/or an oxide of hafnium, which are insulating materials, is preferably used. As the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. The insulator 222 formed of such a material functions as a layer that inhibits release of oxygen from the oxide 230 to the substrate side and diffusion of impurities such as hydrogen from the periphery of the transistor M1 into the oxide 230. Thus, providing the insulator 222 can inhibit diffusion of impurities such as hydrogen into the transistor M1 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. The insulator 222 may have a stacked-layer structure including silicon oxide, silicon oxynitride, or silicon nitride over any of these insulators.

The insulator 222 may be formed to have a single-layer structure or a stacked-layer structure using an insulator containing what is called a high-k material such as aluminum oxide, hafnium oxide, tantalum oxide, zirconium oxide, or hafnium zirconium oxide. With miniaturization or high integration of transistors, a problem such as generation of leakage current may arise because of a thinner gate insulator. When a high-k material is used for the insulator functioning as a gate insulator, a gate potential at the time of operation of the transistor can be reduced while the physical thickness is maintained. Alternatively, the insulator 222 can be formed using a substance with high dielectric constant, in some cases, such as lead zirconate titanate (PZT), strontium titanate (SrTiO₃), or (Ba,Sr)TiO₃ (BST).

The insulator 224 in contact with the oxide 230 is formed using, for example, silicon oxide or silicon oxynitride as appropriate.

Note that the insulator 222 and the insulator 224 may each have a stacked-layer structure of two or more layers. In that cases, without limitation to stacked layers containing the same material, stacked layers containing different materials may be used. The insulator 224 may be formed into an island shape overlapping with the oxide 230a. In this case, the insulator 275 is in contact with the side surface of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface of the oxide 230b. The conductor 242a and the conductor 242b function as the source electrode and the drain electrode of the transistor M1.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are a conductive material that is not easily oxidized or a material that maintains the conductivity even when absorbing oxygen.

Note that hydrogen contained in the oxide 230b or the like diffuses into the conductor 242a or the conductor 242b in some cases. In particular, when a nitride containing tantalum is used for the conductor 242a and the conductor 242b, hydrogen contained in the oxide 230b or the like is likely to diffuse into the conductor 242a or the conductor 242b, and the diffused hydrogen is bonded to nitrogen contained in the conductor 242a or the conductor 242b in some cases. That is, hydrogen contained in the oxide 230b or the like is sometimes absorbed by the conductor 242a or the conductor 242b.

No curved surface is preferably formed between the side surface and the top surface of the conductor 242. In that case, the conductor 242 can have a large cross-sectional area. When the conductor 242 has a large cross-sectional area, the conductivity of the conductor 242 is increased, and the on-state current of the transistor M1 can be increased.

As illustrated in FIG. 21A, the conductor 242a includes an opening in a region between two transistors M1. The conductor 240 is placed to overlap with the opening. With this structure, the conductor 242a and the conductor 240 include a region where they are in contact with each other. Thus, the conductor 242a and the conductor 240 are electrically connected to each other.

When heat treatment is performed in the state where the conductor 242a (the conductor 242b) and the oxide 230b are in contact with each other, the sheet resistance of the oxide 230b in a region overlapping with the conductor 242a (the conductor 242b) is decreased in some cases. The carrier concentration is sometimes increased. Thus, the resistance of the oxide 230b in the region overlapping with the conductor 242a (the conductor 242b) can be lowered in a self-aligned manner.

The conductor 242a and the conductor 242b are preferably formed using a conductive film having compressive stress. This can form distortion extended in the tensile direction (hereinafter, such distortion is sometimes referred to as tensile distortion) in the region 230ba and the region 230bb. When V_{O}H is stably formed by the tensile distortion, the region 230ba and the region 230bb can be stable n-type regions. The compressive stress of the conductor 242a refers to stress for relaxing the compressive shape of the conductor 242a that has a vector in a direction from a center portion to an end portion of the conductor 242a. The compressive stress of the conductor 242b is similar to that of the conductor 242a.

The level of the compressive stress of the conductor 242a is, for example, preferably higher than or equal to 500 MPa, further preferably higher than or equal to 1000 MPa, still further preferably higher than or equal to 1500 MPa, yet still further preferably higher than or equal to 2000 MPa. The level of the stress of the conductor 242a may be determined from the measured stress of a sample formed by depositing a conductive film to be used for the conductor 242a on a substrate. The same applies to the level of the compressive stress of the conductor 242b. An example of a conductor having the above level of compressive stress is a nitride containing tantalum.

Distortion is formed in each of the region 230ba and the region 230bb by the compressive stress of the conductor 242a and the conductor 242b. The distortion is distortion extended in the tensile direction (tensile distortion) because of the compressive stress of the conductor 242a and the conductor 242b. In the case where the region 230ba and the region 230bb have a CAAC structure, the distortion corresponds to the extension in the direction perpendicular to the c-axis of the CAAC structure. When the CAAC structure is extended in the direction perpendicular to the c-axis of the CAAC structure, oxygen vacancies are likely to be formed in the distortion.

Furthermore, hydrogen is likely to be taken in the distortion, so that V_{O}H is likely to be formed. Thus, oxygen vacancies and V_{O}H are easily formed in the distortion, and oxygen vacancies and V_{O}H are likely to have a stable structure. Thus, the region 230ba and the region 230bb can be stable n-type regions with high carrier concentrations.

Although the distortion formed in the oxide 230b is described above, the present invention is not limited thereto. In some cases, the distortion is formed similarly in the oxide 230a.

In the memory device illustrated in FIGS. 21A to 21D, the conductor 242 has a stacked-layer structure of two layers. Specifically, the conductor 242a includes the conductor 242al and the conductor 242a2 over the conductor 242al. Similarly, the conductor 242b includes the conductor 242b1 and the conductor 242b2 over the conductor 242b1. At this time, the conductor 242al and the conductor 242b1 are placed on the side in contact with the oxide 230b.

Hereinafter, the conductor 242al and the conductor 242b1 are collectively referred to as a lower layer of the conductor 242 in some cases. The conductor 242a2 and the conductor 242b2 are collectively referred to as an upper layer of the conductor 242 in some cases.

The lower layer of the conductor 242 (the conductor 242al and the conductor 242b1) is preferably formed using a conductive material less likely to be oxidized. Thus, oxidation of the lower layer of the conductor 242 and a resultant decrease in conductivity of the conductor 242 can be inhibited. Note that the lower layer of the conductor 242 may have such a property that hydrogen is easily absorbed (easily extracted). Accordingly, hydrogen in the oxide 230 can be diffused into the lower layer of the conductor 242, so that the hydrogen concentration in the oxide 230 can be reduced. Accordingly, the transistor M1 can have stable electric characteristics. The lower layer of the conductor 242 preferably has high compressive stress as described above, and preferably has higher compressive stress than the upper layer of the conductor 242. Thus, as described above, the region 230ba and the region 230bb that are in contact with the lower layer of the conductor 242 can be stable n-type regions with a high carrier concentration.

The upper layer of the conductor 242 (the conductor 242a2 and the conductor 242b2) preferably has higher conductivity than the lower layer of the conductor 242 (the conductor 242al and the conductor 242b1). For example, the upper layer of the conductor 242 is thicker than the lower layer of the conductor 242. Note that at least part of the upper layer of the conductor 242 includes a region having higher conductivity than the lower layer of the conductor 242. Alternatively, the upper layer of the conductor 242 is preferably formed using a conductive material with lower resistivity than that of the lower layer of the conductor 242. As a result, a memory device with reduced wiring delay can be manufactured.

Note that the upper layer of the conductor 242 may have such a property that hydrogen is easily absorbed. Accordingly, hydrogen absorbed by the lower layer of the conductor 242 is also diffused into the upper layer of the conductor 242, so that the hydrogen concentration in the oxide 230 can be further reduced. Accordingly, the transistor M1 can have stable electric characteristics.

In the case where the conductor 242 has a stacked-layer structure of two layers, one or more selected from constituent elements, chemical composition, and deposition conditions may be different between the lower layer of the conductor 242 and the upper layer of the conductor 242.

For example, tantalum nitride or titanium nitride can be used for the lower layer of the conductor 242 (the conductor 242al and the conductor 242b1), and tungsten can be used for the upper layer of the conductor 242 (the conductor 242a2 and the conductor 242b2). In this case, the conductor 242al and the conductor 242b1 become a conductor containing tantalum or titanium and nitrogen. With this structure, oxidation of the lower layer of the conductor 242 and a resultant decrease in conductivity of the conductor 242 can be inhibited. With this structure, the conductor 242a2 can be surrounded by the insulator 275 having a barrier property against oxygen and the conductor 242al having a property of being less likely to be oxidized, and the conductor 242b2 can be surrounded by the insulator 275 having a barrier property against oxygen and the conductor 242b1 having a property of being less likely to be oxidized. Thus, a memory device in which oxidation of the conductor 242a2 and the conductor 242b2 and wiring delay are inhibited can be manufactured.

Alternatively, for example, a nitride containing tantalum (e.g., tantalum nitride) may be used for the lower layer of the conductor 242, and a nitride containing titanium (e.g., titanium nitride) may be used for the upper layer of the conductor 242. Titanium nitride can have higher conductivity than tantalum nitride; thus, the conductivity of the upper layer of the conductor 242 can be higher than that of the lower layer of the conductor 242. Thus, the contact resistance between the conductor 242 and the conductor 240 provided in contact with the top surface of the conductor 242 can be reduced, so that a memory device with reduced wiring delay can be manufactured.

Although the lower layer of the conductor 242 and the upper layer of the conductor 242 are formed using different conductive materials in the above-described example, the present invention is not limited thereto.

The lower layer of the conductor 242 and the upper layer of the conductor 242 may be formed using conductive materials with the same element and different chemical composition. In this case, the lower layer of the conductor 242 and the upper layer of the conductor 242 can be deposited successively without being exposed to an atmospheric environment. By the deposition without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

For example, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, for the lower layer of the conductor 242, a nitride containing tantalum with an atomic ratio of nitrogen to tantalum of greater than or equal to 1.0 and less than or equal to 2.0, preferably greater than or equal to 1.1 and less than or equal to 1.8, further preferably greater than or equal to 1.2 and less than or equal to 1.5 is used. For example, for the upper layer of the conductor 242, a nitride containing tantalum with an atomic ratio of nitrogen to tantalum of greater than or equal to 0.3 and less than or equal to 1.5, preferably greater than or equal to 0.5 and less than or equal to 1.3, further preferably greater than or equal to 0.6 and less than or equal to 1.0 is used.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. As a result, a memory device with reduced wiring delay can be manufactured.

Note that the boundary between the upper layer and the lower layer of the conductor 242 is difficult to clearly detect in some cases. In the case where a nitride containing tantalum is used for the conductor 242, the tantalum concentration and the nitrogen concentration detected in each layer may gradually change within each layer and may also change continuously (or in a gradation manner) in a region between the upper layer and the lower layer. That is, the atomic ratio of nitrogen to tantalum is preferably higher in the region of the conductor 242 that is closer to the oxide 230. Thus, the atomic ratio of nitrogen to tantalum in a region positioned below the conductor 242 is preferably higher than the atomic ratio of nitrogen to tantalum in a region positioned above the conductor 242.

Although the conductor 242 has a stacked-layer structure of two layers in the transistor M1, the present invention is not limited thereto. For example, the conductor 242 may have a single-layer structure or a stacked-layer structure of three or more layers. In the case where a component has a stacked-layer structure, layers may be distinguished by ordinal numbers corresponding to the formation order.

The top surface of the conductor 260 is placed to be substantially aligned with the uppermost portion of the insulator 254, the uppermost portion of the insulator 253, and the top surface of the insulator 280.

The conductor 260 functions as the first gate electrode of the transistor M1. The conductor 260 preferably includes the conductor 260a and the conductor 260b over the conductor 260a. For example, the conductor 260a is preferably placed to cover the bottom and side surfaces of the conductor 260b. Although the conductor 260 has a two-layer structure of the conductor 260a and the conductor 260b in FIGS. 21B and 21C, the conductor 260 may have a single-layer structure or a stacked-layer structure of three or more layers.

The conductor 260a is preferably formed using a conductive material which has a function of inhibiting diffusion of impurities such as a hydrogen atom, a hydrogen molecule, a water molecule, a nitrogen atom, a nitrogen molecule, a nitrogen oxide molecule, and a copper atom. Alternatively, the conductor 260a is preferably formed using a conductive material having a function of inhibiting diffusion of oxygen (e.g., oxygen atoms, oxygen molecules, or both).

When the conductor 260a has a function of inhibiting diffusion of oxygen, the conductivity of the conductor 260b can be inhibited from being lowered because of oxidation of the conductor 260b due to oxygen diffused from the insulator 280 side. As the conductive material having a function of inhibiting oxygen diffusion, for example, titanium, titanium nitride, tantalum, tantalum nitride, ruthenium, or ruthenium oxide is preferably used.

The conductor 260 is formed to fill the first opening extending in the channel width direction, i.e., the conductor 260 extends in the channel width direction. Thus, when the plurality of transistors M1 are provided, the conductor 260 can function as a wiring. In this case, the insulator 253 and the insulator 254 also extend together with the conductor 260.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure, for example, a stacked-layer structure of titanium or titanium nitride and the above conductive material.

In the transistor M1, the conductor 260 is formed in a self-aligned manner to fill the first opening formed in the insulator 280 and the like. In this manner, the conductor 260 can surely be provided in a region between the conductor 242a and the conductor 242b without alignment.

As illustrated in FIG. 21C, in the channel width direction of the transistor M1, the bottom surface of the conductor 260 not overlapping with the oxide 230b is preferably lower in level than the bottom surface of the oxide 230b, with the level of the bottom surface of the insulator 222 as a reference. When the conductor 260 functioning as the gate electrode covers the side and top surfaces of the channel formation region of the oxide 230b with the insulator 253 and the like therebetween, the electric field of the conductor 260 is likely to affect the entire channel formation region in the oxide 230b. Hence, the transistor M1 can have a higher on-state current and higher frequency characteristics. With the level of the bottom surface of the insulator 222 as a reference, the difference between the level of the bottom surface of the conductor 260 and the level of the bottom surface of the oxide 230b in a region where the conductor 260 does not overlap with the oxide 230a and the oxide 230b is greater than or equal to 0 nm and less than or equal to 100 nm, preferably greater than or equal to 3 nm and less than or equal to 50 nm, and further preferably greater than or equal to 5 nm and less than or equal to 20 nm.

The insulator 280 is provided over the insulator 275, and the opening is formed in the region where the insulator 253, the insulator 254, and the conductor 260 are provided. The top surface of the insulator 280 may be planarized.

The insulator 280 functioning as the interlayer film preferably has a low dielectric constant. When a material with a low dielectric constant is used for an interlayer film, the parasitic capacitance generated between wirings can be reduced. The insulator 280 is preferably formed using a material similar to that used for the insulator 216, for example. In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed.

The concentration of impurities such as water and hydrogen in the insulator 280 is preferably reduced. For example, an oxide containing silicon, such as silicon oxide or silicon oxynitride, can be used for the insulator 280 as appropriate.

The insulator 282 is placed to be in contact with at least parts of the top surfaces of the conductor 260, the insulator 253, the insulator 254, and the insulator 280.

The insulator 282 preferably functions as a barrier insulating film that inhibits impurities such as water or hydrogen from diffusing into the insulator 280 from the above and also has a function of capturing impurities such as hydrogen. The insulator 282 also preferably functions as a barrier insulating film that inhibits oxygen transmission. As the insulator 282, a metal oxide having an amorphous structure, e.g., an insulator such as aluminum oxide, is used. In this case, the insulator 282 is an insulator containing at least oxygen and aluminum. When the insulator 282 having a function of capturing impurities such as hydrogen is provided in contact with the insulator 280, impurities such as hydrogen contained in the insulator 280 and the like can be captured. It is particularly preferable to use aluminum oxide having an amorphous structure as the insulator 282 because hydrogen can be captured or fixed more effectively in some cases. Accordingly, the transistor M1 and the memory device with favorable characteristics and high reliability can be manufactured.

As the insulator 282, aluminum oxide is preferably deposited by a sputtering method, and further preferably, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. A radio frequency (RF) power may be applied to the substrate. The amount of oxygen implanted into layers below the insulator 282 can be controlled depending on the amount of the RF power applied to the substrate. For example, the amount of oxygen implanted into the layers below the insulator 282 is smaller as the RF power is lower, and the amount of oxygen is easily saturated even when the insulator 282 has a small thickness. Moreover, the amount of oxygen implanted into the layers below the insulator 282 is larger as the RF power is higher.

The RF power is higher than or equal to 0 W/cm² and lower than or equal to 1.86 W/cm², for example. In other words, the supply amount of oxygen can be changed to be appropriate for the characteristics of the transistor, with the RF power used at the time of forming the insulator 282. Accordingly, an appropriate amount of oxygen for improving the reliability of the transistor can be implanted.

The RF frequency is preferably 10 MHz or higher. The typical frequency is 13.56 MHZ. The higher the RF frequency is, the less damage to the substrate can be.

Although FIG. 21A to 21D or the like illustrate a single-layer structure of the insulator 282, the present invention is not limited to this structure, and a stacked-layer structure of two or more layers may be employed. The insulator 282 may have a two-layer structure, for example.

An upper layer and a lower layer of the insulator 282 are preferably formed using the same material by different methods. For example, in the case where aluminum oxide is deposited as the insulator 282 by a pulsed DC sputtering method using an aluminum target in an atmosphere containing an oxygen gas, the RF power applied to the substrate in forming the lower layer of the insulator 282 is preferably different from the RF power applied to the substrate in forming the upper layer of the insulator 282, and further preferably, the RF power applied to the substrate in forming the lower layer of the insulator 282 is lower than the RF power applied to the substrate in forming the upper layer of the insulator 282. Specifically, the RF power applied to the substrate in the formation of the lower layer of the insulator 282 is greater than or equal to 0 W/cm² and less than or equal to 0.62 W/cm², and the RF power applied to the substrate in the formation of the upper layer of the insulator 282 is less than or equal to 1.86 W/cm². More specifically, the RF power applied to the substrate in the formation of the lower layer of the insulator 282 is 0 W/cm², and the RF power applied to the substrate in the formation of the upper layer of the insulator 282 is 0.31 W/cm². With this structure, the insulator 282 can have an amorphous structure and the amount of oxygen to be supplied to the insulator 280 can be adjusted.

Note that the RF power applied to the substrate in forming the lower layer of the insulator 282 may be higher than the RF power applied to the substrate in forming the upper layer of the insulator 282. Specifically, the RF power applied to the substrate in the formation of the lower layer of the insulator 282 is less than or equal to 1.86 W/cm², and the RF power applied to the substrate in the formation of the upper layer of the insulator 282 is greater than or equal to 0 W/cm² and less than or equal to 0.62 W/cm². More specifically, the RF power applied to the substrate in the formation of the lower layer of the insulator 282 is 1.86 W/cm², and the RF power applied to the substrate in the formation of the upper layer of the insulator 282 is 0.62 W/cm². With this structure, the amount of oxygen supplied to the insulator 280 can be increased.

The thickness of the lower layer of the insulator 282 is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With this structure, the lower layer of the insulator 282 can have an amorphous structure regardless of the value of RF power. When the lower layer of the insulator 282 has an amorphous structure, the upper layer of the insulator 282 is likely to have an amorphous structure and the insulator 282 can have an amorphous structure.

The lower layer of the insulator 282 and the upper layer of the insulator 282 are stacked layers containing the same material; however, the present invention is not limited thereto. The lower layer of the insulator 282 and the upper layer of the insulator 282 may be stacked layers containing different materials.

### <<Capacitor C1>>

As described above, the capacitor C1 includes the conductor 150 functioning as the one of the pair of electrodes of the capacitor C1, the conductor 160 (the conductor 160a and the conductor 160b) functioning as the other of the pair of electrodes of the capacitor C1, and the insulator 282 functioning as the dielectric of the capacitor C1. Note that the conductor 242b in contact with the conductor 150 also functions as the one of the pair of electrodes of the capacitor C1 in some cases.

The insulator 280 has the second opening. In FIGS. 21A, 21B, and 21D, the second opening is provided in the insulator 280 to reach a region of the conductor 242b that does not overlap with the insulator 224. That is, the second opening includes a region not overlapping with the insulator 224 but overlapping with the conductor 242b.

The conductor 150, the insulator 282, the conductor 160a, and the conductor 160b are placed inside the second opening provided in the insulator 280. In particular, the conductor 150 is provided on the top surface of the conductor 242b corresponding to the bottom portion of the second opening, the side surface of the insulator 280 corresponding to the sidewall of the second opening, and the top surface of the insulator 280; the insulator 282 is provided over the conductor 150 and the insulator 280; the conductor 160a is provided over the insulator 282; and the conductor 160b is provided over the conductor 160a.

As described above, the insulator 282 preferably contains a high-k material that can be used for the insulator 253 functioning as the gate insulating film of the transistor M1. When the insulator 282 contains a high-k material, the dielectric constant of the insulator 282 can be increased and the capacitance value of the capacitor C1 can be increased. Accordingly, data retention time of the memory cell 10_a and the memory cell 10_b can be made longer.

The conductor 150 preferably contains the same conductive material as the conductor 242a, the conductor 242b, or the conductor 260, for example; for the details, the description of the conductor 242a, the conductor 242b, or the conductor 260 can be referred to. The conductor 160a preferably contains the same conductive material as the conductor 260a; for the details, the description of the conductor 260a can be referred to. The conductor 160b preferably contains the same conductive material as the conductor 260b; for the details, the description of the conductor 260b can be referred to.

Although FIG. 21B illustrates a structure in which the sidewall of the second opening is substantially perpendicular to the top surface of the insulator 222, the present invention is not limited thereto. The sidewall of the second opening may have a tapered shape. With such a tapered sidewall of the second opening, the coverage with the conductor 150, the insulator 282, and the like can be improved in a later step, so that the number of defects such as voids can be reduced.

The conductor 160 is formed to fill the second opening. In particular, the conductor 160 positioned above the second opening is formed along the Y direction (the channel width direction of the transistor M1) as illustrated in FIG. 21A. Thus, the wiring (e.g., the wiring VE1_A to the wiring VE1_D in FIG. 2) electrically connected to the other of the pair of electrodes of the capacitor C1 can be provided.

As the length of the second opening in the insulator 280 (the trench length of the capacitor C1), FIG. 21B illustrates H₁ that is the vertical distance from the bottom surface of the conductor 150 (the fourth conductor in FIG. 6 described in Embodiment 1) to the top surface of the insulator 280 (any one of the insulating layer SK_A to the insulating layer SK_D in FIG. 6 described in Embodiment 1). Note that H₁ corresponds to H_{A} to H_{D} illustrated in FIG. 6.

In addition to H₁, H₂ is illustrated in the cross-sectional view in FIG. 21D. H₂ is also the length of the second opening in the insulator 280; H₁ is the length from the top surface of the conductor 242b to the top surface of the insulator 280, and H₂ is the length from the top surface of the insulator 222 to the top surface of the insulator 280. As described above, the length of the second opening is sometimes different from place to place in the second opening. In this case, the length of the second opening in the insulator 280 (the trench length of the capacitor C1) is the largest vertical height in the second opening from the bottom surface of the conductor 150 (the fourth conductor in FIG. 6 described in Embodiment 1) to the top surface of the insulator 280 (any one of the insulating layer SK_A to the insulating layer SK_D in FIG. 6 described in Embodiment 1). That is, in FIG. 21D, H₂ is the length of the second opening (the trench length of the capacitor C1).

### <<Wiring BL>>

Next, the conductor 240 functioning as the wiring BL and its peripheral component are described.

The conductor 240 is provided in contact with the inner wall of the opening in the insulator 285, the insulator 283, the insulator 282, the insulator 280, the insulator 275, the conductor 242a, the insulator 222, the insulator 216, the insulator 214, and the insulator 212. The conductor 240 includes a region in contact with the top surface of the conductor 209.

Here, the conductor 240 functions as a plug or a wiring for electrically connecting the transistor M1 to a circuit element such as a switch, a transistor, a capacitor, an inductor, a resistor element, or a diode, a wiring, an electrode, or a terminal.

The conductor 240 preferably has a stacked-layer structure of the conductor 240a and the conductor 240b. For example, as illustrated in FIG. 21B, the conductor 240 can have a structure in which the conductor 240a is provided in contact with the inner wall of the opening and the conductor 240b is provided inside the conductor 240a. That is, the conductor 240a is positioned in the vicinity of the insulator 285, the insulator 283, the insulator 282, the insulator 280, the insulator 275, the conductor 242a, the insulator 222, the insulator 216, the insulator 214, and the insulator 212.

For the conductor 240a, a conductive material having a function of inhibiting the passage of impurities such as water or hydrogen is preferably used. For example, tantalum, tantalum nitride, titanium, titanium nitride, ruthenium, or ruthenium oxide is preferably used. The conductive material having a function of inhibiting transmission of impurities such as water or hydrogen can be used as a single layer or stacked layers. Furthermore, impurities such as water or hydrogen contained in the components above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

The conductor 240 is provided to include a region in contact with the conductor 242a. In other words, when the conductor 240 is provided, electrical continuity can be established between the one of the source electrode and the drain electrode of one of the two transistors M1 and the one of the source electrode and the drain electrode of the other of the two transistors M1. In addition, a circuit for electrically connecting the memory cell 10_a and the memory cell 10_b can be provided above and/or below of the memory layer 60. Specifically, by stacking the plurality of memory layers 60, for example, the conductors 240 included in the memory layers 60 overlap with each other as illustrated in FIG. 20; thus, the stacked body functions as one wiring (the wiring BL[j] in FIG. 2 or FIG. 5).

Although FIG. 21B illustrates the conductor 240 (a stack of the conductor 240a and the conductor 240b) as a wiring extending in the Z direction (the wiring BL[j] in FIG. 2 or FIG. 5) in the memory layer 60, the memory device of one embodiment of the present invention is not limited thereto. For example, the conductor 240 may have a single-layer structure or a stacked-layer structure of three or more layers. In the case where a component has a stacked-layer structure, layers may be distinguished by ordinal numbers corresponding to the formation order. Although not illustrated in FIG. 21B, the top surface of the conductor 240 is higher than the top surface of the insulator 285 in some cases.

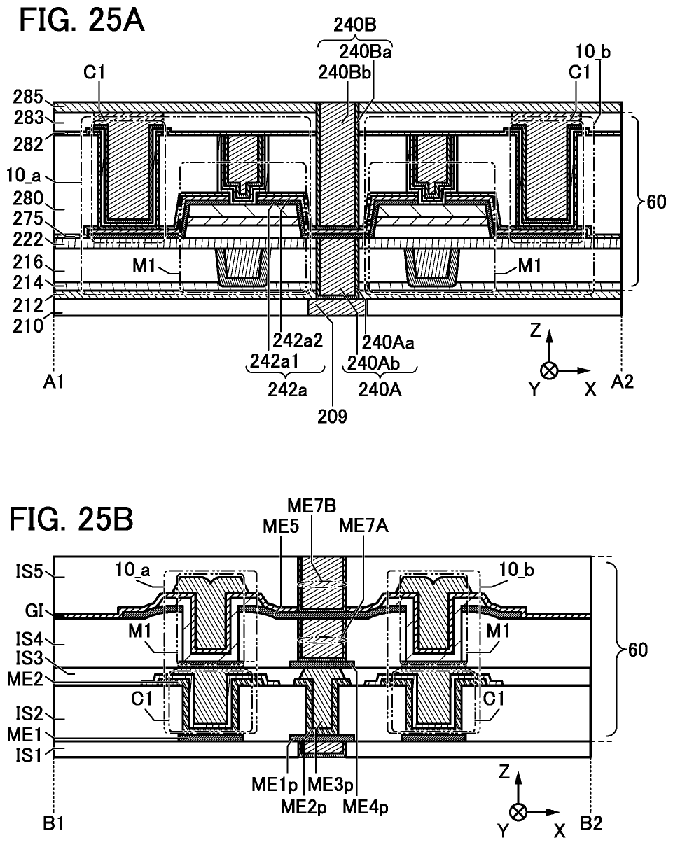

In the memory layer 60 illustrated in FIG. 21B, the conductor 240 is formed to be embedded in the opening provided in the insulator 212, the insulator 214, the insulator 216, the conductor 242a, the insulator 275, the insulator 280, the insulator 282, the insulator 283, and the insulator 285; however, the memory device of one embodiment of the present invention is not limited thereto. For example, as illustrated in FIG. 25A, a wiring (the wiring BL[j] in FIG. 2 or FIG. 5) may be formed in the following manner: the opening is not formed in the conductor 242a, an opening portion is provided in each of a stacked-layer structure of the insulators below the conductor 242a and a stacked-layer structure of the insulators above the conductor 242a, and the opening portions are filled with a conductor. Specifically, for example, in FIG. 25A, an opening whose bottom portion is the conductor 209 is provided in the insulator 212, the insulator 214, the insulator 216, and the insulator 222 below the conductor 242a, and a conductor 240A is provided to fill the opening. In addition, an opening whose bottom portion is the conductor 242a is provided in the insulator 275, the insulator 280, the insulator 282, the insulator 283, and the insulator 285 above the conductor 242a, and a conductor 240B is provided to fill the opening.

As illustrated in FIG. 25A, a wiring extending in the Z direction (the wiring BL[j] in FIG. 2 or FIG. 5) may be formed in the following manner: openings are formed a plurality of times in the memory layer 60 and a conductor is embedded inside the openings after every formation of the openings. When the openings are formed a plurality of times and the conductors are embedded in the openings a plurality of times, electrical continuity between the other of the source and the drain of the transistor M1 (the conductor 242a) and the wiring (the conductor embedded in the opening) is established more easily than in the case where the opening is formed in one step and the conductor is embedded in one step as illustrated in FIG. 21B. That is, when the openings are formed a plurality of times and the conductors are embedded in the openings a plurality of times, defective conduction between the conductor 242a and the wiring (the conductor embedded in the opening) that might be caused in manufacturing the memory device can be prevented.

Note that as illustrated in FIG. 25A, the conductor 240A may have a two-layer structure of a conductor 240Aa and a conductor 240Ab. The description of the conductor 240a can be referred to for the conductor 240Aa, and the description of the conductor 240b can be referred to for the conductor 240Ab. Similarly, as illustrated in FIG. 25A, the conductor 240B may have a two-layer structure of a conductor 240Ba and a conductor 240Bb. The description of the conductor 240a can be referred to for the conductor 240Ba, and the description of the conductor 240b can be referred to for the conductor 240Bb. Note that the conductor 240A and the conductor 240B may each have a single-layer structure or a stacked-layer structure of three or more layers instead of the two-layer structure.

When the plurality of memory layers 60 illustrated in FIGS. 21A to 21D are stacked, the memory device MDV0 in FIGS. 19A and 19B can be formed. When the plurality of memory layers 60 are stacked, the memory capacity of the memory device MDV0 can be increased. Furthermore, when the plurality of memory layers 60 are stacked and the capacitance values of the capacitors C1 included in the memory layers 60 are different from each other, the memory device MDV0A in FIG. 20 capable of multi-bit data writing and reading can be formed.

Since the memory device MDV0A in FIG. 20 has a structure in which the plurality of memory layers 60 illustrated in FIGS. 21A to 21D are stacked, the memory layers 60 can be fabricated using the same layout pattern, for example. Thus, it can be said that the components included in the memory layer 60_1 to the memory layer 60_4 overlap with each other. For example, the oxide 230 included in the memory layer 60_2 includes a region overlapping with at least part of the oxide 230 included in the memory layer 60_1. For example, the second opening of the memory layer 60_2 includes a region overlapping with at least part of the second opening of the memory layer 60_1. For example, the conductor 242a included in the memory layer 60_2 includes a region overlapping with at least part of the conductor 242a included in the memory layer 60_1. For example, the conductor 240 included in the memory layer 60_2 includes a region overlapping with at least part of the conductor 240 included in the memory layer 60_1. The above description made on the overlap between the components of the memory layer 60_1 and the memory layer 60_2 can be applied to a different combination of the memory layers 60.

### <Structure Example 2 of Memory Layer 60>

Next, a structure example of the memory layer 60 that can be applied to the memory device MDV0 in FIGS. 19A and 19B, which is different from that of the memory device MDV0A in FIG. 20, is described.

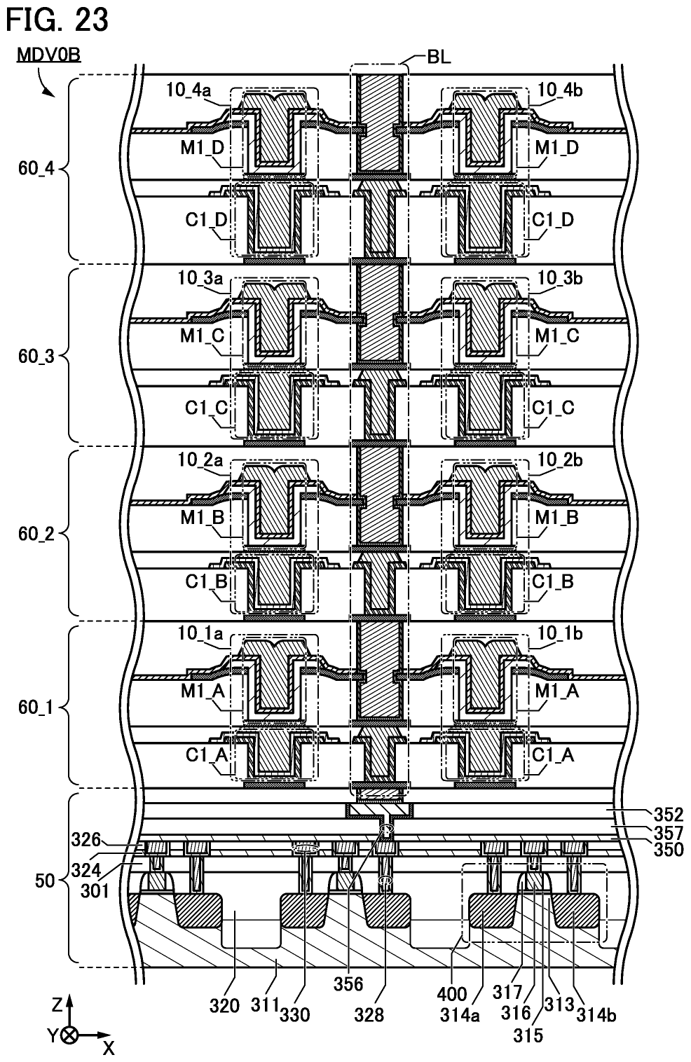

A memory device MDV0B illustrated in FIG. 23 is a structure example of the memory device MDV0 in which the driver circuit layer 50 is provided in the memory device MDVA2 illustrated in FIG. 7. For the driver circuit layer 50, the description of FIG. 20 can be referred to.

In FIG. 23, as in FIG. 20, the memory device MDV0B includes the memory cell 10_1a, the memory cell 10_1b, the memory cell 10_2a, the memory cell 10_2b, the memory cell 10_3a, the memory cell 10_3b, the memory cell 10_4a, and the memory cell 10_4b as the memory cells 10 illustrated in FIGS. 19A and 19B. Also in FIG. 23, the memory layer 60_1 includes the memory cell 10_1a and the memory cell 10_1b, the memory layer 60_2 includes the memory cell 10_2a and the memory cell 10_2b, the memory layer 60_3 includes the memory cell 10_3a and the memory cell 10_3b, and the memory layer 60_4 includes the memory cell 10_4a and the memory cell 10_4b.

Next, specific structure examples of the transistor M1 and the capacitor C1 included in the memory layer 60 are described.

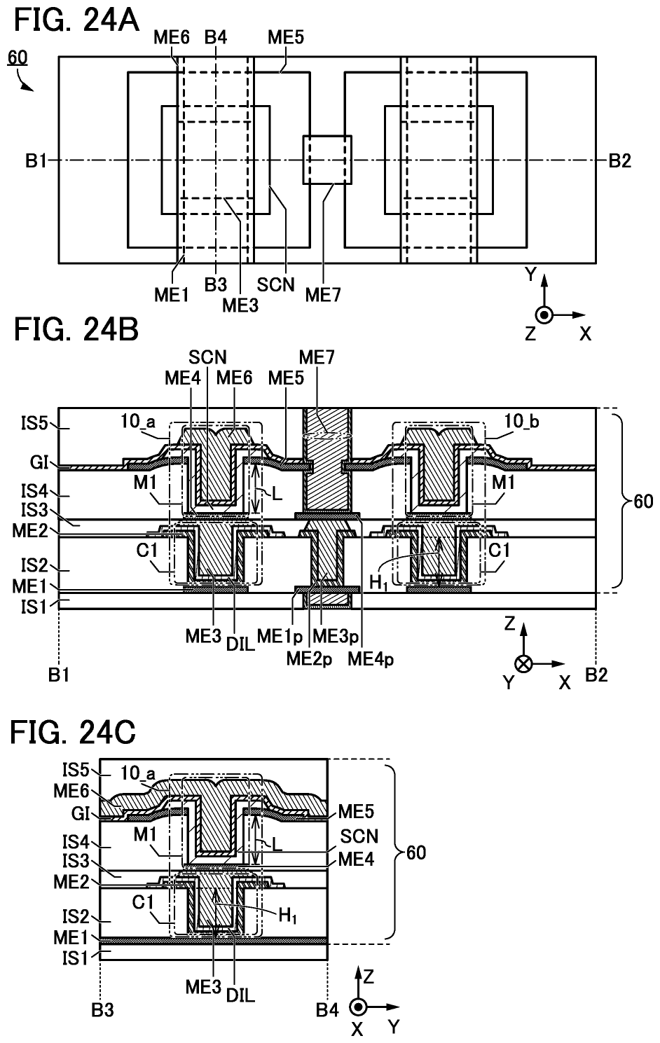

FIGS. 24A to 24C are a schematic plan view and schematic cross-sectional views of any one of the memory layer 60_1 to the memory layer 60_4 each including the transistor M1 and the capacitor C1 in the memory device MDV0A in FIG. 20. FIG. 24A is a schematic plan view of the memory layer 60. FIGS. 24B and 24C are schematic cross-sectional views of the memory layer 60. Here, FIG. 24B is a schematic cross-sectional view taken along dashed-dotted line B1-B2 in FIG. 24A. FIG. 24C is a schematic cross-sectional view taken along dashed-dotted line B3-B4 in FIG. 24A. Note that for simplification, some components are not illustrated in the plan view of FIG. 24A.

The memory layer 60 is provided over an insulator IS1, for example. The memory layer 60 includes an insulator IS2, an insulator IS3, an insulator IS4, an insulator IS5, an insulator DIL, an insulator GI, a conductor ME1, a conductor ME1p, a conductor ME2, a conductor ME2p, a conductor ME3, a conductor ME3p, a conductor ME4, a conductor ME4p, a conductor ME5, a conductor ME6, a conductor ME7, and an oxide SCN.

The insulator IS2 corresponds to any one of the insulating layer SK1_A to the insulating layer SK1_D in the memory device MDVA2 in FIG. 7 described in Embodiment 1. The conductor ME1 corresponds to the first conductor in the memory device MDVA2 in FIG. 7 described in Embodiment 1. The conductor ME2 corresponds to the one of the pair of electrodes of any one of the capacitor C1_A to the capacitor C1_D in the memory device MDVA2 in FIG. 7 described in Embodiment 1. The insulator DIL corresponds to the dielectric of any one of the capacitor C1_A to the capacitor C1_D in the memory device MDVA2 in FIG. 7 described in Embodiment 1. The conductor ME3 corresponds to the other of the pair of electrodes of any one of the capacitor C1_A to the capacitor C1_D in the memory device MDVA2 in FIG. 7 described in Embodiment 1. The conductor ME4 corresponds to the third conductor in the memory device MDVA2 in FIG. 7 described in Embodiment 1. The insulator IS4 corresponds to any one of the insulating layer SK2_A to the insulating layer SK2_D in the memory device MDVA2 in FIG. 7 described in Embodiment 1. The conductor ME5 corresponds to the second conductor in the memory device MDVA2 in FIG. 7 described in Embodiment 1. The oxide SCN corresponds to the semiconductor in the memory device MDVA2 in FIG. 7 described in Embodiment 1. The insulator GI corresponds to the insulator functioning as the gate insulator of any one of the transistor M1_A to the transistor M1_D in the memory device MDVA2 in FIG. 7 described in Embodiment 1. The conductor ME6 corresponds to the fourth conductor in the memory device MDVA2 in FIG. 7 described in Embodiment 1. The conductor ME1p, the conductor ME2p, the conductor ME3p, the conductor ME4p, and the conductor ME7 correspond to the fifth conductor in the memory device MDVA2 in FIG. 7 described in Embodiment 1.

In the memory layer 60, the capacitor C1 is positioned above the insulator IS1, and the transistor M1 is positioned above the capacitor C1.

The capacitor C1 illustrated in FIGS. 24A to 24C can be a trench capacitor like the capacitor C1 illustrated in FIGS. 21A, 21B, and 21D.

As the length of the second opening in the insulator IS2 (the trench length of the capacitor C1), FIGS. 24B and 24C illustrates H₁ that is the vertical distance from the bottom surface of the conductor ME1 (the first conductor in FIG. 7 described in Embodiment 1) to the top surface of the insulator IS2 (any one of the insulating layer SK1_A to the insulating layer SK1_D in FIG. 7 described in Embodiment 1). Note that H₁ corresponds to H_{A} to H_{D} illustrated in FIG. 6.

Although not illustrated in FIG. 24B, in the X direction, the width of the second opening is larger than the width of the conductor ME1 in some cases. In the capacitor C1 of that case, the length of the second opening is sometimes different from place to place in the second opening, as in the capacitor C1 illustrated in FIG. 21D. In this case, the length of the second opening in the insulator IS2 (the trench length of the capacitor C1) is the largest vertical height in the second opening from the bottom surface of the conductor ME2 (the second conductor in FIG. 7 described in Embodiment 1) to the top surface of the insulator IS2 (any one of the insulating layer SK1_A to the insulating layer SK1_D in FIG. 6 described in Embodiment 1).

Note that the transistor M1 illustrated in FIGS. 24B and 24C can be a vertical-channel transistor.

As illustrated in FIGS. 24A to 24C, when the channel formation region of the transistor M1 is provided along the side surface of the first opening of the insulator IS4 functioning as an interlayer film, the transistor formation area can be smaller than that in the case where the channel formation region of the transistor M1 is provided along the X-Y plane. In the transistor M1, the source electrode, the semiconductor, and the drain electrode can be provided to overlap with each other; thus, the area occupied by the transistor M1 can be significantly smaller than that of what is called a planar transistor in which a semiconductor is provided in a planar shape. Thus, when a circuit is formed using the transistor M1, the area of the circuit can be small. As a result, the memory device including the circuit can be downsized.

The channel length of the transistor M1 can be, for example, the depth of the first opening of the insulator IS4 illustrated in FIGS. 24B and 24C. Note that in FIGS. 24B and 24C, the depth of the first opening of the insulator IS4 is denoted by L, and the channel length of the transistor M1 can be L. The channel length L of the transistor M1 can be the shortest distance between a portion in contact with the conductor ME4 and a portion in contact with the conductor ME5 in the oxide SCN in the cross-sectional view. Note that the channel length here can be a length of a channel formation region between a source and a drain.

The channel length L of the transistor M1 corresponds to the length in the height direction of the first opening of the insulator IS4 in the cross-sectional view. That is, the channel length L depends on the thickness of the insulator IS4. In the case where the first opening of the insulator IS4 has a tapered shape, the channel length L depends on the angle formed between the first opening and the formation surface (here, the top surface of the conductor ME4). Thus, the channel length L can be a value smaller than that of the resolution limit of a light-exposure apparatus, for example, which enables the transistor to have a minute size. Specifically, it is possible to obtain a transistor with an extremely short channel length that could not be obtained with the use of a conventional light-exposure apparatus (the minimum line width:approximately 2 μm or approximately 1.5 μm, for example). Moreover, it is also possible to obtain a transistor with a channel length shorter than 10 nm without using an extremely expensive light-exposure apparatus used in the latest LSI technology.

The channel length L can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

When the channel length L is small, the transistor M1 can have a high on-state current. Therefore, for example, when the transistor M1 is used in the memory cell of the memory device, power consumption needed for the memory cell can be reduced. Note that a vertical-channel transistor like the transistor M1 may be used not only in a memory cell but also in a driver circuit or the like. Furthermore, in the case where the transistor M1 is used in a memory device, even when the number of wirings is increased, signal delay in each wiring can be reduced, so that the driving speed of the memory device can be increased. Furthermore, the area occupied by the circuit can be reduced, so that the circuit density can be increased.

For the insulator IS1, the material usable for the insulator 210, the insulator 216, the insulator 280, or the insulator 283 described above can be used, for example. For the insulator IS2, the material usable for the insulator 212, the insulator 214, the insulator 222, the insulator 275, the insulator 282, or the insulator 285 described above can be used, for example.

The conductor ME1 is positioned over the insulator IS1. The conductor ME1 is formed along the Y direction as illustrated in FIGS. 24A and 24C. Thus, the conductor ME1 functions as any one of the wiring VE1_A to the wiring VE1_D in FIG. 2.

For the conductor ME1, the material usable for the conductor 205, the conductor 242a, the conductor 242b, the conductor 150, the conductor 160, or the conductor 260 described above can be used, for example.

The capacitor C1 can be formed by embedding the conductor ME2, the insulator DIL, and the conductor ME3 inside the second opening provided in the insulator IS2. Note that the second opening is formed in a region where the conductor ME1, the conductor ME2, and the conductor ME3 overlap with each other.

In particular, the conductor ME2 is formed on the top surface of the conductor ME1 corresponding to the bottom portion of the second opening, the side surface of the insulator IS2 corresponding to the sidewall of the second opening, and the top surface of the insulator IS2. The insulator DIL is formed on the top surface of the conductor ME2 and the top surface of the insulator IS2. The conductor ME3 is formed on the top surface of the insulator DIL to fill the second opening.

After the formation of the conductor ME3, an insulating film to be the insulator IS3 is formed and then processed by planarization treatment (e.g., CMP) to expose the conductor ME3 and make the conductor ME3 and the insulator IS3 have the same height. Thus, the insulator IS3 can be formed.

The conductor ME3 functions as the one of the pair of electrodes of the capacitor C1, the insulator DIL functions as the dielectric of the capacitor C1, and the conductor ME2 functions as the other of the pair of electrodes of the capacitor C1.

For each of the conductor ME2 and the conductor ME3, the material usable for the conductor 205, the conductor 242a, the conductor 242b, the conductor 150, the conductor 160, or the conductor 260 described above can be used, for example.

For each of the conductor IS2 and the conductor IS3, the material usable for the insulator 210, the insulator 216, the insulator 280, or the insulator 283 described above can be used, for example. For the insulator IS2, the material usable for the insulator 212, the insulator 214, the insulator 222, the insulator 275, the insulator 282, or the insulator 285 described above can be used, for example.

A material with a high dielectric constant is preferably used for the insulator DIL, and for example, the material usable for the insulator 282 described above can be used.

The conductor ME4 is formed on the top surface of the conductor ME3. The insulator IS4 is formed on the top surface of the insulator IS3 and the top surface of the conductor ME3. The conductor ME5 is formed on the top surface of the insulator IS4.

For each of the conductor ME4 and the conductor ME5, the material usable for the conductor 205, the conductor 242a, the conductor 242b, the conductor 150, the conductor 160, or the conductor 260 described above can be used, for example.

For the insulator IS4, the material usable for the insulator 210, the insulator 216, the insulator 280, or the insulator 283 described above can be used, for example. For the insulator IS2, the material usable for the insulator 212, the insulator 214, the insulator 222, the insulator 275, the insulator 282, or the insulator 285 described above can be used, for example.

The transistor M1 can be formed by embedding the oxide SCN, the insulator GI, and the conductor ME6 inside the first opening provided in the insulator IS4 and the conductor ME5 over the insulator IS4. Note that the first opening is formed in a region where the conductor ME1, the conductor ME2, and the conductor ME3 overlap with each other.

In particular, the oxide SCN is formed on the top surface of the conductor ME4 corresponding to the bottom portion of the first opening, the side surface of the insulator IS4 corresponding to the sidewall of the first opening, and the top surface of the conductor ME5. The insulator GI is formed on the top surface of the oxide SCN, the top surface of the conductor ME5, and the top surface of the insulator IS4. The conductor ME6 is formed on the top surface of the insulator GI to fill the first opening. The insulator IS5 is formed on the top surface of the conductor ME6.

The conductor ME4 functions as the one of the source and the drain of the transistor M1, and the conductor ME5 functions as the other of the source and the drain of the transistor M1. The channel formation region in the transistor M1 is formed in the oxide SCN. The insulator GI functions as a gate insulating film of the transistor M1, and the conductor ME6 functions as a gate of the transistor M1.

For the oxide SCN, the material usable for the oxide 230 described above can be used, for example.

For example, the oxide SCN can be a metal oxide functioning as an oxide semiconductor. In that case, the transistor M1 is an OS transistor. The metal oxide preferably contains at least indium or zinc, for example. In particular, the metal oxide preferably contains indium and zinc. In addition to them, the element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. Furthermore, the element M preferably contains one or both of gallium and tin.

For example, an In—Ga—Zn oxide is preferably used as the oxide SCN. In particular, the In—Ga—Zn oxide is further preferably a metal oxide having an atomic ratio of In:Ga:Zn=1:1:1 or in the neighborhood thereof, In:Ga:Zn=4:2:3 or in the neighborhood thereof, or In:Ga:Zn=3:1:2 or in the neighborhood thereof. For another example, an In—Zn oxide is preferably used as the oxide SCN. In particular, the In—Zn oxide is further preferably a metal oxide having an atomic ratio of In:Zn=4:1 or in the neighborhood thereof.

For the conductor ME6, the material usable for the conductor 205, the conductor 242a, the conductor 242b, the conductor 150, the conductor 160, or the conductor 260 described above can be used, for example.

For the insulator GI, the material usable for the insulator 253 or the insulator 254 described above can be used.

For the insulator IS5, the material usable for the insulator 210, the insulator 216, the insulator 280, or the insulator 283 described above can be used, for example. For the insulator IS2, the material usable for the insulator 212, the insulator 214, the insulator 222, the insulator 275, the insulator 282, or the insulator 285 described above can be used, for example.

Note that since the plurality of memory layers 60 are stacked, the insulator IS1 illustrated in FIGS. 24B and 24C can be formed using the same material as the insulator IS5 described later.

The conductor ME5 is formed along the X direction as illustrated in FIGS. 24A and 24B and is in contact with the conductor ME7 described later. Thus, electrical continuity is established between the conductor ME5 and the conductor ME7 that corresponds to part of the wiring BL in FIG. 2.

The conductor ME6 is formed along the Y direction as illustrated in FIGS. 24A and 24C. Accordingly, the conductor ME6 functions as any one of the wiring WL_A[i], the wiring WL_B[i], the wiring WL_C[i], and the wiring WL_D[i] in FIG. 2 or any one of the wiring WL_Aa[i], the wiring WL_Ab[i], the wiring WL_Ba[i], the wiring WL_Bb[i], the wiring WL_Ca[i], the wiring WL_Cb[i], the wiring WL_Da[i], and the wiring WL_Db[i] in FIG. 5.

In FIGS. 24A and 24B, the conductor ME1p, the conductor ME2p, the conductor ME3p, the conductor ME4p, and the conductor ME7 functioning as the wiring BL are positioned between the one of the source electrode and the drain electrode of one of two transistors M1 and the one of the source electrode and the drain electrode of the other of the two transistors M1.

As illustrated in FIG. 24B, the conductor ME1p is formed over the insulator IS1 and the conductor embedded in the insulator IS1, and particularly, the conductor ME1p can be formed concurrently with the conductor ME1. Thus, the same material as the conductor ME1 can be used for the conductor ME1p.

An opening which is provided in the insulator IS2 and in which the conductor ME2p and the conductor ME3p are embedded can be formed concurrently with the second opening included in the capacitor C1 described above. Note that the opening in which the conductor ME2p and the conductor ME3p are embedded is formed in a region overlapping with the conductor ME1p.

Similarly, the conductor ME2p can be formed concurrently with the conductor ME2, for example. Thus, the same material as the conductor ME2 can be used for the conductor ME2p. Similarly, the conductor ME3p can be formed concurrently with the conductor ME3, for example. Thus, the same material as the conductor ME3 can be used for the conductor ME3p.

As illustrated in FIG. 24B, the conductor ME4p is formed over the insulator IS3 and the conductor ME3p, and particularly, the conductor ME4p can be formed concurrently with the conductor ME4. Thus, the same material as the conductor ME4 can be used for the conductor ME4p.

A third opening in which the conductor ME7 is to be embedded is provided in the insulator IS4, the insulator GI, and the insulator IS5. The conductor ME7 is embedded in the third opening, whereby the conductor ME7 includes a region in contact with the conductor ME5. In other words, when the conductor ME7 is provided in the third opening, electrical continuity can be established between the one of the source electrode and the drain electrode of one of the two transistors M1 and the one of the source electrode and the drain electrode of the other of the two transistors M1. In addition, since electrical continuity is established from the conductor embedded in the insulator IS1 to the conductor ME7, a circuit for electrically connecting the memory cell 10_a and the memory cell 10_b can be provided above and/or below the memory layer 60. Specifically, by stacking the plurality of memory layers 60, for example, stacked bodies each of which includes the conductor embedded in the insulator IS1, the conductor ME1p to the conductor ME4p, and the conductor ME7 and which are included in the memory layers 60 overlap with each other as illustrated in FIG. 23; thus, the stacked bodies function as one wiring (the wiring BL[j] in FIG. 2 or FIG. 5).

Although the memory layer 60 in FIG. 24B has the stacked-layer structure of the conductor ME1p, the conductor ME2p, the conductor ME3p, the conductor ME4p, and the conductor ME7 as a wiring extending in the Z direction (the wiring BL[j] in FIG. 2 or FIG. 5), the memory device of one embodiment of the present invention is not limited thereto. For example, as illustrated in FIG. 25B, a wiring (the wiring BL[j] in FIG. 2 or FIG. 5) may be formed in the following manner: the opening is not formed in the conductor ME5, an opening portion is provided in each of a stacked-layer structure of the insulators below the conductor ME5 and a stacked-layer structure of the insulators above the conductor ME5, and the opening portions are filled with a conductor. Specifically, for example, in FIG. 25B, an opening whose bottom portion is the conductor ME4p is provided in the insulator IS4 below the conductor ME5, and a conductor ME7A is provided to fill the opening. In addition, an opening whose bottom portion is the conductor ME5 is provided in the insulator GI and the insulator IS5 above the conductor ME5, and a conductor ME7B is provided to fill the opening.

As illustrated in FIG. 25B, a wiring extending in the Z direction (the wiring BL[j] in FIG. 2 or FIG. 5) may be formed in the following manner: openings are formed a plurality of times above the insulator IS3 in the memory layer 60 and a conductor is embedded inside the openings after every formation of the openings. When the openings are formed a plurality of times and the conductors are embedded in the openings a plurality of times, electrical continuity between the other of the source and the drain of the transistor M1 (the conductor ME5) and the wiring (the conductor embedded in the opening) is established more easily than in the case where the opening is formed in one step and the conductor is embedded in one step as illustrated in FIG. 21B. That is, when the openings are formed a plurality of times and the conductors are embedded in the openings a plurality of times, defective conduction between the conductor ME5 and the wiring (the conductor embedded in the opening) that might be caused in manufacturing the memory device can be prevented.

Note that the description of the conductor ME7 is referred to for each of the conductor ME7A and the conductor ME7B. The conductor ME7A and the conductor ME7B may each have a single-layer structure or a stacked-layer structure of three or more layers instead of the two-layer structure.

When the plurality of memory layers 60 illustrated in FIGS. 24A to 24C are stacked, the memory device MDV0 in FIGS. 19A and 19B can be formed. When the plurality of memory layers 60 are stacked, the memory capacity of the memory device MDV0 can be increased. Furthermore, when the plurality of memory layers 60 are stacked and the capacitance values of the capacitors C1 included in the memory layers 60 are different from each other, the memory device MDV0B in FIG. 23 capable of multi-bit data writing and reading can be formed.

Since the memory device MDV0B in FIG. 23 has a structure in which the plurality of memory layers 60 illustrated in FIGS. 24A to 24C are stacked, the memory layers 60 can be fabricated using the same layout pattern, for example. Thus, it can be said that the components included in the memory layer 60_1 to the memory layer 60_4 overlap with each other. For example, the oxide SCN included in the memory layer 60_2 includes a region overlapping with at least part of the oxide SCN included in the memory layer 60_1. For example, the second opening of the memory layer 60_2 includes a region overlapping with at least part of the second opening of the memory layer 60_1. For example, the first opening of the memory layer 60_2 includes a region overlapping with at least part of the first opening of the memory layer 60_1. For example, the conductor ME5 included in the memory layer 60_2 includes a region overlapping with at least part of the conductor ME5 included in the memory layer 60_1. For example, the conductor ME4 included in the memory layer 60_2 includes a region overlapping with at least part of the conductor ME4 included in the memory layer 60_1. For example, the conductor ME7 included in the memory layer 60_2 includes a region overlapping with at least part of the conductor ME7 included in the memory layer 60_1. The above description made on the overlap between the components of the memory layer 60_1 and the memory layer 60_2 can be applied to a different combination of the memory layers 60.

### <Materials of Memory Device>

Materials that can be used for the memory device are described below.

### <<Substrate>>

As a substrate over which the transistor M1 is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate using silicon carbide, silicon germanium, gallium arsenide, indium phosphide, zinc oxide, or gallium oxide as a material. Other examples include a semiconductor substrate in which an insulator region is provided in the above semiconductor substrate, e.g., a silicon on insulator (SOI) substrate. Examples of the conductor substrate include a graphite substrate, a metal substrate, an alloy substrate, and a conductive resin substrate. Alternatively, a substrate including a metal nitride, a substrate including a metal oxide, or the like is given. A substrate which is an insulator substrate provided with a conductor or a semiconductor, a substrate which is a semiconductor substrate provided with a conductor or an insulator, a substrate which is a conductor substrate provided with a semiconductor or an insulator, or the like is also given. Alternatively, any of these substrates provided with an element may be used. Examples of the element provided over the substrate include a capacitor, a resistor element, a switching element, a light-emitting element, and a memory element.

### <<Insulator>>

Examples of an insulator include an insulating oxide, an insulating nitride, an insulating oxynitride, an insulating nitride oxide, an insulating metal oxide, an insulating metal oxynitride, and an insulating metal nitride oxide.

With miniaturization or high integration of transistors, for example, a problem such as generation of leakage current or the like may arise because of a thinner gate insulator. When a high-k material is used for the insulator functioning as a gate insulator, the voltage at the time of operation of the transistor can be reduced while the physical thickness is maintained. By contrast, when a material with a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting transmission of oxygen and impurities such as hydrogen. An insulator with a function of inhibiting transmission of oxygen and impurities such as hydrogen can be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating is provided in contact with the oxide 230 (or the oxide SCN) to compensate for the oxygen vacancies in the oxide 230 (or the oxide SCN).

### <<Conductor>>

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Alternatively, a semiconductor having high electric conductivity, typified by polycrystalline silicon containing an impurity element such as phosphorus, or silicide such as nickel silicide may be used.

Conductive layers formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

As the oxide 230 (or the oxide SCN), a metal oxide functioning as a semiconductor (oxide semiconductor) is preferably used. A metal oxide that can be used for the oxide 230 (or the oxide SCN) according to the present invention is described below.

A metal oxide preferably contains at least indium or zinc. In particular, the metal oxide preferably contains indium and zinc. In addition, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, antimony, and the like may be contained.

Here, the case where the metal oxide is In-M-Zn oxide, which contains indium, the element M, and zinc is considered. The element M can be one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony.

It is particularly preferable that an oxide containing indium (In), gallium (Ga), and zinc (Zn) (also referred to as IGZO) be used for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also referred to as a metal oxide in some cases. In addition, a metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### [Impurities]

The influence of impurities in the oxide semiconductor will be described.

When silicon or carbon, which is a Group 14 element, is contained in an oxide semiconductor, defect states are formed in the oxide semiconductor. Thus, the concentration of silicon or carbon in the oxide semiconductor (the concentration measured by secondary ion mass spectrometry (SIMS)) is lower than or equal to 2×10¹⁸ atoms/cm³, preferably lower than or equal to 2×10¹⁷ atoms/cm³.

When the oxide semiconductor contains alkali metal or alkaline earth metal, defect states are formed and carriers are generated in some cases. Accordingly, a transistor including an oxide semiconductor that contains alkali metal or alkaline earth metal tends to become normally-on. Thus, the concentration of alkali metal or alkaline earth metal in the oxide semiconductor, which is measured by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to become normally-on. When nitrogen is contained in the oxide semiconductor, a trap state is sometimes formed. This might make the electrical characteristics of the transistor unstable. Thus, the concentration of nitrogen in the oxide semiconductor, which is measured by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to become normally-on. For this reason, hydrogen in the oxide semiconductor is preferably reduced as much as possible. Specifically, the concentration of hydrogen in the oxide semiconductor, which is measured by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

### <<Other Semiconductor Materials>>

A semiconductor material that can be used for the oxide 230 (or the oxide SCN) is not limited to the above metal oxides. A semiconductor material which has a band gap (a semiconductor material that is not a zero-gap semiconductor) can be used for the oxide 230 (or the oxide SCN). For example, a single element semiconductor such as silicon, a compound semiconductor such as gallium arsenide, or a layered material functioning as a semiconductor (also referred to as an atomic layered material or a two-dimensional material) is preferably used as a semiconductor material. In particular, a layered material functioning as a semiconductor is preferably used as a semiconductor material.

In this specification and the like, the layered material is a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

The oxide 230 (or the oxide SCN) is preferably formed using a transition metal chalcogenide functioning as a semiconductor, for example. Specific examples of the transition metal chalcogenide which can be used for the oxide 230 (or the oxide SCN) include molybdenum sulfide (typically MoS₂), molybdenum selenide (typically MoSe₂), molybdenum telluride (typically MoTe₂), tungsten sulfide (WS₂), tungsten selenide (typically WSe₂), tungsten telluride (typically WTe₂), hafnium sulfide (HfS₂), hafnium selenide (HfSe₂), zirconium sulfide (ZrS₂), and zirconium selenide (ZrSe₂). When the transition metal chalcogenide is used for the oxide 230 (or the oxide SCN), a semiconductor device with a high on-state current can be provided.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 4

In this embodiment, a transistor whose channel formation region includes an oxide semiconductor (OS transistor) is described. Brief description is also made on comparison of an OS transistor with a transistor whose channel formation region includes silicon (also referred to as Si transistor).

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In some cases, the OS transistor has a defect that is an oxygen vacancy in the oxide semiconductor into which hydrogen enters (V_{O}H), which generates an electron serving as a carrier. When V_{O}H is formed in the channel formation region, the donor concentration in the channel formation region is increased in some cases. As the donor concentration in the channel formation region increases, the threshold voltage might vary. Accordingly, when the channel formation region in the oxide semiconductor includes oxygen vacancies, the transistor tends to become normally-on (in the state where a channel is generated even when no voltage is applied to a gate electrode and a current flows through the transistor). Therefore, the impurities, oxygen vacancies, and V_{O}H are preferably reduced as much as possible in the channel formation region of the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off-leakage current or Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. Meanwhile, an OS transistor includes an oxide semiconductor that is a semiconductor material with a large band gap, and thus is less likely to suffer from the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometime also referred to as S value), an increase in leakage current, and the like. Here, the S value refers to the amount of change in gate voltage in a subthreshold region, which is required for changing drain current by one digit at a constant drain voltage. The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length needs to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻ region and the source and drain regions become n⁺ regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has advantages over a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

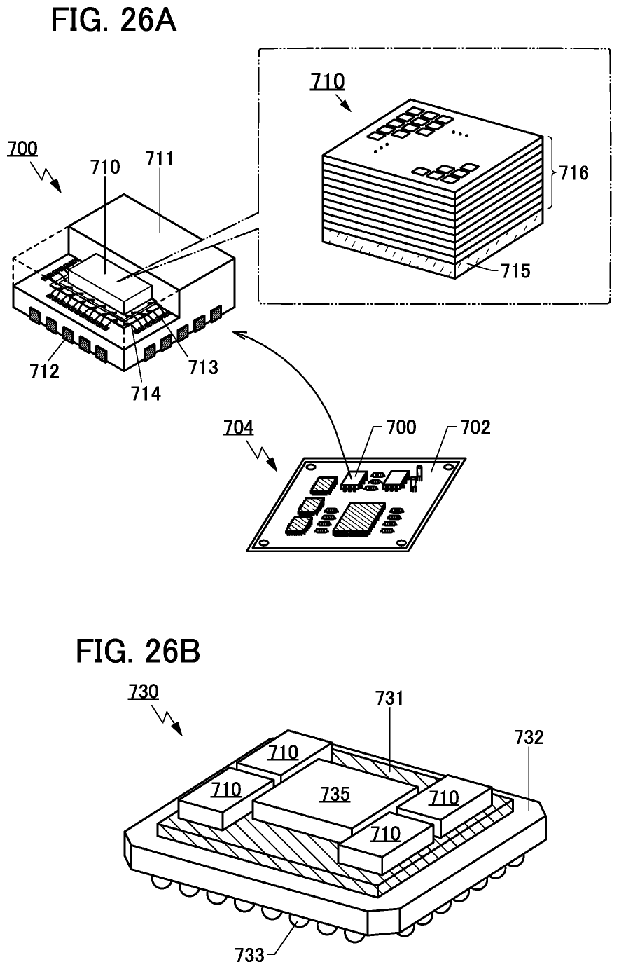

FIG. 26A is a perspective view of a substrate (a circuit board 704) on which an electronic component 700 is mounted. The electronic component 700 illustrated in FIG. 26A includes a semiconductor device 710 in a mold 711. Some components are omitted in FIG. 26A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase a memory bandwidth.

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the formation process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 26B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a central processing unit (CPU), a graphics processing unit (GPU), or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 26B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by any of various mounting methods other than BGA and PGA. Examples of a mounting method include a staggered pin grid array (SPGA), a land grid array (LGA), a quad flat package (QFP), a quad flat J-leaded package (QFJ), and a quad flat non-leaded package (QFN).

### [Electronic Device]

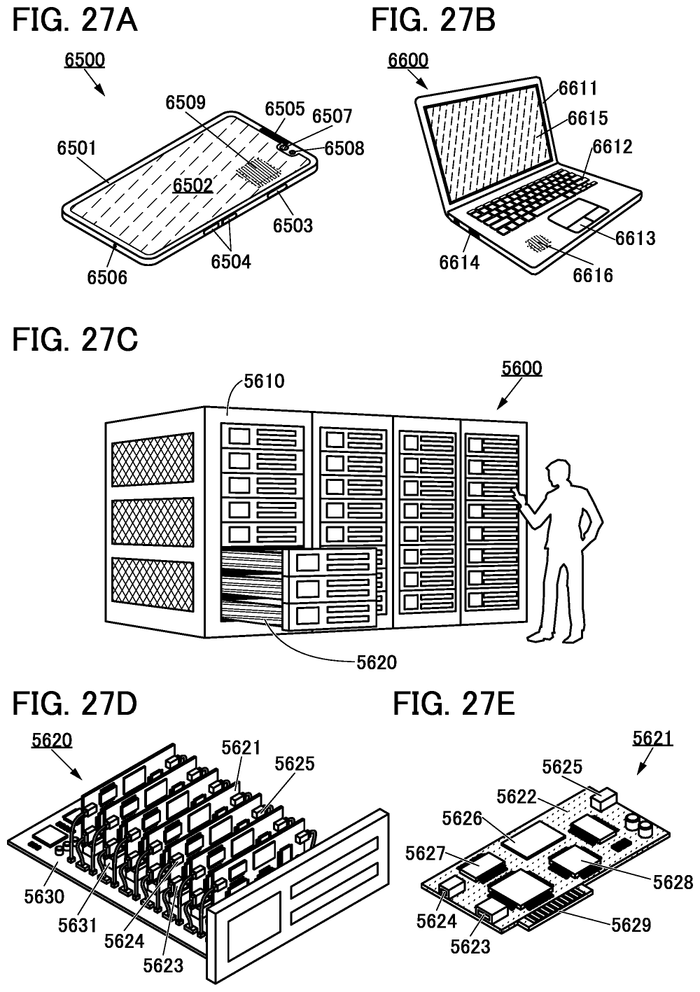

FIG. 27A is a perspective view of an electronic device 6500. The electronic device 6500 illustrated in FIG. 27A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are used as the control device 6509, for example. The semiconductor device of one embodiment of the present invention can be used for the display portion 6502, the control device 6509, and the like.

An electronic device 6600 illustrated in FIG. 27B is an information terminal that can be used as a notebook personal computer. The electronic device 6600 includes a housing 6611, a keyboard 6612, a pointing device 6613, an external connection port 6614, a display portion 6615, and a control device 6616. One or more selected from a CPU, a GPU, and a memory device are used as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 27C is a perspective view of a large computer 5600. In the large computer 5600 illustrated in FIG. 27C, a plurality of rack mount computers 5620 are stored in a rack 5610. Note that the large computer 5600 may be referred to as a supercomputer.

The computer 5620 can have a structure in a perspective view of FIG. 27D, for example. In FIG. 27D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 27E is an example of a processing board provided with a CPU, a GPU, a memory device, and the like. The PC card 5621 includes a board 5622. The board 5622 includes the connection terminal 5623, the connection terminal 5624, and the connection terminal 5625, a semiconductor device 5626, a semiconductor device 5627, a semiconductor device 5628, and a connection terminal 5629. Although FIG. 27E also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment (e.g., equipment having a function of processing and storing information).

The semiconductor device of one embodiment of the present invention can include an OS transistor. A change in electrical characteristics of the OS transistor due to radiation irradiation is small. That is, the OS transistor is highly resistant to radiation and thus can be suitably used even in an environment where radiation can enter. For example, the OS transistor can be suitably used in outer space.

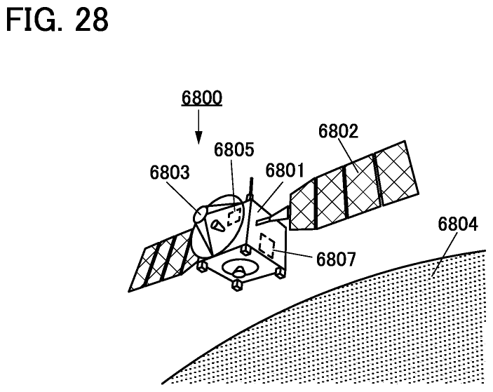

FIG. 28 illustrates an artificial satellite 6800 as an example of space equipment. The artificial satellite 6800 includes a body 6801, a solar panel 6802, an antenna 6803, a secondary battery 6805, and a control device 6807. FIG. 28 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 28, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a memory device are used as the control device 6807, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the memory device of one embodiment of the present invention for the storage system in the data center, electric power required for data retention and the size of a memory device retaining data can be reduced. Thus, the size of the storage system, the amount of electric power for data retention, the size of the cooling equipment, and the like can be reduced. This can reduce the scale of the data center.

Since the memory device of one embodiment of the present invention has low power consumption, heat generation from a circuit can be reduced. Accordingly, adverse effects of the heat generation on the circuit itself, the peripheral circuit, and the module can be reduced. Furthermore, the use of the memory device of one embodiment of the present invention enables a data center that operates stably even in a high temperature environment. Thus, the reliability of the data center can be increased.

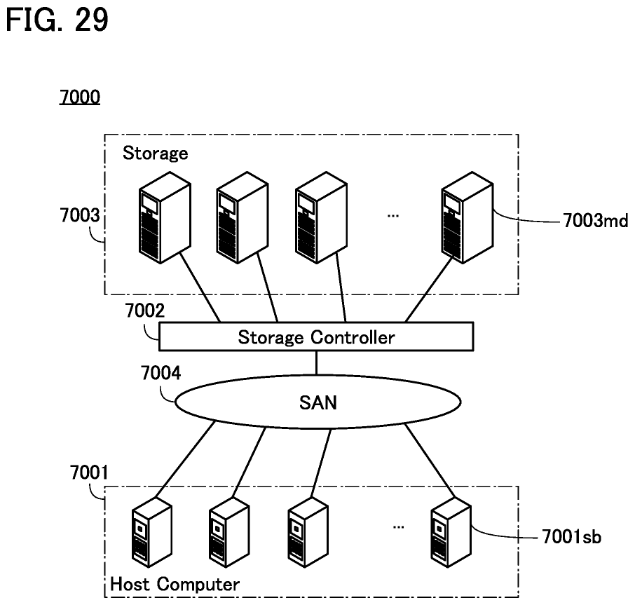

FIG. 29 illustrates a storage system that can be used in a data center. A storage system 7000 illustrated in FIG. 29 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

This application is based on Japanese Patent Application Serial No. 2023-015427 filed with Japan Patent Office on Feb. 3, 2023, the entire contents of which are hereby incorporated by reference.

What is claimed is:

1. A memory device comprising:
a first layer comprising a first memory cell, the first memory cell comprising a first transistor and a first capacitor; and
a second layer comprising a second memory cell, the second memory cell comprising a second transistor and a second capacitor,
wherein one of a source and a drain of the first transistor is electrically connected to the first capacitor,
wherein one of a source and a drain of the second transistor is electrically connected to the second capacitor,
wherein the other of the source and the drain of the first transistor is electrically connected to a wiring,
wherein the other of the source and the drain of the second transistor is electrically connected to the wiring,
wherein the second layer comprises a region overlapping with the first layer,
wherein the first layer further comprises a first insulator,
wherein the second layer further comprises a second insulator,
wherein each of the first capacitor and the second capacitor is a trench capacitor,
wherein the first capacitor is positioned inside a first opening of the first insulator,
wherein the second capacitor is positioned inside a second opening of the second insulator,
wherein a length of the second opening is larger than a length of the first opening,
wherein the first capacitor is configured to retain a voltage corresponding to a lower bit signal of digital data, and
wherein the second capacitor is configured to retain a voltage corresponding to a higher bit signal of the digital data.

2. The memory device according to claim 1,
wherein the first layer further comprises a third conductor,
wherein the second layer further comprises a fourth conductor comprising a region overlapping with the third conductor,
wherein the third conductor and the fourth conductor are configured to be the wiring,
wherein the other of the source and the drain of the first transistor comprises a first conductor comprising a region in contact with the third conductor,
wherein the other of the source and the drain of the second transistor comprises a second conductor comprising a region in contact with the fourth conductor.

3. The memory device according to claim 1,
wherein the first transistor comprises a first oxide semiconductor in a channel formation region,
wherein the second transistor comprises a second oxide semiconductor in a channel formation region, and
wherein the second oxide semiconductor comprises a region overlapping with the first oxide semiconductor.

4. The memory device according to claim 1,
wherein the first transistor comprises a first oxide semiconductor in a channel formation region,
wherein the second transistor comprises a second oxide semiconductor in a channel formation region,
wherein the first oxide semiconductor and the second oxide semiconductor each comprise one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, magnesium, and antimony.

5. The memory device according to claim 1,
wherein a capacitance value of the second capacitor is greater than or equal to 1.8 times and less than or equal to 2.2 times a capacitance value of the first capacitor.

6. The memory device according to claim 1,
wherein the second opening comprises a region overlapping with the first opening.

7. The memory device according to claim 1,
wherein the first memory cell and the second memory cell are included in a cell array, and
wherein the digital data comprising the lower bit signal and the higher bit signal is written to the cell array.

8. The memory device according to claim 1, wherein the wiring is configured to be a bit line.

9. The memory device according to claim 1, further comprising a driver circuit layer,
wherein the driver circuit layer is positioned below the first layer.
